(19) United States
(12) Patent Application Publication
(10) Pub. No.: US 2026/0010072 A1
(43) Pub. Date: Jan. 8, 2026

(54) METHOD FOR PRODUCING SOLUTION, METHOD FOR PRODUCING RESIST COMPOSITION, PATTERN FORMING METHOD, AND METHOD FOR PRODUCING ELECTRONIC DEVICE

(71) Applicant: FUJIFILM CORPORATION, Tokyo (JP)

(72) Inventors: Shuhei Yamaguchi, Shizuoka (JP); Taro Miyoshi, Shizuoka (JP); Eiji Fukuzaki, Shizuoka (JP)

(21) Appl. No.: 19/327,095

(22) Filed: Sep. 12, 2025

Related U.S. Application Data
(63) Continuation of application No. PCT/JP2024/009320, filed on Mar. 11, 2024.

(30) Foreign Application Priority Data
Mar. 20, 2023 (JP) 2023-044470

(51) Int. Cl. G03F 7/004

(52) U.S. Cl. CPC G03F 7/0048

(57) ABSTRACT

A method for producing a solution in which one or more solid substances are dissolved in a solvent, the one or more solid substances are used as components of a resist composition, and the method includes placing, into a container including a resin in at least a portion of an inner wall surface, the one or more solid substances and the solvent; and dissolving a portion of or an entirety of a solid content contained in the one or more solid substances, a method for producing a resist composition, a pattern forming method using a resist composition produced by the method for producing a resist composition, and a method for producing an electronic device.

### CROSS REFERENCE TO RELATED APPLICATION

This is a continuation of International Application No. PCT/JP2024/009320 filed on Mar. 11, 2024, and claims priority from Japanese Patent Application No. 2023-044470 filed on Mar. 20, 2023, the entire disclosure of which is incorporated herein by reference.

### BACKGROUND OF THE INVENTION

### 1. Field of the Invention

The present invention relates to a method for producing a solution, a method for producing a resist composition, a pattern forming method, and a method for producing an electronic device. More specifically, the present invention relates to a method for producing a solution that can be used to prepare a resist composition that can be suitably used in ultramicrolithography processes applicable to, for example, processes for producing ultra-LSIs (Large Scale Integrations) and high-capacity microchips, processes for producing nanoimprint molds, and processes for producing high-density information recording media, and other photofabrication processes, a method for producing a resist composition, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB), X-rays, extreme ultraviolet rays (EUV), or the like is also being developed. With this, resist compositions effectively sensitive to various actinic rays or radiations have been developed.

JP2016-14116A describes a method for producing a polymer for semiconductor lithography, the method having a step of using a solvent contained in a vessel having an inner wall surface that is formed of electrolytically polished stainless steel.

JP2016-79296A describes a method for producing a polymer for semiconductor lithography, the method including a step of feeding a liquid substance through a liquid feeding pipe formed by connecting together a plurality of pipe members, wherein a connecting member or the like formed of perfluoroelastomer is disposed at a point where pipe members are connected together in the liquid feeding pipe.

### SUMMARY OF THE INVENTION

Solid substances (substances that are solid) used as components of resist compositions may be used in the form of powder; however, in particular, substances that are less likely to be crystallized or that are deliquescent are used after being dissolved in solvents and turned into solutions.

In the case of preparing solutions by dissolving solid substances used as components of resist compositions in solvents or in the case of preparing resist compositions by dissolving solid substances used as components of resist compositions in solvents, stainless steel containers or glass containers have been used.

The inventors of the present invention performed studies and have found that resist compositions prepared using solutions prepared by the existing methods and resist compositions prepared by the existing methods tend to cause development defects when used for pattern formation.

An object of the present invention is to provide a method for producing a solution that can be used for preparing a resist composition that can suppress generation of development defects when used for pattern formation, a method for producing the resist composition, a pattern forming method using the resist composition produced by the method for producing the resist composition, and a method for producing an electronic device.

The inventors of the present invention have found that the following features can address the above-described object.

[1]

A method for producing a solution in which one or more solid substances are dissolved in a solvent,
the one or more solid substances are used as components of a resist composition, and
the method includes placing, into a container including a resin in at least a portion of an inner wall surface, the one or more solid substances and the solvent and dissolving a portion of or an entirety of a solid content contained in the one or more solid substances.
   [2]

The method for producing a solution according to [1], wherein the solvent includes at least one selected from the group consisting of a compound represented by a formula (1-1) below and a compound represented by a formula (1-2) below:

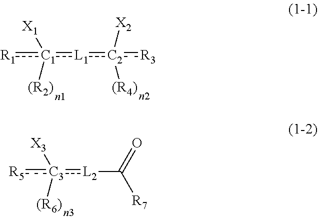

in the formula (1-1), X₁ and X₂ each independently represent a hydroxy group, an alkoxy group, an acyloxy group, —N(Rx)₂, —NRaCORb, a thiol group, or a thioalkoxy group;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
C₁ and C₂ each independently represent an sp³ carbon or an sp² carbon;
L₁ represents a single bond, a double bond, an aromatic carbon-carbon bond, or a linking group having 2 or less carbon atoms;
R₁ to R₄ each independently represent a hydrogen atom or an organic group;
at least two of X₁, X₂, R₁ to R₄, and L₁ may be bonded together to form a ring;
n1 represents 0 or 1, provided that, when C₁ is an sp² carbon, n1 is 0, and when C₁ is an sp³ carbon, n1 is 1; and
n2 represents 0 or 1, provided that, when C₂ is an sp² carbon, n2 is 0, and when C₂ is an sp³ carbon, n2 is 1,
in the formula (1-2), X₃ represents a hydroxy group, an alkoxy group, an acyloxy group, —N(Rx)₂, —NRaCORb, a thiol group, or a thioalkoxy group;
C₃ represents an sp³ carbon or an sp² carbon;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
L₂ represents a single bond, a double bond, an aromatic carbon-carbon bond, or a linking group having 2 or less carbon atoms;
R₅ and R₆ each independently represent a hydrogen atom or an organic group;
R₇ represents a hydrogen atom, an alkyl group, an aryl group, —OH, or —OR₈;
R₈ represents an organic group;
at least two of X₃, R₅ to R₈, and L₂ may be bonded together to form a ring; and
n3 represents 0 or 1, provided that, when C₃ is an sp² carbon, n3 is 0, and when C₃ is an sp³ carbon, n3 is 1.
   [3]

The method for producing a solution according to [1] or [2], wherein the solid substances include a compound having a salt structure.

[4]

The method for producing a solution according to [3], wherein the compound having a salt structure includes at least one selected from the group consisting of a compound represented by a formula (2-1) below, a compound represented by a formula (2-2) below, and a compound represented by a formula (2-3) below:

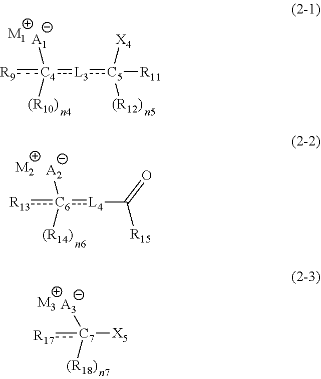

in the formula (2-1), M₁⁺ represents an organic cation;
A₁⁻ represents an acid residue;
X₄ represents a hydroxy group, an alkoxy group, an acyloxy group, —N(Rx)₂, —NRaCORb, a thiol group, or a thioalkoxy group;
C₄ and C₅ each independently represent an sp³ carbon or an sp² carbon;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
L₃ represents a single bond, a double bond, an aromatic carbon-carbon bond, or a linking group having 2 or less carbon atoms;
R₉ to R₁₂ each independently represent a hydrogen atom or an organic group;
at least two of X₄, R₉ to R₁₂, and L₃ may be bonded together to form a ring;
n4 represents 0 or 1, provided that, when C₄ is an sp² carbon, n4 is 0, and when C₄ is an sp³ carbon, n4 is 1; and
n5 represents 0 or 1, provided that, when C₅ is an sp² carbon, n5 is 0, and when C₅ is an sp³ carbon, n5 is 1,
in the formula (2-2), M₂⁺ represents an organic cation;
A₂⁻ represents an acid residue;
L₄ represents a single bond, a double bond, an aromatic carbon-carbon bond, or a linking group having 2 or less carbon atoms;
C₆ represents an sp³ carbon or an sp² carbon;
R₁₃ and R₁₄ each independently represent a hydrogen atom or an organic group;
R¹⁵ represents a hydrogen atom, an alkyl group, an aryl group, —OH, or —OR₁₆,
R₁₆ represents an organic group;
at least two of R₁₃ to R₁₆ and L₄ may be bonded together to form a ring; and
n6 represents 0 or 1, provided that, when C₆ is an sp² carbon, n6 is 0, and when C₆ is an sp³ carbon, n6 is 1,
in the formula (2-3), M₃⁺ represents an organic cation;
A₃⁻ represents an acid residue;
X₅ represents a hydroxy group, an alkoxy group, an acyloxy group, —N(Rx)₂, —NRaCORb, a thiol group, or a thioalkoxy group;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
C₇ represents an sp³ carbon or an sp² carbon;
R₁₇ and R₁₈ each independently represent a hydrogen atom or an organic group; at least two of X₅, R₁₇, and R₁₈ may be bonded together to form a ring; and
n7 represents 0 or 1, provided that, when C₇ is an sp² carbon, n7 is 0, and when C₇ is an sp³ carbon, n7 is 1.
   [5]

The method for producing a solution according to any one of [1] to [4], wherein the container is a portable container.

[6]

The method for producing a solution according to any one of [1] to [5], wherein the container has a volume of 1 L or more.

[7]

A method for producing a resist composition, the method including:
placing, into a container including a resin in at least a portion of an inner wall surface, one or more solid substances used as components of a resist composition and a solvent; and
dissolving a portion of or an entirety of a solid content contained in the one or more solid substances.
   [8]

A method for producing a resist composition, the method including using a solution produced by the method for producing a solution according to any one of [1] to [6], to prepare a resist composition.

[9]

A pattern forming method including:
forming a resist film using a resist composition produced by the method for producing a resist composition according to [7] or [8];
exposing the resist film; and
developing the exposed resist film using a developer.
   [10]

A method for producing an electronic device, the method including the pattern forming method according to [9].

The present invention can provide a method for producing a solution that can be used for preparing a resist composition that can suppress generation of development defects when used for pattern formation, a method for producing the resist composition, a pattern forming method using the resist composition produced by the method for producing the resist composition, and a method for producing an electronic device.

### DESCRIPTION OF THE PREFERRED EMBODIMENTS

Hereinafter, the present invention will be described in detail.

Features may be described below on the basis of representative embodiments of the present invention; however, the present invention is not limited to such embodiments.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, soft X-rays, or an electron beam (EB: Electron Beam).

In this Specification, “light” means an actinic ray or a radiation.

In this Specification, “exposure” includes, unless otherwise specified, not only exposure using the emission line spectrum of a mercury lamp, far ultraviolet rays represented by excimer lasers, extreme ultraviolet rays, X-rays, EUV, or the like, but also patterning using a corpuscular beam such as an electron beam or an ion beam.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M, manufactured by Tosoh Corporation, column temperature: 40° C., flow rate: 1.0 mL/min, detector: differential refractive index detector (Refractive Index Detector)).

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified. Examples of the substituent include monovalent non-metallic atomic groups except for the hydrogen atom and, for example, can be selected from the group consisting of the following Substituents T.

### Substituents T

Examples of the substituents T include halogen atoms such as a fluorine atom, a chlorine atom, a bromine atom, and an iodine atom; alkoxy groups such as a methoxy group, an ethoxy group, and a tert-butoxy group; cycloalkyloxy groups; aryloxy groups such as a phenoxy group and a p-tolyloxy group; alkoxycarbonyl groups such as a methoxycarbonyl group and a butoxycarbonyl group; cycloalkyloxycarbonyl groups; aryloxycarbonyl groups such as a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; a sulfanyl group; alkylsulfanyl groups such as a methylsulfanyl group and a tert-butylsulfanyl group; arylsulfanyl groups such as a phenylsulfanyl group and a p-tolylsulfanyl group; alkyl groups; alkenyl groups; cycloalkyl groups; aryl groups; aromatic heterocyclic groups; a hydroxy group; a carboxy group; a formyl group; a sulfo group; a cyano group; alkylaminocarbonyl groups; arylaminocarbonyl groups; a sulfonamide group; a silyl group; an amino group; and a carbamoyl group. When such a substituent can additionally have one or more substituents, a group having, as the additional substituents, one or more substituents selected from the group consisting of the substituents described above (such as a monoalkylamino group, a dialkylamino group, an arylamino group, or a trifluoromethyl group) is also included in examples of the substituents T.

In this Specification, the bonding directions of divalent groups described are not limited unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H dissociation free energy in an aqueous solution based on a thermodynamic cycle. The H dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density function theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

In this Specification, the solid content of the resist composition means a component included in the resist composition and a component included in a resist film formed using the resist composition. Solvents are not the “solid content”. As long as a component is included in the resist composition and the component is also included in the resist film formed using the resist composition, even when it has a property of being liquid, it is regarded as the “solid component”. “Total solid content” refers to all the solid contents.

### Method for Producing Solution

The method for producing a solution of the present invention is
a method for producing a solution in which one or more solid substances are dissolved in a solvent,
the one or more solid substances being used as components of a resist composition,
the method including a step of placing, into a container including a resin in at least a portion of an inner wall surface, the one or more solid substances and the solvent, and dissolving a portion of or an entirety of a solid content formed of the one or more solid substances.

The one or more solid substances used in the method for producing a solution of the present invention are also referred to as “solid substance (U)”.

The solvent used in the method for producing a solution of the present invention is also referred to as “solvent(S)”.

The solution produced by the method for producing a solution of the present invention is also referred to as “solution (Z)”.

The mechanism by which the resist composition prepared using the solution produced by the method for producing a solution of the present invention can suppress generation of development defects when used for pattern formation has not been clarified, but is inferred by the inventors of the present invention as follows. However, the present invention is not limited at all by the following inferred mechanism.

As described above, existing resist compositions prepared using solutions prepared in glass or stainless steel containers cause generation of a large number of development defects when used for pattern formation. The inventors of the present invention consider that these development defects are caused by scale-like dirt formed on the inner wall surfaces of glass or stainless steel containers and containing silicon as the main component (reference literature: International Journal of Automotive Engineering, 2020, 11(2), 57-63). They presumed that the scale-like dirt is less likely to form on resin surfaces and have found that preparation of a solution in a container including a resin in at least a portion of the inner wall surface can suppress generation of development defects.

The present invention provides considerable advantages particularly in the case of producing a solution by dissolving a compound having a salt structure (salt compound) in a solvent or in the case of producing a solution using a solvent that is a polar solvent; they consider that this is attributable to the reason that the scale-like dirt is likely to dissolve in solutions in the presence of the salt compound or the polar solvent.

In the method for producing a solution of the present invention, in the step of dissolving a solid substance (U) in a solvent(S) (solution-forming step), the solid substance (U), which is typically a dried powder (dry powder) or a powder wetted with a solvent (wet powder), is dissolved in the solvent(S). This provides a solution (Z) in which the solid substance (U) is dissolved in the solvent(S).

In the solution-forming step, the solid substance (U) and the solvent(S) are placed into a container including a resin in at least a portion of the inner wall surface, and a portion of or the entirety of the solid content formed of the solid substance (U) is dissolved in the solvent(S) in the container to obtain the solution (Z).

In the solution-forming step, when the solid substance (U) is formed of a single solid substance alone, a portion of or the entirety of the single solid substance may be dissolved in the solvent(S). In the solution-forming step, when the solid substance (U) includes two or more solid substances, a portion of or the entirety of at least one solid substance thereof may be dissolved in the solvent(S).

When the solvent is water, the completion of dissolution of the solid substance in water can be confirmed, for example, by a method in accordance with the shake flask method described in OECD Test Guideline Test No. 105: Water Solubility. When the solvent is an organic solvent, the completion of dissolution of the solid substance in the organic solvent can be confirmed by the above-described method in which the water is replaced by the organic solvent. When the solvent is a mixed solvent of water and an organic solvent, the completion of dissolution of the solid substance in the mixed solvent of water and the organic solvent can be confirmed by the above-described method in which the water is replaced by the mixed solvent of water and the organic solvent.

The temperature at which the solid substance is dissolved in the solvent is not particularly limited, but is preferably 0 to 90° C., more preferably 10 to 70° C., and particularly preferably 15 to 50° C.

At the time when the solid substance is dissolved in the solvent, the solution may be stirred. The stirring can be performed using a stirring impeller (stirring blade), a magnetic stirrer, a rotary mixer, or the like. In the case of using a stirring impeller and a magnetic stirrer, the surfaces of the stirring impeller and the stirrer tip that contact the solution are preferably covered with a resin. The resin may be a resin similar to a resin used for the container described later. The stirring impeller may be, for example, a paddle impeller, a pitched paddle impeller, a disk turbine impeller, a propeller impeller, a three-blade retreated impeller, an anchor impeller, a helical ribbon impeller, a screw impeller, a MAXBLEND impeller, a Super Mix impeller, a FULLZONE impeller, or the like.

### Container

In the present invention, a container including a resin in at least a portion of the inner wall surface is used.

The container including a resin in at least a portion of the inner wall surface refers to a container in which at least a portion of the inner wall surface is formed of a resin.

The container may be a container entirely formed of a resin (resin container), or may be a container formed of a material other than resins in which at least a portion of the inner wall surface is covered with a resin. Examples of the material other than resins include glass and metal.

The container in which at least a portion of the inner wall surface is covered with a resin is preferably a glass or stainless steel container in which at least a portion of the inner wall surface is covered with a resin.

The container that is in a state of containing the solution and being left at rest preferably includes the resin for 50 to 100%, more preferably for 80 to 100%, of the inner wall surface that contacts the solution.

The resin used for the container is not particularly limited, and examples thereof include polyethylene, polypropylene, polyester, polystyrene, polyvinyl chloride, polytetrafluoroethylene (PTFE), ethylene-tetrafluoroethylene copolymers, perfluoroalkoxy fluororesins, perfluoroethylene-propene copolymers, and polyvinylidene fluoride. Examples of the perfluoroalkoxy fluororesins include copolymers of tetrafluoroethylene and perfluoroalkoxyethylene (perfluoroalkoxyalkanes, PFA).

The size and shape of the container are not particularly limited. The volume of the container is not particularly limited and may be, for example, 1 L or more. The volume of the container may be, for example, 200 L or less, may be 100 L or less, or may be 30 L or less.

The container employed can also be a portable container. The portable container is a container that is not fixed to, for example, facilities, apparatuses, or buildings, and is sealable.

The use of the portable container eliminates the necessity of performing, for example, opening and transfer of the solution after the formation of the solution and enables, for example, transport and storage of the solution, to thereby prevent entry of impurities and the like into the solution.

The portable container may have a shape such as a drum, a pail, a square can, a flat can, a kerosene can, a 18-liter can, a gallon bottle, or a screw-top bottle.

The volume of the portable container is not particularly limited, but is preferably 1 L or more. The volume of the portable container is preferably 200 L or less, more preferably 100 L or less, and particularly preferably 30 L or less.

The portable container may be a resin container, or may be a container in which a portion of the inner wall of a glass or metal container is covered with a resin, but is preferably a resin container.

### Solvent

The solvent (solvent(S)) used in the present invention is not particularly limited.

The solvent(S) may be water, may be an organic solvent, or may be a mixed solvent of water and an organic solvent. Examples of the organic solvent include ketone-based solvents, ester-based solvents, alcohol-based solvents, amide-based solvents, ether-based solvents, hydrocarbon-based solvents, sulfoxide-based solvents, sulfone-based solvents, nitrile-based solvents, and carbonate-based solvents.

Examples of the solvent(S) include water, methanol, ethanol, n-propanol, isopropanol, 1-butanol, 2-butanol, isobutanol, 2-ethylhexanol, propylene glycol, ethylene glycol, amyl alcohol, 1,3-butylene glycol, glycerol, diacetone alcohol, diethylene glycol, cyclohexanol, dipropylene glycol, methyl isobutyl carbinol, acetone, methyl ethyl ketone, methyl propyl ketone, methyl isobutyl ketone, methyl isoamyl ketone, diisobutyl ketone, cyclohexanone, cyclopentanone methyl amyl ketone, isophorone, tetrahydrofuran, ethylene glycol monoethyl ether, diethylene glycol monoethyl ether, diethylene glycol monobutyl ether, propylene glycol monomethyl ether, dipropylene glycol n-butyl ether, dipropylene glycol n-propyl ether, dipropylene glycol dimethyl ether, dipropylene glycol methyl ether, tripropylene glycol n-butyl ether, tripropylene glycol methyl ether, propylene glycol n-butyl ether, propylene glycol n-propyl ether, propylene glycol phenyl ether, methyl lactate, ethyl lactate, n-propyl acetate, isopropyl acetate, n-butyl acetate, isobutyl acetate, amyl acetate, isopentyl acetate, acid 2-ethylhexyl, ethyl propionate, n-butyl propionate, n-pentyl propionate, n-butyl lactate, 1,3-butylene glycol diacetate, 3-methoxybutyl acetate, 3-methoxybutanol, cyclohexanol acetate, ethylene glycol monoethyl ether acetate, ethylene glycol monobutyl ether acetate, ethylene glycol monomethyl ether acetate, diethylene glycol monoethyl ether acetate, diethylene glycol monobutyl ether acetate, dipropylene glycol methyl ether acetate, propylene glycol monomethyl ether acetate, propylene glycol diacetate, triacetin, n-butyl acetoacetate, isobutyl isobutyrate, γ-butyrolactone, n-methyl-2-pyrrolidone, dimethylformamide, dimethylacetamide, dimethyl sulfoxide, sulfolane, hexane, cyclohexane, heptane, D-limonene, xylene, and toluene.

The solvent(S) preferably includes a polar solvent.

The solvent(S) preferably includes at least one selected from the group consisting of a compound represented by a formula (1-1) below and a compound represented by a formula (1-2) below.

Relative to the total mass of the solvent(S), the content of at least one selected from the group consisting of a compound represented by the formula (1-1) below and a compound represented by the formula (1-2) below is preferably 20 mass % or more and 100 mass % or less, more preferably 50 mass % or more and 100 mass % or less, and still more preferably 70 mass % or more and 100 mass % or less.

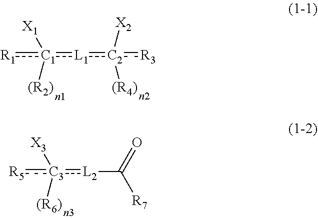

In the formula (1-1), X₁ and X₂ each independently represent a hydroxy group, an alkoxy group, an acyloxy group, —N(Rx)₂, —NRaCORb, a thiol group, or a thioalkoxy group, Rx represent a hydrogen atom or an organic group, two Rx may be the same or different, Ra represents a hydrogen atom or an organic group, Rb represents a hydrogen atom, an alkyl group, a cycloalkyl group, an aryl group, an aralkyl group, an alkoxy group, —N(Rc)₂, or a thioalkoxy group, Rc represent a hydrogen atom or an organic group, two Rc may be the same or different, C₁ and C₂ each independently represent an sp³ carbon or an sp² carbon, L₁ represents a single bond, a double bond, an aromatic carbon-carbon bond, or a linking group having 2 or less carbon atoms, R₁ to R₄ each independently represent a hydrogen atom or an organic group, at least two of X₁, X₂, R₁ to R₄, and L₁ may be bonded together to form a ring; n1 represents 0 or 1, provided that, when C₁ is an sp² carbon, n1 is 0 or, when C₁ is an sp³ carbon, n1 is 1; n2 represents 0 or 1, provided that, when C₂ is an sp² carbon, n2 is 0 or, when C₂ is an sp³ carbon, n2 is 1.

In the formula (1-2), X₃ represents a hydroxy group, an alkoxy group, an acyloxy group, —N(Rx)₂, —NRaCORb, a thiol group, or a thioalkoxy group, C₃ represents an sp³ carbon or an sp² carbon, Rx represent a hydrogen atom or an organic group, two Rx may be the same or different, Ra represents a hydrogen atom or an organic group, Rb represents a hydrogen atom, an alkyl group, a cycloalkyl group, an aryl group, an aralkyl group, an alkoxy group, —N(Rc)₂, or a thioalkoxy group, Rc represent a hydrogen atom or an organic group, two Rc may be the same or different, L₂ represents a single bond, a double bond, an aromatic carbon-carbon bond, or a linking group having 2 or less carbon atoms, R₅ and R₆ each independently represent a hydrogen atom or an organic group, R₇ represents a hydrogen atom, an alkyl group, an aryl group, —OH, or —OR₈, R₈ represents an organic group, at least two of X₃, R₅ to R₈, and L₂ may be bonded together to form a ring; n3 represents 0 or 1, provided that, when C₃ is an sp² carbon, n3 is 0 or, when C₃ is an sp³ carbon, n3 is 1.

Note that the following notations in the formula (1-1) and (1-2) represent a single bond, a double bond, or an aromatic carbon-carbon bond. The same applies to formulas (2-1), (2-2), and (2-3) described later.

[symbol]

In the formula (1-1), X₁ and X₂ each independently represent a hydroxy group, an alkoxy group, an acyloxy group, —N(Rx)₂, —NRaCORb, a thiol group, or a thioalkoxy group. Rx represent a hydrogen atom or an organic group. Two Rx may be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different.

For X₁ and X₂, the number of carbon atoms of the alkyl group included in the alkoxy group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. The alkyl group may have a substituent. The alkyl groups included in the thioalkoxy groups represented by X₁ and X₂, and the alkyl groups when the acyloxy groups represented by X₁ and X₂ are alkylcarbonyloxy groups are also the same as described above.

When the acyloxy groups represented by X₁ and X₂ are arylcarbonyloxy groups, such an aryl group may be either monocyclic or polycyclic (for example, 2 to 6 rings). The number of carbon atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. The aryl group may have a substituent.

For X₁ and X₂, when the acyloxy group is a cycloalkylcarbonyloxy group, the cycloalkyl group may be monocyclic or polycyclic, and is preferably a cycloalkyl group having 3 to 20 carbon atoms, more preferably a cycloalkyl group having 4 to 15 carbon atoms, and still more preferably a cycloalkyl group having 5 to 10 carbon atoms. The cycloalkyl group may be, for example, a cyclopentyl group, a 1-methylcyclopentyl group, a cyclohexyl group, an adamantyl group, a 1-ethyladamantyl group, a norbornyl group, a tetracyclodecanyl group, or a tetracyclododecanyl group. The cycloalkyl group may have a substituent. One of the methylene groups constituting the cycloalkane ring of the cycloalkyl group may be replaced by a heteroatom such as an oxygen atom, a group having a heteroatom such as a carbonyl group, a sulfonyl group, or an ester bond, or a vinylidene group. In the cycloalkyl group, one or more ethylene groups constituting the cycloalkane ring may be replaced by a vinylene group.

Rx represent a hydrogen atom or an organic group. The organic groups represented by Rx are not particularly limited, but may be, for example, an alkyl group, a cycloalkyl group, an aryl group, or a group that is a combination of the foregoing.

The alkyl groups represented by Rx may be linear or branched, are preferably an alkyl group having 1 to 12 carbon atoms, more preferably an alkyl group having 1 to 6 carbon atoms, and still more preferably an alkyl group having 1 to 3 carbon atoms. Examples of the alkyl groups represented by Rx include a methyl group, an ethyl group, an n-propyl group, an isopropyl group, an n-butyl group, an isobutyl group, a sec-butyl group, and a t-butyl group. The alkyl groups represented by Rx may have a substituent.

The cycloalkyl groups represented by Rx may be monocyclic or polycyclic, and are preferably a cycloalkyl group having 3 to 20 carbon atoms, more preferably a cycloalkyl group having 4 to 15 carbon atoms, and still more preferably a cycloalkyl group having 5 to 10 carbon atoms. Examples of the cycloalkyl groups represented by Rx include a cyclopentyl group, a 1-methylcyclopentyl group, a cyclohexyl group, an adamantyl group, a 1-ethyladamantyl group, a norbornyl group, a tetracyclodecanyl group, and a tetracyclododecanyl group. The cycloalkyl groups represented by Rx may have a substituent. In the cycloalkyl groups represented by Rx, one of the methylene groups constituting such a cycloalkane ring may be replaced by a heteroatom such as an oxygen atom, a group having a heteroatom such as a carbonyl group, a sulfonyl group, or an ester bond, or a vinylidene group. In the cycloalkyl groups represented by Rx, one or more ethylene groups constituting such a cycloalkane ring may be replaced by a vinylene group.

The aryl groups represented by Rx are preferably an aryl group having 6 to 20 carbon atoms, more preferably an aryl group having 6 to 15 carbon atoms, and still more preferably an aryl group having 6 to 10 carbon atoms. The aryl groups represented by Rx are preferably a phenyl group, a naphthyl group, or an anthryl group, more preferably a phenyl group or a naphthyl group, and still more preferably a phenyl group. The aryl groups represented by Rx may have a substituent.

Ra represents a hydrogen atom or an organic group. The description, specific examples, and preferred ranges of Ra are the same as those described above for Rx.

Rb represents a hydrogen atom, an alkyl group, a cycloalkyl group, an aryl group, an aralkyl group, an alkoxy group, —N(Rc)₂, or a thioalkoxy group.

The descriptions, specific examples, and preferred ranges of the alkyl group, cycloalkyl group, and aryl group represented by Rb are the same as those described above for Rx.

In the alkoxy group and thioalkoxy group represented by Rb, the alkyl group is also the same as described above.

The aralkyl group represented by Rb may be a group in which the above-described aryl group represented by Rb is bonded to the above-described alkyl group represented by Rb. Examples of the aralkyl group include a benzyl group, a phenethyl group, a naphthylmethyl group, a naphthylethyl group, and a naphthylbutyl group.

Rc represent a hydrogen atom or an organic group. The description, specific examples, and preferred ranges of Rc are the same as those described above for Rx.

In the formula (1-1), L₁ represents a single bond, a double bond, an aromatic carbon-carbon bond, or a linking group having 2 or less carbon atoms.

An embodiment in which L₁ is an aromatic carbon-carbon bond may be, for example, an embodiment in which, in the formula (1-1), C₁ and C₂ are sp² carbons, n1 and n2 are 0, and R¹ and R₃ are bonded together to form an aromatic ring.

The linking group having 2 or less carbon atoms may be either a linking group having 0 carbon atoms, a linking group having 1 carbon atom, or a linking group having 2 carbon atoms.

Examples of linking group having 0 carbon atoms and represented by L₁ include —O—, —NH—, —S—, —SO—, and —SO₂—.

Examples of the linking group having 1 carbon atom and represented by L₁ include —CO—, —CH₂—, and —CH₂O—.

Examples of the linking group having 2 carbon atoms and represented by L₁ include-CH₂CH₂—, —CH═CH—, and —CH₂CH₂O—.

The linking group having 2 or less carbon atoms and represented by L₁ may have a substituent. When the linking group having 2 or less carbon atoms and represented by L₁ has a substituent, the number of carbon atoms of the substituent is not included in the number of carbon atoms of L₁. The number of carbon atoms of the substituent is not particularly limited, but is preferably 6 or less. The above-described specific examples of L₁ in which one or more hydrogen atoms are substituted with substituents are also included in the specific examples of L₁. For example, —NRd-, —C(Rd)₂-, —C(Rd)₂O—, —C(Rd)₂C (Rd)₂-, —C(Rd)═C(Rd)-, and —C(Rd)₂C(Rd)₂O— are also included in the specific examples of L₁. Rd represents a hydrogen atom or a substituent, preferably represents a hydrogen atom or a substituent having 6 or less carbon atoms, and more preferably represents a hydrogen atom, an alkyl group, a cycloalkyl group, an aryl group, or an acyl group. When a plurality of Rd are present, the plurality of Rd may be the same or different. The descriptions, specific examples, and preferred ranges of the alkyl group, cycloalkyl group, and aryl group represented by Rd are the same as those described above for Rx. When the acyl group represented by Rd is an alkyl carbonyl group, the alkyl group is also the same as described above. When the acyl group represented by Rd is a cycloalkyl carbonyl group, the cycloalkyl group is also the same as described above. When the acyl group represented by Rd is an aryl carbonyl group, the aryl group is also the same as described above.

R₁ to R₄ in the formula (1-1) each independently represent a hydrogen atom or an organic group. For R₁ to R₄, the organic group is not particularly limited, but may be, for example, an alkyl group, a cycloalkyl group, or an aryl group. The descriptions, specific examples, and preferred ranges of R¹ to R⁴ are the same as those described above for Rx.

At least two of X₁, X₂, R₁ to R₄, and L₁ in the formula (1-1) may be bonded together to form a ring. The ring formed by bonding together at least two of X₁, X₂, R₁ to R₄, and L₁ may be an aromatic ring (for example, a benzene ring, a naphthalene ring, or a pyridine ring), may be a non-aromatic ring (for example, a cyclohexane ring, a tetrahydropyran ring, or a pyran ring), or may be a ring in which a non-aromatic ring and an aromatic ring are fused together. The number of ring-member atoms of the ring is not particularly limited, but is, for example, preferably 5 to 20. The ring may have a substituent.

In the formula (1-2), X₃ represents a hydroxy group, an alkoxy group, an acyloxy group, —N(Rx)₂, —NRaCORb, a thiol group, or a thioalkoxy group. Rx represent a hydrogen atom or an organic group. Two Rx may be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different.

The description, specific examples, and preferred ranges of X₃ are the same as those described above for X₁ and X₂ in the formula (1-1).

When X₃ represents —N(Rx)₂, the description, specific examples, and preferred ranges of Rx are the same as those described above for Rx in the description of the formula (1-1).

When X₃ represents —NRaCORb, the descriptions, specific examples, and preferred ranges of Ra and Rb are the same as those described above for Ra and Rb in the description of the formula (1-1).

When Rb represents —N(Rc)₂, the description, specific examples, and preferred ranges of Rc are the same as those described above for Rc in the description of the formula (1-1).

In the formula (1-2), L₂ represents a single bond, a double bond, an aromatic carbon-carbon bond, or a linking group having 2 or less carbon atoms. The description, specific examples, and preferred ranges of L₂ are the same as those described above for L₁ in the formula (1-1).

In the formula (1-2), R₅ and R₆ each independently represent a hydrogen atom or an organic group. The descriptions, specific examples, and preferred ranges of R₅ and R₆ are the same as those described above for Rx in the description of the formula (1-1).

In the formula (1-2), R₇ represents a hydrogen atom, an alkyl group, an aryl group, —OH, or —OR₈. R₈ represents an organic group. The descriptions, specific examples, and preferred ranges of the alkyl group and aryl group represented by R₇ are respectively the same as those described above for Rx in the description of the formula (1-1). The description, specific examples, and preferred ranges of the organic group represented by R₅ are the same as those described above for Rx in the description of the formula (1-1).

At least two of X₃, R₅ to R₈, and L₂ in the formula (1-2) may be bonded together to form a ring. The descriptions, specific examples, and preferred ranges of the ring formed by bonding together at least two of X₃, R₅ to R₈, and L₂ are the same as those described above for the ring formed by bonding together at least two of X₁, X₂, R₁ to R₄, and L₁ in the formula (1-1).

The solvent(S) may be formed of a single solvent or may be a mixed solvent including two or more solvents.

The solid substance content (solid-content concentration) in the solution produced by the method for producing a solution of the present invention is not particularly limited, and, for example, may be 0.1 to 80 mass %, may be 0.5 to 50 mass %, or may be 0.1 to 30 mass %.

### Solid Substance

The solid substance used in the present invention (solid substance (U)) is used as a component of the resist composition.

The solid substance is not particularly limited as long as it is used as a component of the resist composition and it forms a solid content. That is, when a solution produced by the method for producing a solution according to the present invention is used to prepare a resist composition, the solid substance means a component included in the resist composition and a component included in a resist film formed using the resist composition. Solvents are not the “solid substance”. Even when the substance has a property of being liquid, as long as it serves as a component included in the resist composition and serves as a component included in a resist film formed using the resist composition, it is regarded as a “solid substance”.

Examples of the solid substance include nonionic low-molecular-weight compounds, compounds having a salt structure (salt compounds), and polymers. Specific examples of the solid substance include a compound that generates an acid upon irradiation with an actinic ray or a radiation (photoacid generator), an acid diffusion control agent, a resin (such as an acid-decomposable resin or a crosslinkable resin), a crosslinking agent, and a surfactant. The photoacid generator is a compound that is decomposed upon irradiation with an actinic ray or a radiation to generate an acid, and the generated acid serves as an active species and can serve as a catalyst for a deprotection reaction (leaving reaction of a leaving group), cationic polymerization, a crosslinking reaction, or the like of the acid-decomposable resin. The acid diffusion control agent acts as a quencher that traps the acid generated from the photoacid generator or the like and suppresses the reaction of the acid-decomposable resin in the unexposed regions due to the excess of generated acid.

### Salt Compound

The solid substance (U) preferably includes a salt compound.

The salt compound may be a photoacid generator or may be an acid diffusion control agent.

The salt compound may be in the form of a low-molecular compound, or may be in the form of being incorporated into a portion of a polymer. Alternatively, the form of a low-molecular-weight compound and the form of being incorporated into a portion of a polymer may be used in combination.

When the salt compound is in the form of a low-molecular compound, the molecular weight of the salt compound is preferably 5000 or less, more preferably 4000 or less, and still more preferably 3000 or less. The lower limit of the molecular weight of the salt compound is not particularly limited, but is preferably 100 or more.

The salt compound is preferably in the form of a low-molecular-weight compound.

The salt compound may be, for example, a compound represented by “M⁺X⁻” (onium salt), and is preferably a compound that generates an acid upon exposure. Examples of the acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl) imidic acids, and tris(alkylsulfonyl) methide acids.

In the compound represented by “M⁺X⁻”, M⁺ represents an organic cation. The organic cation represented by M⁺ is not particularly limited, but is preferably a cation represented by the following formula (ZaI) (hereinafter also referred to as “cation (ZaI)”) or a cation represented by the following formula (ZaII) (hereinafter also referred to as “cation (ZaII)”).

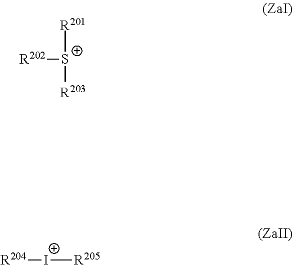

In the formula (ZaI), R²⁰¹, R²⁰², and R²⁰³ each independently represent an organic group.

For R²⁰¹, R²⁰², and R²⁰³, the number of carbon atoms of the organic group is preferably 1 to 30, and more preferably 1 to 20. Of R²⁰¹ to R²⁰³, two may be bonded together to form a ring structure and the ring may include an oxygen atom, a sulfur atom, an ester group, an amide group, or a carbonyl group. Examples of the group formed by bonding together two of R²⁰¹ to R²⁰³ include alkylene groups (such as a butylene group and a pentylene group), and —CH₂—CH₂—O—CH₂—CH₂—.

For R²⁰¹, R²⁰², and R²⁰³, the organic group is preferably an alkyl group, a cycloalkyl group, an aryl group, or a heteroaryl group.

The alkyl group may be either linear or branched. The number of carbon atoms of the alkyl group is not particularly limited, but is preferably 1 to 10, and more preferably 1 to 5. Examples of the alkyl group include a methyl group, an ethyl group, an n-propyl group, an isopropyl group, an n-butyl group, an isobutyl group, and a t-butyl group.

The number of carbon atoms of the cycloalkyl group is not particularly limited, but is preferably 3 to 20, and more preferably 5 to 15. The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group.

The aryl group is preferably an aryl group having 6 to 20 carbon atoms, more preferably an aryl group having 6 to 15 carbon atoms, still more preferably a phenyl group or a naphthyl group, and particularly preferably a phenyl group.

The heteroaryl group is preferably a heteroaryl group having 3 to 20 carbon atoms. The heteroaryl group preferably includes at least one heteroatom selected from the group consisting of an oxygen atom, a sulfur atom, and a nitrogen atom. Examples of the heteroaryl group include a pyrrolyl group, a furanyl group, a thiophenyl group, an indolyl group, a benzofuranyl group, and a benzothiophenyl group.

In the formula (ZaII), R²⁰⁴ and R²⁰⁵ each independently represent an aryl group, an alkyl group, or a cycloalkyl group.

For R²⁰⁴ and R²⁰⁵, the aryl group is preferably a phenyl group or a naphthyl group, and more preferably a phenyl group. For R²⁰⁴ and R²⁰⁵, the aryl group may be an aryl group having a heterocycle having an oxygen atom, a nitrogen atom, a sulfur atom, or the like. Examples of the skeleton of the aryl group having a heterocycle include pyrrole, furan, thiophene, indole, benzofuran, and benzothiophene.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. For R²⁰⁴ and R²⁰⁵, substituents are also preferably provided independently as appropriate combinations of substituents to form acid-decomposable groups.

The following are non-limiting specific examples of the cation represented by M⁺.

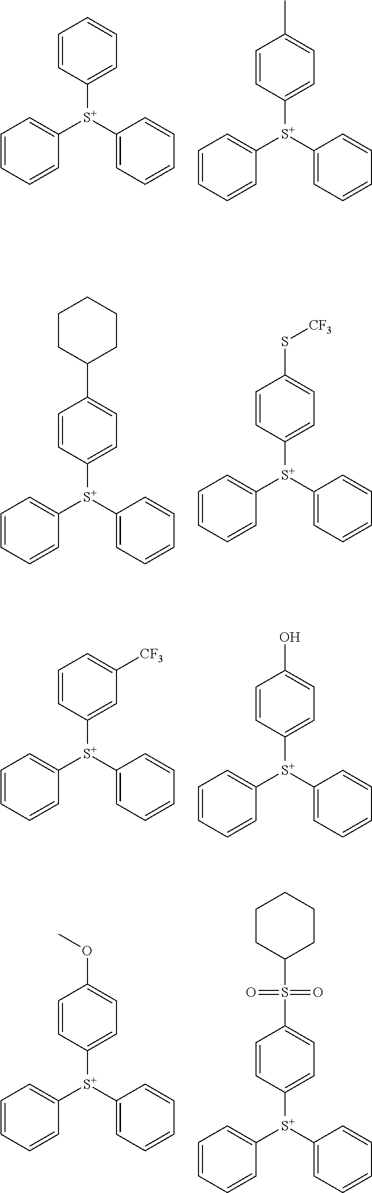

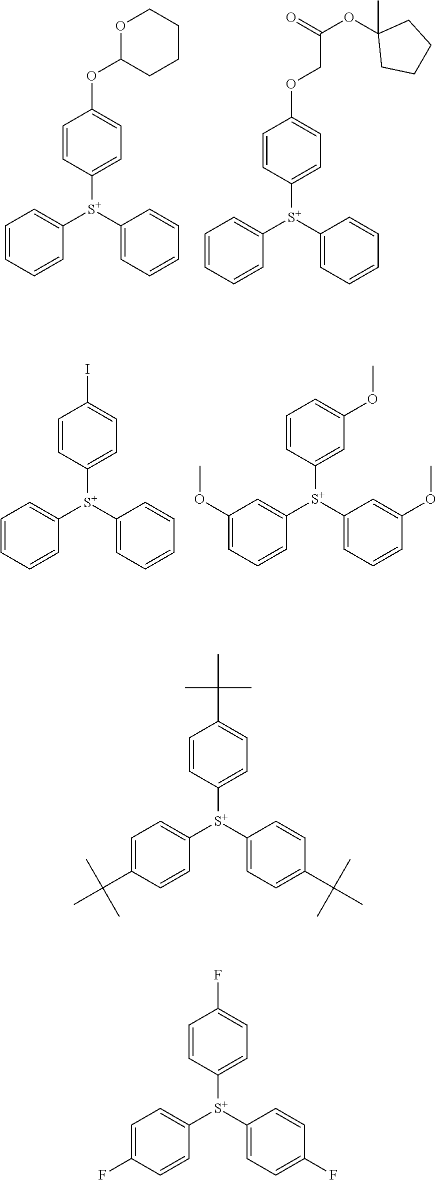 [SMILES: c1ccc([S+](c2ccccc2)c2ccc(OC3CCCCO3)cc2)cc1 ; CC1(OC(=O)COc2ccc([S+](c3ccccc3)c3ccccc3)cc2)CCCC1 ; Ic1ccc([S+](c2ccccc2)c2ccccc2)cc1 ; COc1cccc([S+](c2cccc(OC)c2)c2cccc(OC)c2)c1 ; CC(C)(C)c1ccc([S+](c2ccc(C(C)(C)C)cc2)c2ccc(C(C)(C)C)cc2)cc1 ; Fc1ccc([S+](c2ccc(F)cc2)c2ccc(F)cc2)cc1]

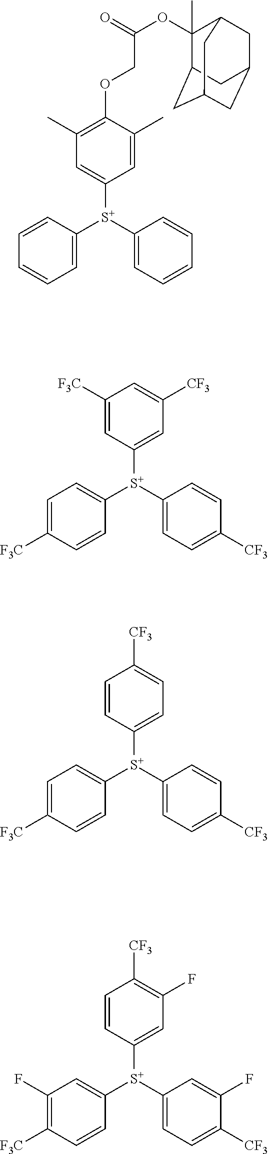 [SMILES: Cc1cc([S+](c2ccccc2)c2ccccc2)cc(C)c1OCC(=O)OC1(C)C2CC3CC(C2)CC1C3 ; FC(F)(F)c1ccc([S+](c2ccc(C(F)(F)F)cc2)c2cc(C(F)(F)F)cc(C(F)(F)F)c2)cc1 ; FC(F)(F)c1ccc([S+](c2ccc(C(F)(F)F)cc2)c2ccc(C(F)(F)F)cc2)cc1 ; Fc1cc([S+](c2ccc(C(F)(F)F)c(F)c2)c2ccc(C(F)(F)F)c(F)c2)ccc1C(F)(F)F]

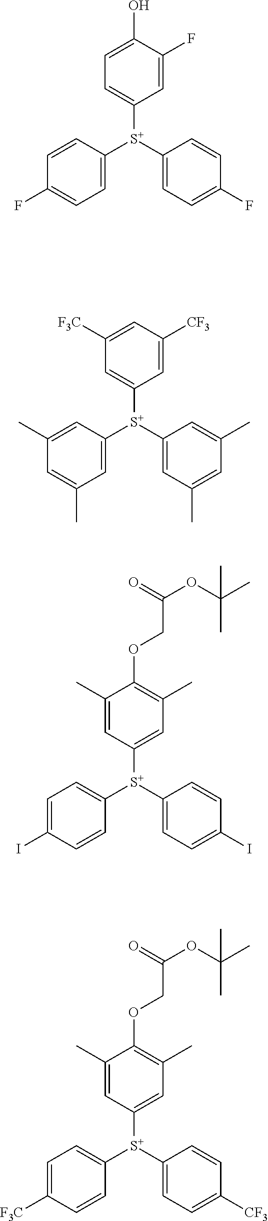

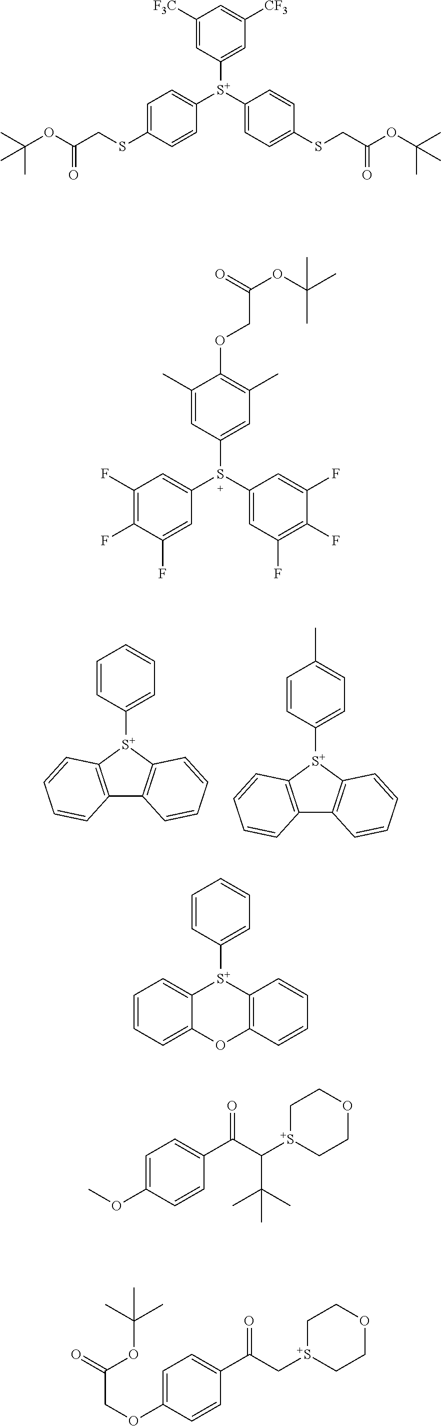

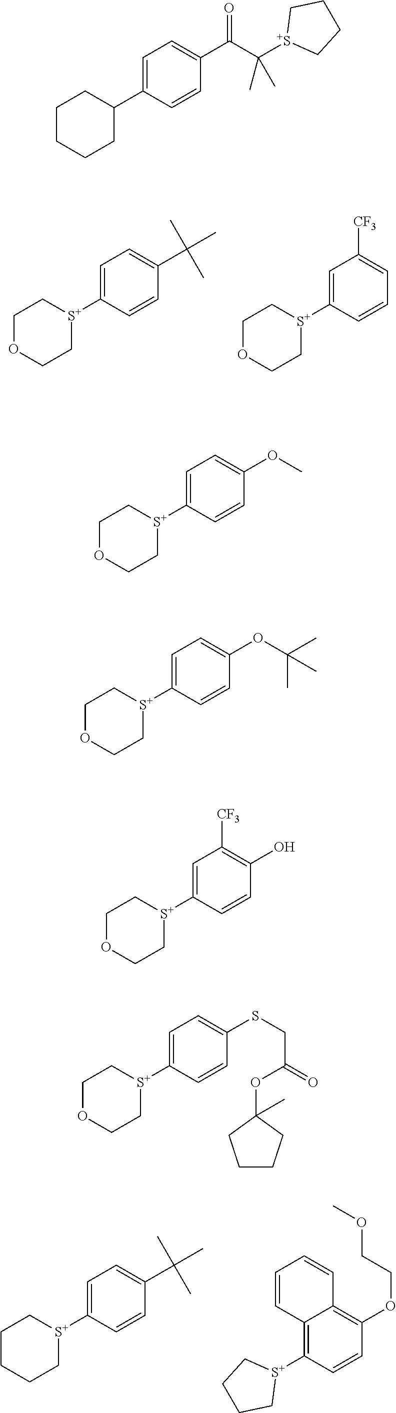

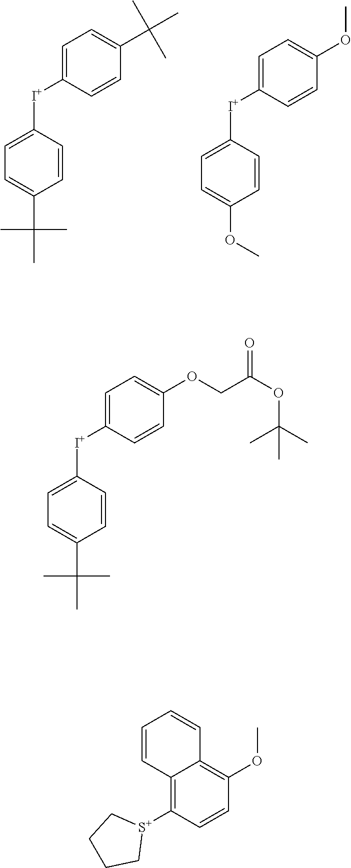 [SMILES: CC(C)(C)c1ccc([I+]c2ccc(C(C)(C)C)cc2)cc1 ; COc1ccc([I+]c2ccc(OC)cc2)cc1 ; CC(C)(C)OC(=O)COc1ccc([I+]c2ccc(C(C)(C)C)cc2)cc1 ; COc1ccc([S+]2CCCC2)c2ccccc12]

In the compound represented by “M⁺X⁻”, X-represents an anion, and preferably represents an organic anion. Examples of the anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, tris(alkylsulfonyl) methide anions, and a phenoxide anion.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited, but examples thereof include a nitro group, halogen atoms such as a fluorine atom and a chlorine atom, a carboxy group, a hydroxy group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group. The sulfonylimide anion may be, for example, a saccharin anion.

In such a bis(alkylsulfonyl)imide anion or tris(alkylsulfonyl) methide anion, the alkyl groups are preferably an alkyl group having 1 to 5 carbon atoms. A substituent of such an alkyl group may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the anion include phosphorus fluoride (for example, PF₆⁻), boron fluoride (for example, BF₄⁻), and antimony fluoride (for example, SbF₆⁻).

X⁻ is preferably a phenoxide anion, a sulfonate anion, or a carboxylate anion.

X⁻ may be an anion represented by the following formula (xa1).

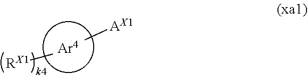

In the formula (xa1), A^{X1} represents O⁻, COO⁻, or SO₃⁻. Ar⁴ represents an aromatic ring. R^{X1} represents a substituent. k4 represents an integer of 0 to 7. When k4 is 2 or more, the plurality of R^{X1} may be the same or different. When k4 is 2 or more, the plurality of R^{X1} may be bonded together to form a ring.

The aromatic ring represented by Ar⁴ may be an aromatic hydrocarbon ring or an aromatic heterocycle. The number of ring-member carbon atoms of the aromatic hydrocarbon ring is preferably 6 to 20, and more preferably 6 to 15. The aromatic hydrocarbon ring is preferably a benzene ring or a naphthalene ring and more preferably a benzene ring. The number of ring-member atoms of the aromatic heterocycle is preferably 4 to 20, and more preferably 5 to 10. The aromatic heterocycle preferably includes at least one of a sulfur atom, a nitrogen atom, or an oxygen atom. Examples of the aromatic heterocycle include 5-membered aromatic heterocycles such as a pyrrole ring, an imidazole ring, a pyrazole ring, an oxazole ring, an isoxazole ring, a thiazole ring, an isothiazole ring, triazole, a furan ring, and a thiophene ring, and 6-membered aromatic heterocycles such as a pyridine ring, a pyrazine ring, a pyrimidine ring, a pyridazine ring, a triazine ring, a thiazine ring, and an oxazine ring.

The substituent represented by R^{X1} is not particularly limited, but may be, for example, the above-described substituents T, and is preferably a hydroxy group, a carboxy group, an alkyl group, an alkoxy group, a cycloalkyl group, or a halogen atom.

k4 represents an integer of 0 to 7, preferably represents an integer of 0 to 5, and more preferably represents an integer of 0 to 3.

The salt compound preferably includes at least one selected from the group consisting of a compound represented by the following formula (2-1), a compound represented by the following formula (2-2), and a compound represented by the following formula (2-3).

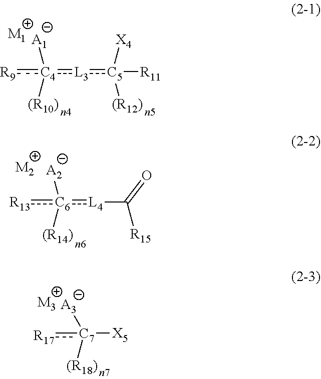

In the formula (2-1), M₁⁺ represents an organic cation. A₁⁺ represents an acid residue. X₄ represents a hydroxy group, an alkoxy group, an acyloxy group, —N(Rx)₂, —NRaCORb, a thiol group, or a thioalkoxy group. C₄ and C₅ each independently represent an sp³ carbon or an sp² carbon. Rx represent a hydrogen atom or an organic group. Two Rx may be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different. L₃ represents a single bond, a double bond, an aromatic carbon-carbon bond, or a linking group having 2 or less carbon atoms. R₉ to R₁₂ each independently represent a hydrogen atom or an organic group. At least two of X₄, R₉ to R₁₂, and L₃ may be bonded together to form a ring. n4 represents 0 or 1, provided that, when C₄ is an sp² carbon, n4 is 0 or, when C₄ is an sp³ carbon, n4 is 1. n5 represents 0 or 1, provided that, when C₅ is an sp² carbon, n5 is 0 or, when C₅ is an sp³ carbon, n5 is 1.

In the formula (2-2), M₂⁺ represents an organic cation. A₂⁻ represents an acid residue. L₄ represents a single bond, a double bond, an aromatic carbon-carbon bond, or a linking group having 2 or less carbon atoms. C₆ represents an sp³ carbon or an sp² carbon. R₁₃ and R₁₄ each independently represent a hydrogen atom or an organic group. R₁₅ represents a hydrogen atom, an alkyl group, an aryl group, —OH, or —OR₁₆. R₁₆ represents an organic group. At least two of R₁₃ to R₁₆ and L₄ may be bonded together to form a ring. n6 represents 0 or 1, provided that, when C₆ is an sp² carbon, n6 is 0 or, when C₆ is an sp³ carbon, n6 is 1.

In the formula (2-3), M₃⁺ represents an organic cation. A₃⁻ represents an acid residue. X₅ represents a hydroxy group, an alkoxy group, an acyloxy group, —N(Rx)₂, —NRaCORb, a thiol group, or a thioalkoxy group. Rx represent a hydrogen atom or an organic group. Two Rx may be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different. Cz represents an sp³ carbon or an sp² carbon. R₁₇ and R₁₈ each independently represent a hydrogen atom or an organic group. At least two of X₅, R₁₇, and R₁₈ may be bonded together to form a ring. n7 represents 0 or 1, provided that, when C₇ is an sp² carbon, n7 is 0 or, when C₇ is an sp³ carbon, n7 is 1.

M₁⁺ in the formula (2-1), M₂⁺ in the formula (2-2), and M₃⁺ in the formula (2-3) each independently represent an organic cation. The descriptions, specific examples, and preferred ranges of M₁⁺, M₂⁺, and M₃⁺ are respectively the same as those described above for M⁺.

Ar₁⁻ in the formula (2-1), A₂⁻ in the formula (2-2), and A₃⁻ in the formula (2-3) each independently represent an acid residue. The acid residue is not particularly limited, but is preferably a carboxylate anion group (—COO⁻), a sulfonate anion group (—SO₃⁻), or a sulfonamide group (represented by —N⁻—SO₂R^{N1}, R^{N1} represents an organic group and is preferably an alkyl group, a fluoroalkyl group, or an aryl group), or a phenoxide anion group, and more preferably a carboxylate anion group or a sulfonate anion group.

X₄ in the formula (2-1) and X₅ in the formula (2-3) each independently represent a hydroxy group, an alkoxy group, an acyloxy group, —N(Rx)₂, —NRaCORb, a thiol group, or a thioalkoxy group. Rx represent a hydrogen atom or an organic group. Two Rx may be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different.

The descriptions, specific examples, and preferred ranges of X₄ and X₅ are the same as those described above for X₁ and X₂ in the formula (1-1).

When X₄ and X₅ represent —N(Rx)₂, the description, specific examples, and preferred ranges of Rx are the same as those described above for Rx in the description of formula (1-1).

When X₄ and X₅ represent —NRaCORb, the description, specific examples, and preferred ranges of Ra and Rb are the same as those described above for Ra and Rb in the description of formula (1-1).

When Rb represents —N(Rc)₂, the description, specific examples, and preferred ranges of Rc are the same as those described above for Rc in the description of the formula (1-1).

L₃ in the formula (2-1) and L₄ in the formula (2-2) each independently represent a single bond, a double bond, an aromatic carbon-carbon bond, or a linking group having 2 or less carbon atoms. The descriptions, specific examples, and preferred ranges of L₃ and L₄ are the same as those described above for L₁ in the formula (1-1).

R₉ to R₁₂ in the formula (2-1), R₁₃ and R₁₄ in the formula (2-2), and R₁₇ and R₁₈ in the formula (2-3) each independently represent a hydrogen atom or an organic group. The descriptions, specific examples, and preferred ranges of R₉ to R₁₂, R₁₃, R₁₄, R₁₇, and R₁₈ are the same as those described above for Rx in the description of the formula (1-1).

In the formula (2-2), R₁₅ represents a hydrogen atom, an alkyl group, an aryl group, —OH, or —OR₁₆. R₁₆ represents an organic group. The descriptions, specific examples, and preferred ranges of the alkyl group and aryl group represented by R₁₅ are respectively the same as those described above for Rx in the description of the formula (1-1). The description, specific examples, and preferred ranges of the organic group represented by R₁₆ are the same as those described above for Rx in the description of the formula (1-1).

At least two of X₄, R₉ to R₁₂, and L₃ in the formula (2-1) may be bonded together to form a ring. The description, specific examples, and preferred ranges of the ring formed by bonding together at least two of X₄, R₉ to R₁₂, and L₃ are the same as those described above for the ring formed by bonding together at least two of X₁, X₂, R₁ to R₄, and L₁ in the formula (1-1).

At least two of R₁₃ to R₁₆ and L₄ in the formula (2-2) may be bonded together to form a ring. The description, specific examples, and preferred ranges of the ring formed by bonding together at least two of R₁₃ to R₁₆ and L₄ are the same as those described above for the ring formed by bonding together at least two of X₁, X₂, R₁ to R₄, and L₁ in the formula (1-1).

At least two of X₅, R₁₇, and R₁₈ in the formula (2-3) may be bonded together to form a ring. The description, specific examples, and preferred ranges of the ring formed by bonding together at least two of X₅, R₁₇, and R₁₈ are the same as those described above for the ring formed by bonding together at least two of X₁, X₂, R₁ to R₄, and L₁ in the formula (1-1).

The salt compound is also preferably a compound represented by a formula (2-1-1) below.

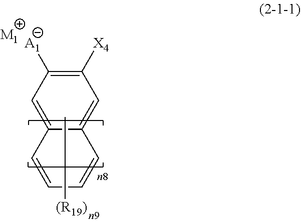

In the formula (2-1-1), M₁⁺ represents an organic cation. A₁⁻ represents an acid residue. X₄ represents a hydroxy group, an alkoxy group, an acyloxy group, —N(Rx)₂, —NRaCORb, a thiol group, or a thioalkoxy group. Rx represent a hydrogen atom or an organic group. Two Rx can be the same or different. Ra represents a hydrogen atom or an organic group. Rb represents a hydrogen atom, an alkyl group, a cycloalkyl group, an aryl group, an aralkyl group, an alkoxy group, —N(Rc)₂, or a thioalkoxy group. Rc represent a hydrogen atom or an organic group. Two Rc may be the same or different. R₁₉ represents a substituent. n8 represents an integer of 0 to 2. n9 represents an integer of 0 to (4+2×n8). When a plurality of R₁₉ are present, the plurality of R₁₉ can be the same or different.

The descriptions, specific examples, and preferred ranges of M₁⁺, A₁⁻, X₄, Rx, Ra, Rb, and Rc in the formula (2-1-1) are respectively the same as those described above for the formula (2-1).

The substituent represented by R₁₉ in the formula (2-1-1) is not particularly limited. Examples of the substituent represented by R₁₉ include the above-described substituents T.

When n8 in the formula (2-1-1) represents 0, the aromatic ring in the formula (2-1-1) represents a benzene ring. When n8 in the formula (2-1-1) represents 1, the aromatic ring in the formula (2-1-1) represents a naphthalene ring. When n8 in the formula (2-1-1) represents 2, the aromatic ring in the formula (2-1-1) represents an anthracene ring.

n8 preferably represents 0 or 1, and more preferably represents 0.

In the formula (2-1-1), n9 preferably represents an integer of 0 to 4, and more preferably represents an integer of 0 to 3.

The following are non-limiting specific examples of the anion represented by X⁻.

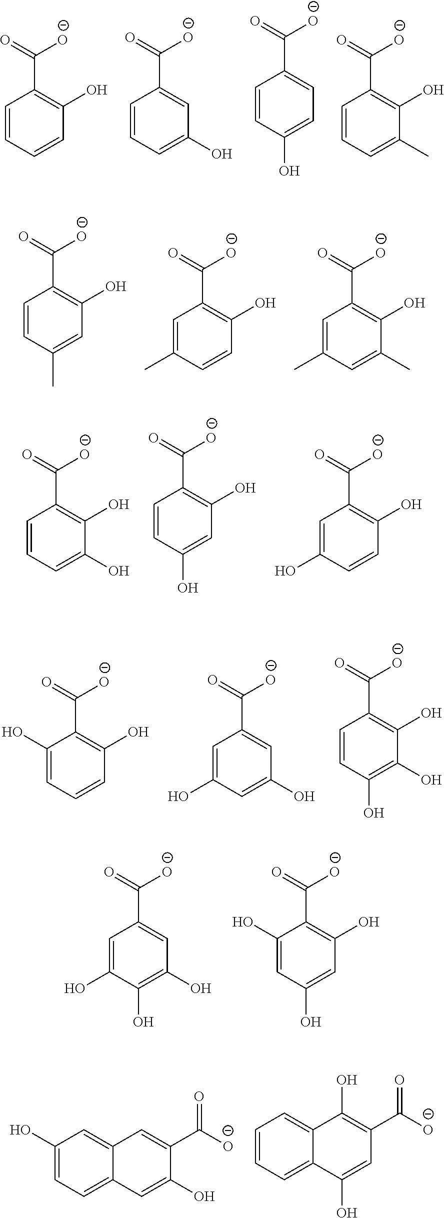

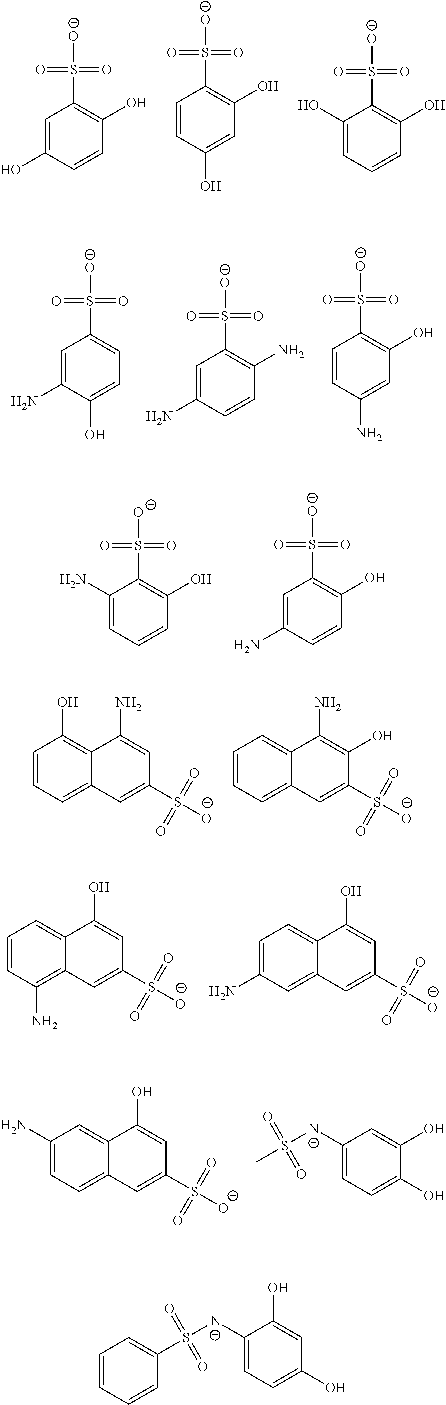

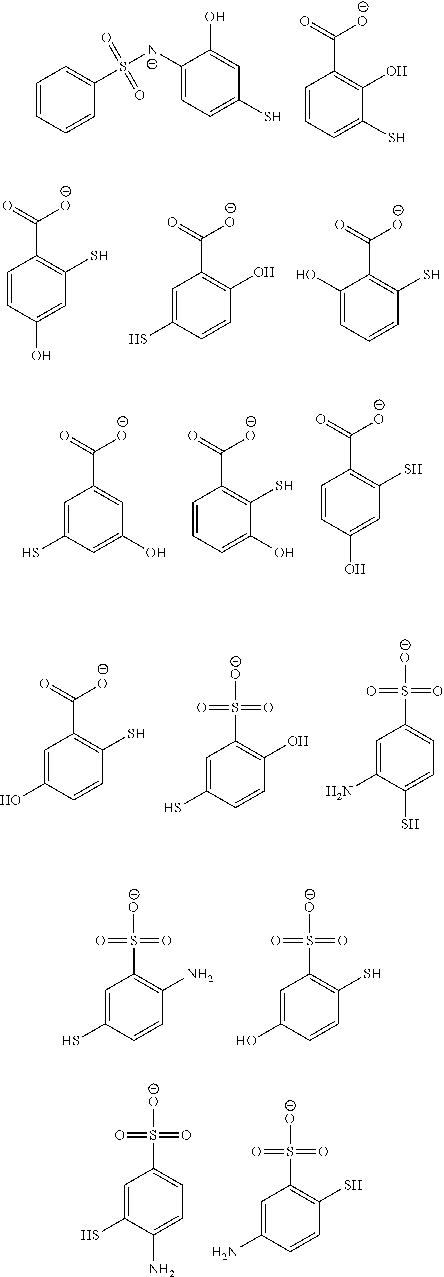

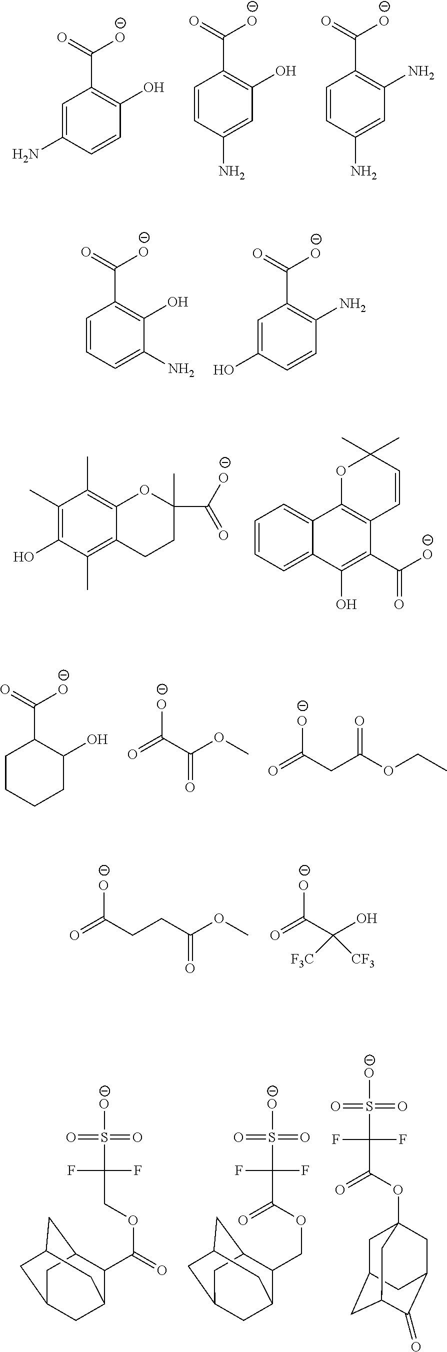

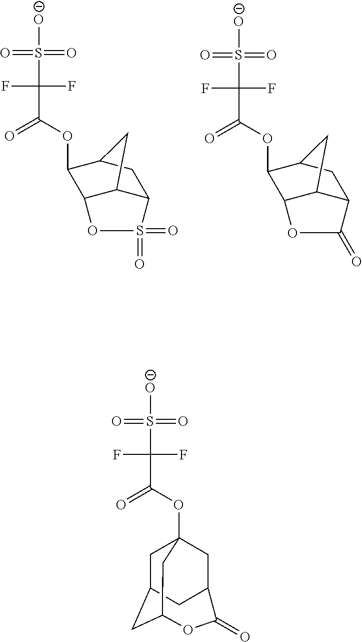 [SMILES: O=C(OC1C2CC3C1OS(=O)(=O)C3C2)C(F)(F)S(=O)(=O)[O-] ; O=C1OC2C3CC(CC13)C2OC(=O)C(F)(F)S(=O)(=O)[O-] ; O=C1OC2CC3CC1CC(OC(=O)C(F)(F)S(=O)(=O)[O-])(C3)C2]

The salt compound may be at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁⁻ and a cationic moiety M₁⁺ and that forms a first acidic moiety represented by HA₁ upon irradiation with an actinic ray or a radiation.

Structural moiety Y: a structural moiety that is constituted by an anionic moiety A₂⁺ and a cationic moiety M₂⁺ and that forms a second acidic moiety represented by HA₂ upon irradiation with an actinic ray or a radiation.

The compound (I) satisfies the following condition I.

Condition I: a compound PI in which the cationic moiety M₁⁺ in the structural moiety X and the cationic moiety M₂⁺ in the structural moiety Y in the compound (I) are replaced by H⁺ has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂⁺ in which the cationic moiety M₂⁺ in the structural moiety Y is replaced by H⁺, and the acid dissociation constant a2 is larger than the acid dissociation constant a1.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA_{2”}.

The acid dissociation constant a1 and the acid dissociation constant a2 of the compound PI will be more specifically described as follows: in determination of the acid dissociation constants of the compound PI, the pKa at the time when the compound PI turns into a “compound having A₁ and HA₂” is the acid dissociation constant a1, and the pKa at the time when the “compound having A₁⁻ and HA₂” turns into a “compound having Ar₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA_{2”}.

In determination of the acid dissociation constants of the compound PI, the acid dissociation constant at the time when the compound PI turns into a “compound having one A₁⁻, one HA₁, and one HA₂” and the acid dissociation constant at the time when the “compound having one A₁⁻, one HA₁, and one HA₂” turns into a “compound having two Ar₁⁻ and one HA₂” correspond to the above-described acid dissociation constant a1. The acid dissociation constant at the time when the “compound having two A₁⁻ and one HA₂” turns into a “compound having two A₁⁻ and A₂⁻” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value among the plurality of the acid dissociation constants a1. Note that, in a case where the acid dissociation constant at the time when the compound PI turns into the “compound having one A₁⁻, one HA₁, and one HA₂” is defined as aa, and the acid dissociation constant at the time when the “compound having one A₁⁻, one HA₁, and one HA₂” turns into the “compound having two A₁⁻ and one HA₂” is defined as ab, the relationship between aa and ab satisfies aa<ab.

The acid dissociation constant a1 and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), the A₁⁻ and the A₂⁻, and the M₁⁺ and the M₂⁺ may be individually the same or different, but the A₁⁻ and the A₂⁻ are preferably different from each other.

In the compound PI, the difference (absolute value) between the acid dissociation constant a1 (when a plurality of acid dissociation constants a1 are present, the maximum value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the maximum value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably −4.0 or more.

In the compound PI, the acid dissociation constant a1 is preferably 2.0 or less, and more preferably 0 or less. Note that the lower limit value of the acid dissociation constant a1 is preferably −20.0 or more.

### Compound (II)

The compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

Structural Moiety Z: A Nonionic Moiety that can Neutralize Acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples are also the same.

For a compound PII in which the cationic moiety M₁⁺ in the structural moiety X in the compound (II) is replaced by H⁺, the preferred range of the acid dissociation constant a1 derived from the acidic moiety represented by HA₁⁻ in which the cationic moiety M₁⁺ in the structural moiety X is replaced by H is the same as in the acid dissociation constant a1 in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A⁻ and one HA₁” and the acid dissociation constant at the time when the “compound having one A₁⁻ and one HA₁” turns into a “compound having two A₁⁻” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to x-conjugation. Examples of the nitrogen atom having an unshared electron pair that does not contribute to x-conjugation include nitrogen atoms having partial structures represented by the following formulas.

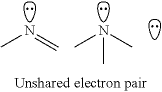

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

For the cation, the compound (I), and the compound (II), the contents of to of WO2022/024928A can be referred to.

Specific examples of the salt compound include the compounds described in to of WO2022/172715A. The above description is incorporated herein.

When the solid substance (U) includes a salt compound, the content of the salt compound is not particularly limited, but is, relative to the total solid content in the solution (Z), preferably 0.1 mass % or more and 100 mass % or less, more preferably 0.5 mass % or more and 100 mass % or less, and still more preferably 1.0 mass % or more and 100 mass % or less.

Such salt compounds may be used alone or may be used in combination of two or more thereof. When two or more thereof are used, the total content thereof is preferably within such a preferred content range.

### Acid-Decomposable Resin

The solid substance (U) may include an acid-decomposable resin (also referred to as “resin (P)”).

The resin (P) is a resin that is decomposed by the action of an acid to undergo an increase in the polarity.

The resin (P) preferably has a group that is decomposed by the action of an acid to undergo an increase the polarity (acid-decomposable group), and more preferably includes a repeating unit having an acid-decomposable group.

The acid-decomposable group is typically a group that is decomposed by the action of an acid to generate a polar group. The acid-decomposable group preferably has a structure in which the polar group is protected with a group (leaving group) that leaves by the action of an acid. Typically, the resin (P) undergoes an increase in the polarity by the action of an acid to undergo an increase in the degree of solubility in the alkali developer and a decrease in the degree of solubility in organic solvents.

### Repeating Unit Having Acid-Decomposable Group

The acid-decomposable group is a group that is decomposed by the action of an acid to undergo an increase in the polarity.

The acid-decomposable group is typically a group that is decomposed by the action of an acid to generate a polar group. The acid-decomposable group preferably has a structure in which the polar group is protected with a group (leaving group) that leaves by the action of an acid. Typically, the resin (P) undergoes an increase in the polarity by the action of an acid to undergo an increase in the degree of solubility in the alkali developer and a decrease in the degree of solubility in organic solvents.

The polar group is preferably an alkali-soluble group; examples include acidic groups such as a carboxy group, a phenolic hydroxyl group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxyl group.

Examples of the leaving group that leaves by the action of an acid include groups represented by formulas (Y1) to (Y4).

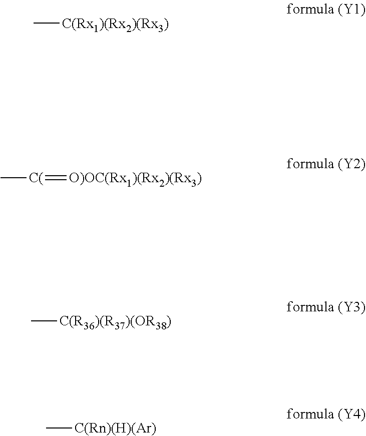

In the formula (Y1) and the formula (Y2), Rx₁ to Rx₃ each independently represent an alkyl group (linear or branched), a cycloalkyl group (monocyclic or polycyclic), an aryl group (monocyclic or polycyclic), an aralkyl group (linear or branched), an alkenyl group (linear or branched), or an alkynyl group (linear or branched). Note that, when all of Rx₁ to Rx₃ are alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded together to form a ring (that may be either monocyclic or polycyclic).

For Rx₁ to Rx₃, the alkyl group is preferably an alkyl group having 1 to 10 carbon atoms such as a methyl group, an ethyl group, an n-propyl group, an isopropyl group, an n-butyl group, an isobutyl group, or a t-butyl group, and more preferably an alkyl group having 1 to 5 carbon atoms.

For Rx₁ to Rx₃, the cycloalkyl group preferably has 3 to 20 carbon atoms, and more preferably 4 to 15 carbon atoms. The cycloalkyl group may be a monocyclic cycloalkyl group such as a cyclopentyl group or a cyclohexyl group or may be a polycyclic cycloalkyl group such as a norbornyl group, a tetracyclodecanyl group, a tetracyclododecanyl group, or an adamantyl group. In the cycloalkyl group, for example, one of the methylene groups constituting the ring may be replaced by a heteroatom such as an oxygen atom, a group having a heteroatom such as a carbonyl group, or a vinylidene group. In the cycloalkyl group, one or more ethylene groups constituting the cycloalkane ring may be replaced by a vinylene group. That is, Rx₁ to Rx₃ may be a cycloalkenylene group.

For Rx₁ to Rx₃, the aryl group is preferably an aryl group having 6 to 10 carbon atoms, and may be, for example, a phenyl group, a naphthyl group, or an anthryl group.

For Rx₁ to Rx₃, the aralkyl group is preferably a group in which one hydrogen atom in an alkyl group described above for Rx₁ to Rx₃ is substituted with an aryl group having 6 to 10 carbon atoms (preferably a phenyl group), and may be, for example, a benzyl group.

For Rx₁ to Rx₃, the alkenyl group may be an alkenyl group having 2 to 20 carbon atoms, is preferably an alkenyl group having 2 to 10 carbon atoms, and, for example, preferably a vinyl group or an allyl group.

For Rx₁ to Rx₃, the alkynyl group may be an alkynyl group having 2 to 20 carbon atoms, is preferably an alkynyl group having 2 to 10 carbon atoms, and, for example, preferably an ethynyl group.

The ring formed by bonding together two of Rx₁ to Rx₃ is preferably a cycloalkyl group. The cycloalkyl group formed by bonding together two of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two of Rx₁ to Rx₃, for example, one of the methylene groups constituting the ring may be replaced by a heteroatom such as an oxygen atom, a group having a heteroatom such as a carbonyl group, or a vinylidene group. In the cycloalkyl group, one or more ethylene groups constituting the cycloalkane ring may be replaced by a vinylene group.

The group represented by the formula (Y1) or the formula (Y2) preferably has a form in which, for example, Rx₁ is a methyl group or an ethyl group, and Rx₂ and Rx₃ are bonded together to form the above-described cycloalkyl group.

In the formula (Y3), R₃₆ to R₃₈ each independently represent a hydrogen atom or a monovalent organic group. R₃₇ and R₃₈ may be bonded together to form a ring. Examples of the monovalent organic group include alkyl groups, cycloalkyl groups, aryl groups, aralkyl groups, and alkenyl groups. R₃₆ is also preferably a hydrogen atom.

Note that the alkyl groups, the cycloalkyl groups, the aryl groups, and the aralkyl groups may include a heteroatom such as an oxygen atom and/or a group having a heteroatom such as a carbonyl group. For example, in the alkyl groups, the cycloalkyl groups, the aryl groups, and the aralkyl groups, for example, one or more methylene groups may be replaced by a heteroatom such as an oxygen atom and/or a group having a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

In the formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

The resin (P) preferably includes a repeating unit represented by a formula (Pa1) below. The repeating unit represented by the formula (Pa1) below is a repeating unit having an acid-decomposable group.

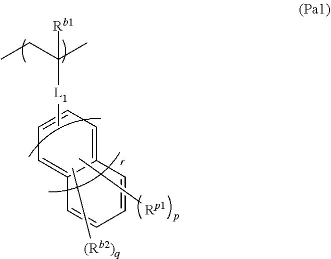

In the formula (Pa1), R^{b1} represents a hydrogen atom or an alkyl group. L¹ represents a single bond or —C(═O)O—. r represents an integer of 0 to 2. p represents an integer of 1 to 5. R^{p1} represents —OR^{p2} or —COOR^{p3}. R^{p2} and R^{p3} each independently represent a group that leaves by the action of an acid. q represents an integer of 0 to (5+2×r−p). R^{b2} represents a hydroxy group, a halogen atom, an alkyl group, an alkoxy group, an alkylthio group, an aryl group, a heteroaryl group, an aryloxy group, a heteroaryloxy group, an ester group, or a carboxy group. When p is 2 or more, the plurality of R^{p1} may be the same or different, and may be bonded together to form a ring. When q is 2 or more, the plurality of R^{b2} may be the same or different, and may be bonded together to form a ring.

L¹ represents a single bond or —C(═O)O—, and preferably represents a single bond.

The alkyl group represented by R^{b1} may be linear or branched. The alkyl group is preferably an alkyl group having 1 to 5 carbon atoms such as a methyl group, an ethyl group, an n-propyl group, an isopropyl group, an n-butyl group, an isobutyl group, or a t-butyl group. The alkyl group may have a substituent.

R^{b1} is preferably a hydrogen atom or a methyl group.

r represents an integer of 0 to 2, preferably represents 0 or 1, and more preferably represents 0. When r represents 0, the aromatic ring in the formula (Pa1) represents a benzene ring. When r represents 1, the aromatic ring in the formula (Pa1) represents a naphthalene ring. When r represents 2, the aromatic ring in the formula (Pa1) represents an anthracene ring.

p represents an integer of 1 to 5, preferably represents an integer of 1 to 3, and more preferably represents 1.

R^{p1} represents —OR^{p2} or —COOR^{p3}.

R^{p2} and R^{p3} each independently represent a group that leaves by the action of an acid. For R^{p2} and R^{p3}, examples of the group that leaves by the action of an acid include groups represented by the above-described formulas (Y1) to (Y4). As a result of leaving of R^{p2}, a hydroxy group (phenolic hydroxy group) is generated in the formula (Pa1). As a result of leaving of R^{p3}, a carboxy group is generated in the formula (Pa1).

q represents an integer of 0 to (5+2×r−p), preferably represents an integer of 0 to 5, more preferably represents an integer of 0 to 3, still more preferably represents 0 or 1, and particularly preferably represents 0.

R^{b2} represents a hydroxy group, a halogen atom, an alkyl group, an alkoxy group, an alkylthio group, an aryl group, a heteroaryl group, an aryloxy group, a heteroaryloxy group, an ester group, or a carboxy group.

The halogen atom of R^{b2} is preferably a fluorine atom, a chlorine atom, a bromine atom, or an iodine atom.

The alkyl group of R^{b2} may be either linear or branched. The number of carbon atoms of the alkyl group is not particularly limited, but is preferably 1 to 10, more preferably 1 to 5, and particularly preferably 1 to 3. Examples of the alkyl group include a methyl group, an ethyl group, an n-propyl group, an isopropyl group, an n-butyl group, an isobutyl group, and a t-butyl group.

The description, specific examples, and preferred ranges of alkyl groups included in the alkoxy group and alkylthio group of R^{b2} are the same as the above description, specific examples, and preferred ranges of the alkyl group of R^{b2}.

The aryl group of R^{b2} is preferably an aryl group having 6 to 20 carbon atoms, more preferably an aryl group having 6 to 15 carbon atoms, still more preferably a phenyl group or a naphthyl group, and particularly preferably a phenyl group.

The specific examples and preferred ranges of the aryl group included in the aryloxy group of R^{b2} are the same as the above-described specific examples and preferred ranges of the aryl group of R^{b2}.

The heteroaryl group of R^{b2} is preferably a heteroaryl group having 3 to 20 carbon atoms. The heteroaryl group preferably includes at least one heteroatom selected from the group consisting of an oxygen atom, a sulfur atom, and a nitrogen atom. Examples of the heteroaryl group include a pyrrole residue, a furan residue, a thiophene residue, an indole residue, a benzofuran residue, and a benzothiophene residue.

The specific examples and preferred ranges of the heteroaryl group included in the heteroaryloxy group of R^{b2} are the same as the above-described specific examples and preferred ranges of the heteroaryl group of R^{b2}.

The ester group of R^{b2} is preferably —COOR^{b3} or —OCOR^{b3}. R^{b3} represents an organic group and preferably represents an alkyl group or an aryl group. The description, specific examples, and preferred ranges of the alkyl group of R^{b3} are the same as the above description, specific examples, and preferred ranges of the alkyl group of R^{b2}. The specific examples and preferred ranges of the aryl group of R^{b3} are the same as the above-described specific examples and preferred ranges of the aryl group of R^{b2}.

A preferred embodiment of the repeating unit having an acid-decomposable group may be an embodiment of having a halogen atom. In this embodiment, preferred is having at least one of a fluorine atom or an iodine atom; more preferably, the total number of fluorine atoms and iodine atoms in one repeating unit is 1 to 10, and still more preferably 1 to 5.

Another preferred embodiment of the repeating unit having an acid-decomposable group may be an embodiment of not having a halogen atom.

For the repeating unit having an acid-decomposable group, the description in to of WO2022/024928A can be referred to. The above description is incorporated herein.

Specific examples of the repeating unit having an acid-decomposable group will be described below, but are not limited to these.

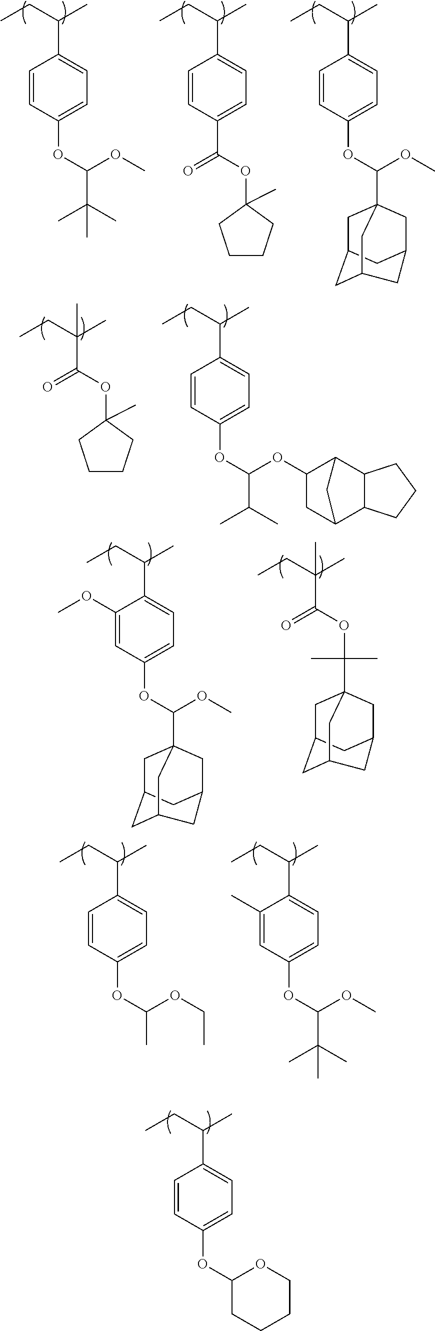

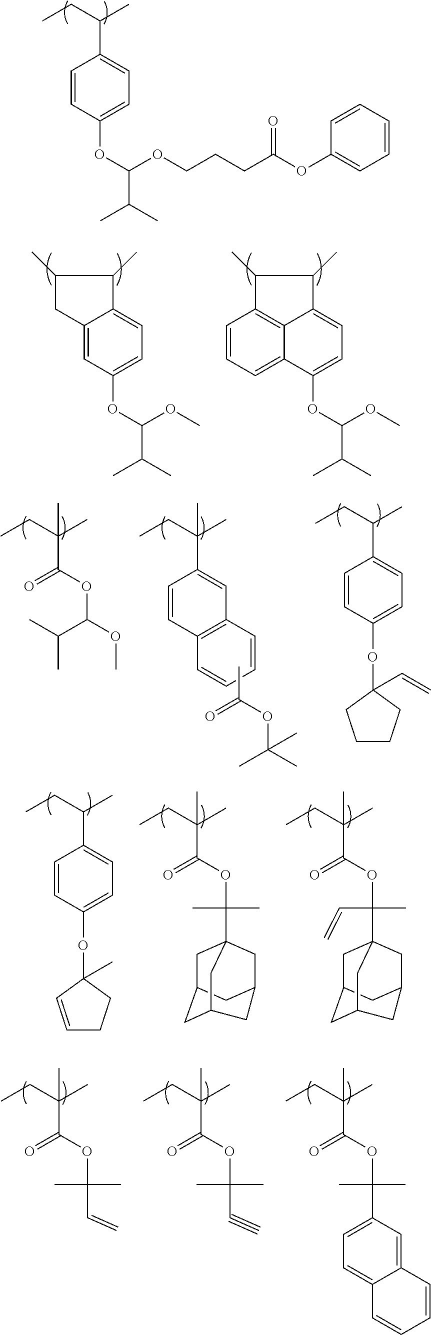

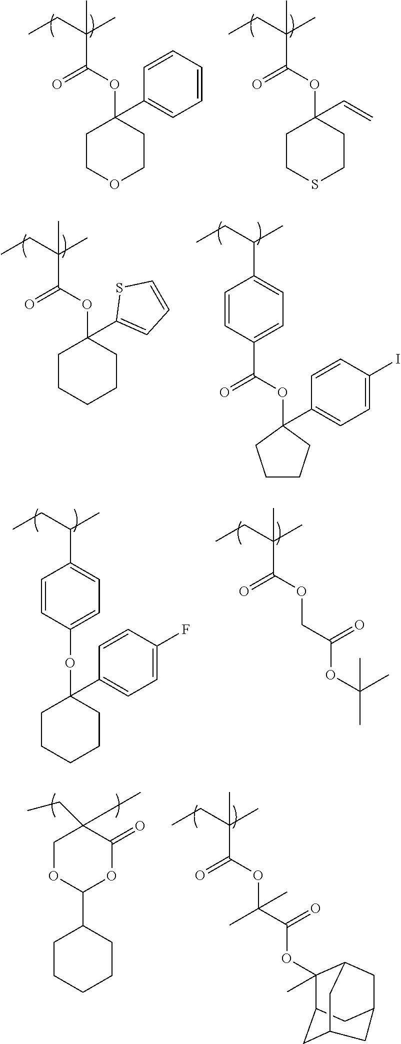

The content of the repeating unit having an acid-decomposable group relative to all the repeating units in the resin (P) is preferably 5 mol % or more, more preferably 10 mol % or more, and still more preferably 15 mol % or more. The content of the repeating unit having an acid-decomposable group relative to all the repeating units in the resin (P) is preferably 70 mol % or less, more preferably 60 mol % or less, and still more preferably 50 mol % or less.

The repeating unit having an acid-decomposable group included in the resin (P) may be of one type, or may be of two or more types. When the resin (P) includes two or more types of repeating units having an acid-decomposable group, the total content thereof is preferably within such a preferred content range.

The resin (P) may include at least one type of a repeating unit selected from the group consisting of the following Group A, and/or at least one type of a repeating unit selected from the group consisting of the following Group B.

Group A: the group consisting of the following repeating units (20) to (25):
(20) a repeating unit having an acid group;
(21) a repeating unit not having an acid-decomposable group or an acid group, but having a fluorine atom, a bromine atom, or an iodine atom;
(22) a repeating unit having a lactone group, a sultone group, or a carbonate group;
(23) a repeating unit having a photoacid generation group;
(24) a repeating unit represented by a formula (V-1) or a formula (V-2); and
(25) a repeating unit for lowering the mobility of the main chain.

Group B: the group consisting of the following repeating units (30) to (32):
(30) a repeating unit having at least one type of a group selected from the group consisting of a lactone group, a sultone group, a carbonate group, a hydroxyl group, a cyano group, and an alkali-soluble group;
(31) a repeating unit having an alicyclic hydrocarbon structure and not exhibiting acid-decomposability; and
(32) a repeating unit not having a hydroxyl group or a cyano group and represented by a formula (III).

### Repeating Unit Having Acid Group

The resin (P) preferably has an acid group and preferably includes a repeating unit having an acid group. When the resin (P) has an acid group, the resin (P) and the acid generated from the photoacid generator interact to thereby suppress diffusion of the acid, so that a pattern having a square profile tends to be formed inferentially.

The acid group is preferably an acid group having a pKa of 13 or less. The pKa of the acid group is preferably 13 or less, more preferably 3 to 13, and still more preferably 5 to 10. Note that the pKa of the acid group is the pKa of the monomer corresponding to the repeating unit having the acid group.

When the resin (P) has an acid group having a pKa of 13 or less, the content of the acid group in the resin (P) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development suitably proceeds to form a pattern having a good profile at high resolution.

The acid group is preferably, for example, a carboxyl group, a phenolic hydroxyl group, a fluoroalcohol group (preferably a hexafluoroisopropanol group), a sulfonic acid group, a sulfonamide group, or an isopropanol group. In the hexafluoroisopropanol group, one or more (preferably 1 to 2) fluorine atoms may be substituted with a group other than fluorine atoms (such as an alkoxycarbonyl group). The acid group is also preferably —C(CF₃)(OH)—CF₂— formed in this manner. Alternatively, one or more of the fluorine atoms may be substituted with a group other than fluorine atoms, to form a ring including —C(CF₃)(OH)—CF₂—.

The acid group is particularly preferably a phenolic hydroxyl group.

The repeating unit having an acid group is preferably a repeating unit different from the repeating unit having an acid-decomposable group.

The repeating unit having an acid group is preferably a repeating unit different from the repeating unit having a lactone group, a sultone group, or a carbonate group.

The repeating unit having an acid group may have a fluorine atom or an iodine atom.

Specific examples of the repeating unit having an acid group include, for example, the repeating units described in [0088] to [0089] and [0103] to [0110] of WO2022/024928A. The above description is incorporated herein.

The content of the repeating unit having an acid group in the resin (P) is not particularly limited, but is, relative to all the repeating units in the resin (P), preferably 20 mol % or more, more preferably 30 mol % or more, and still more preferably 40 mol % or more. The content of the repeating unit having an acid group relative to all the repeating units in the resin (P) is preferably 90 mol % or less, more preferably 85 mol % or less, and still more preferably 80 mol % or less.

The repeating unit having an acid group included in the resin (P) may be of one type or two or more types. When the resin (P) includes two or more types of repeating units having an acid group, the total content thereof is preferably within such a preferred content range.

### Repeating Unit Having Phenolic Hydroxyl Group

The resin (P) preferably includes a repeating unit having a phenolic hydroxyl group.

The repeating unit having a phenolic hydroxyl group is preferably a repeating unit different from the above-described repeating unit having an acid-decomposable group.

The repeating unit having a phenolic hydroxyl group is preferably a repeating unit represented by formula (Pa2) below.

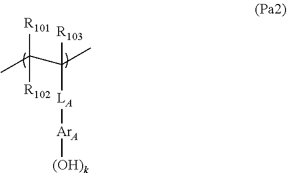

In the formula (Pa2), R₁₀₁, R₁₀₂, and R₁₀₃ each independently represent a hydrogen atom, an alkyl group, a cycloalkyl group, a halogen atom, a cyano group, or an alkoxycarbonyl group. R₁₀₂ may be bonded to Ar_{A} to form a ring and, in this case, R₁₀₂ represents a single bond or an alkylene group.

L_{A} represents a single bond or a divalent linking group.

Ar_{A} represents an aromatic ring group.

k represents an integer of 1 to 5.

R₁₀₁, R₁₀₂, and R₁₀₃ in the formula (Pa2) each independently represent a hydrogen atom, an alkyl group, a cycloalkyl group, a halogen atom, a cyano group, or an alkoxycarbonyl group.

For R₁₀₁, R₁₀₂, and R₁₀₃, the alkyl group may be either linear or branched. The number of carbon atoms of the alkyl group is not particularly limited, but is preferably 1 to 10, more preferably 1 to 5, and particularly preferably 1 to 3. Examples of the alkyl group include a methyl group, an ethyl group, an n-propyl group, an isopropyl group, an n-butyl group, an isobutyl group, and a t-butyl group.

For R₁₀₁, R₁₀₂, and R₁₀₃, the number of carbon atoms of the cycloalkyl group is not particularly limited, but is preferably 3 to 20, and more preferably 5 to 15. For R₁₀₁, R₁₀₂, and R₁₀₃, the cycloalkyl group is preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

For R₁₀₁, R₁₀₂, and R₁₀₃, the halogen atom may be a fluorine atom, a chlorine atom, a bromine atom, or an iodine atom, and is preferably a fluorine atom or an iodine atom.

For R₁₀₁, R₁₀₂, and R₁₀₃, the alkyl group included in the alkoxycarbonyl group may be either linear or branched. For the alkyl group included in the alkoxycarbonyl group, the number of carbon atoms is not particularly limited, but is preferably 1 to 5, and more preferably 1 to 3.

Ar_{A} in the formula (Pa2) represents an aromatic ring group, and more specifically represents a (k+1)-valent aromatic ring group. When k is 1, the divalent aromatic ring group is, for example, preferably an arylene group having 6 to 18 carbon atoms such as a phenylene group, a tolylene group, a naphthylene group, or an anthracenylene group, or a divalent aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aromatic ring group may have a substituent.

When k is an integer of 2 or more, specific examples of the (k+1)-valent aromatic ring group include groups provided by removing any (k−1) hydrogen atoms from the above-described specific examples of the divalent aromatic ring group.

The (k+1)-valent aromatic ring group may further have a substituent.

The substituent that the (k+1)-valent aromatic ring group may have is not particularly limited, but examples thereof include alkyl groups such as a methyl group, an ethyl group, a propyl group, an isopropyl group, an n-butyl group, a sec-butyl group, a hexyl group, a 2-ethylhexyl group, an octyl group, and a dodecyl group; alkoxy groups such as a methoxy group, an ethoxy group, a hydroxyethoxy group, a propoxy group, a hydroxypropoxy group, and a butoxy group; and aryl groups such as a phenyl group.

Ar_{A} preferably represents an aromatic ring group having 6 to 18 carbon atoms, and more preferably represents a benzene ring group, a naphthalene ring group, or a biphenylene ring group.

L_{A} in the formula (Pa2) represents a single bond or a divalent linking group.

The divalent linking group represented by L_{A} is not particularly limited, but may be, for example, —COO—, —CONR₁₀₄—, an alkylene group, or a group that is a combination of two or more of the foregoing groups. The above R₁₀₄ represents a hydrogen atom or an alkyl group.

The alkylene group is not particularly limited, but is preferably an alkylene group having 1 to 8 carbon atoms such as a methylene group, an ethylene group, a propylene group, a butylene group, a hexylene group, or an octylene group.

When R₁₀₄ represents an alkyl group, the alkyl group may be an alkyl group having 20 or less carbon atoms such as a methyl group, an ethyl group, a propyl group, an isopropyl group, an n-butyl group, a sec-butyl group, a hexyl group, a 2-ethylhexyl group, an octyl group, or a dodecyl group, and is preferably an alkyl group having 8 or less carbon atoms.

The repeating unit represented by the formula (Pa2) preferably includes a hydroxystyrene structure. In other words, Ar_{A} preferably represents a benzene ring group.

k preferably represents an integer of 1 to 3, and more preferably represents 1 or 2.

The content of the repeating unit having a phenolic hydroxyl group in the resin (P) is not particularly limited, but is, relative to all the repeating units in the resin (P), preferably 20 mol % or more, more preferably 30 mol % or more, and still more preferably 40 mol % or more. The content of the repeating unit having a phenolic hydroxyl group is, relative to all the repeating units in the resin (P), preferably 90 mol % or less, more preferably 85 mol % or less, and still more preferably 80 mol % or less.

The repeating unit having a phenolic hydroxyl group included in the resin (P) may be of one type, or may be of two or more types. When the resin (P) includes two or more types of repeating units having a phenolic hydroxyl group, the total content thereof is preferably within such a preferred content range.

Specific examples of the repeating unit having an acid group will be described below, but are not limited to these. In the following structural formulas, G¹ and G² each independently represent a hydrogen atom, a methyl group, a fluorine atom, a chlorine atom, a trifluoromethyl group, a cyano group, a hydroxy group, or a hydroxymethyl group. f1 represent an integer of 1 to 3.

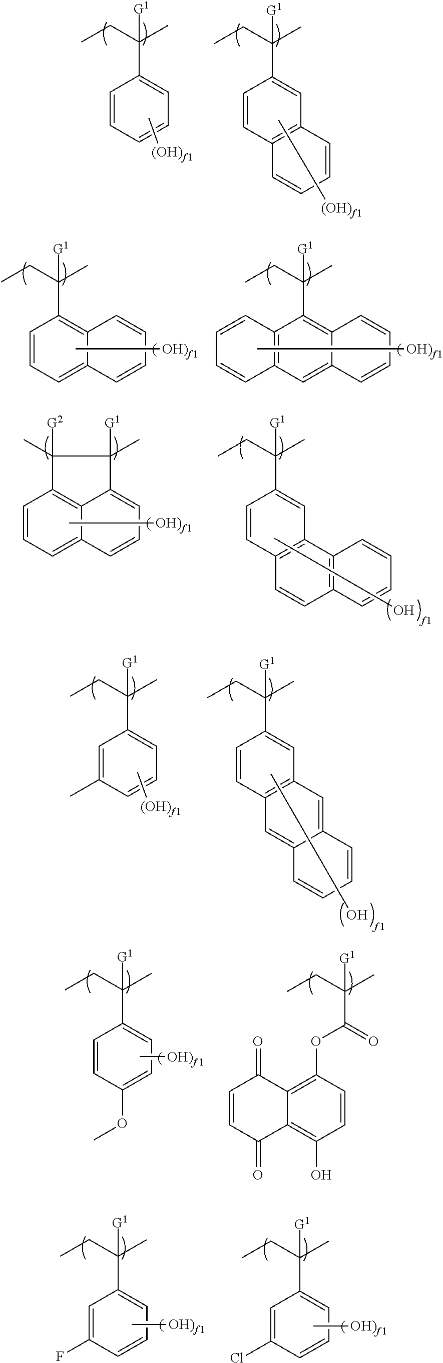

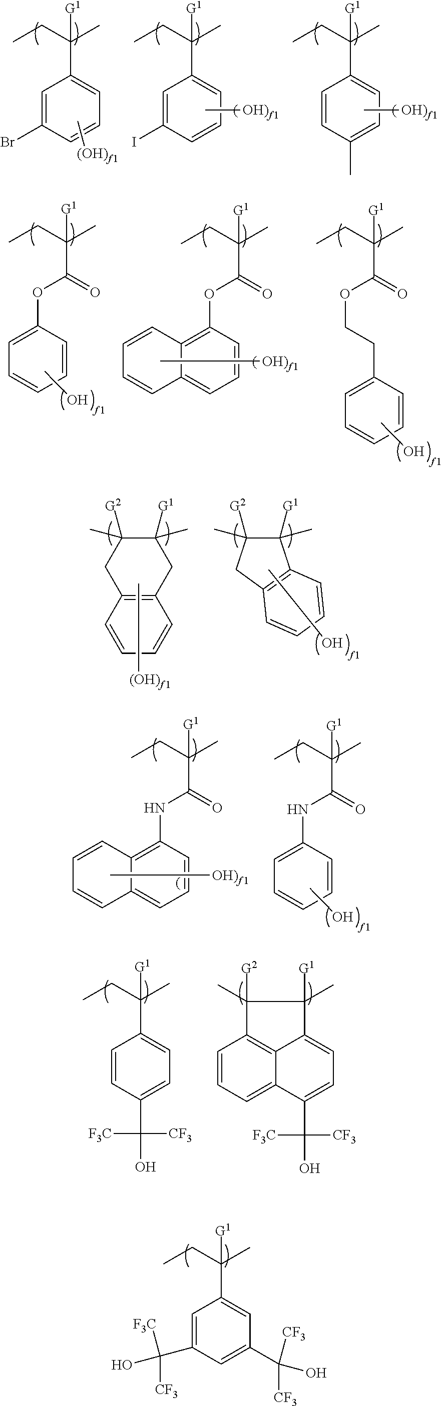

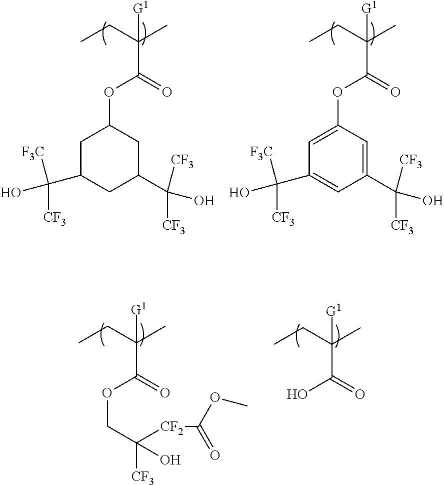

Repeating unit not having acid-decomposable group or acid group, but having fluorine atom, bromine atom, or iodine atom

The resin (P) may have, in addition to the above-described <repeating unit having an acid-decomposable group> and <repeating unit having an acid group>, a repeating unit not having an acid-decomposable group or an acid group, but having a fluorine atom, a bromine atom, or an iodine atom (hereinafter also referred to as “unit X”). This <repeating unit not having an acid-decomposable group or an acid group, but having a fluorine atom, a bromine atom, or an iodine atom> is preferably different from other types of repeating units belonging to the Group A such as the <repeating unit having a lactone group, a sultone group, or a carbonate group> and the <repeating unit having a photoacid generation group> described later.

The unit X is preferably a repeating unit represented by a formula (C).

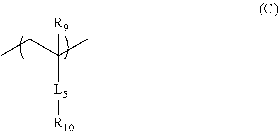

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

Specific examples of the repeating unit having a fluorine atom or an iodine atom include, for example, the repeating units described in [0116] to [0117] of WO2022/024928A. The above description is incorporated herein.

The content of the unit X relative to all the repeating units in the resin (P) is preferably 0 mol % or more, more preferably 5 mol % or more, and still more preferably 10 mol % or more. The content of the unit X relative to all the repeating units in resin (P) is preferably 50 mol % or less, more preferably 45 mol % or less, and still more preferably 40 mol % or less.

### Repeating Unit Having Lactone Group, Sultone Group, or Carbonate Group

The resin (P) may have a repeating unit having a lactone group, a sultone group, or a carbonate group (hereinafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The carbonate group is preferably a cyclic carbonic acid ester group.

For the repeating unit having a cyclic carbonic acid ester group, for example, the description in to of WO2022/024928A can be referred to. The above description is incorporated herein.

The resin (P) preferably has a repeating unit having a lactone group, a sultone group, or a carbonate group formed by removing, from a ring-member atom of a lactone structure represented by any one of formulas (LC1-1) to (LC1-22) below, a sultone structure represented by any one of formulas (SL1-1) to (SL1-3) below, or a cyclic carbonic acid ester structure represented by any one of formulas (CC1-1) to (CC1-2) below, one or more hydrogen atoms, and the lactone group, the sultone group, or the carbonate group may be directly bonded to the main chain. For example, a ring-member atom of the lactone group, the sultone group, or the carbonate group may constitute the main chain of the resin (P). The lactone group, the sultone group, and the carbonate group may have a substituent.

In the following structural formulas, R^{L} represent a substituent. When a plurality of R^{L} are present, the plurality of R^{L} may be the same or different. R^{L} may be, for example, an alkyl group having 1 to 8 carbon atoms, a cycloalkyl group having 4 to 10 carbon atoms, an alkoxy group having 1 to 8 carbon atoms, an alkoxycarbonyl group having 2 to 8 carbon atoms, a carboxyl group, a halogen atom, a cyano group, or an acid-decomposable group. e1 represent an integer of 0 to 4. When a plurality of e1 are present, the plurality of e1 may be the same or may be different. When e1 is 2 or more, the plurality of R^{L} present can be the same or different, and the plurality of R^{L} present may bonded together to form a ring.

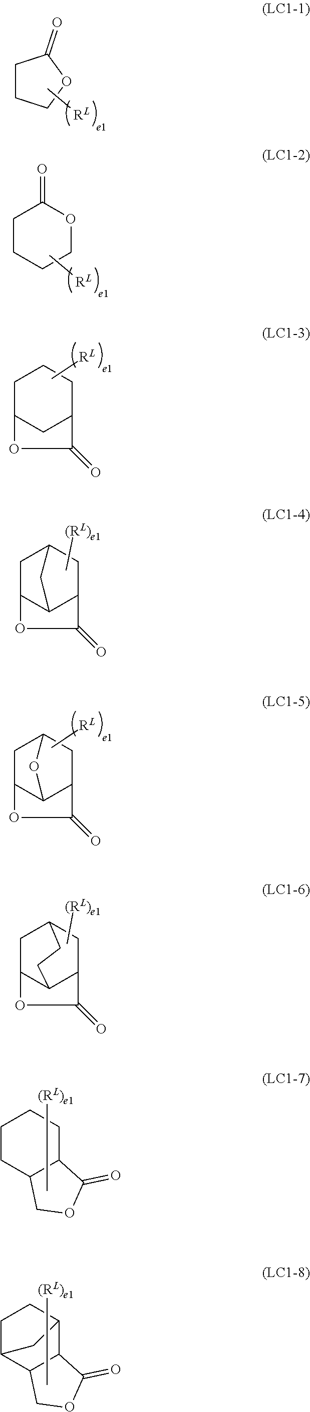

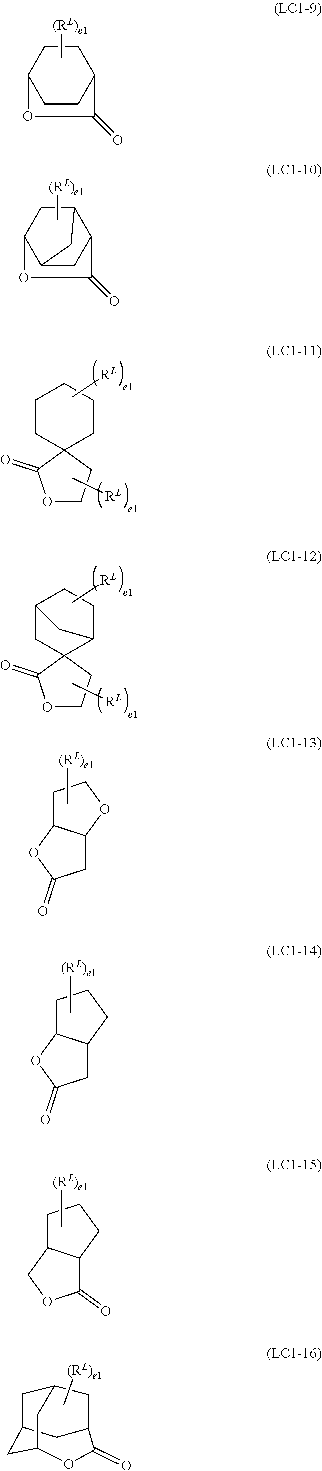

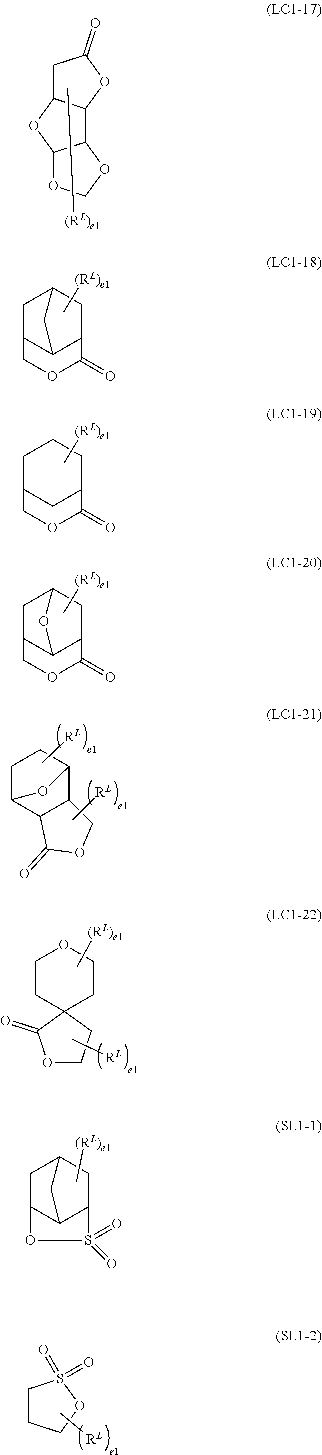

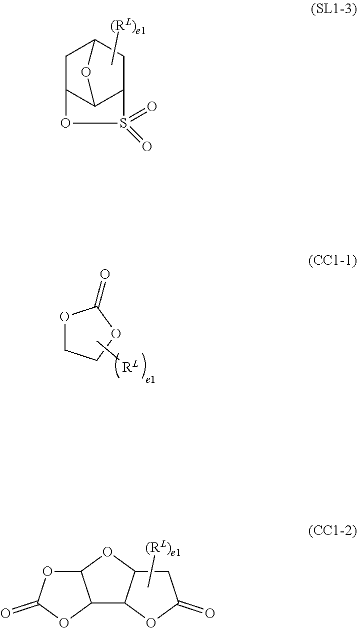

Examples of the repeating unit having a lactone group, a sultone group, or a carbonate group include a repeating unit represented by the following formula (AI-2).

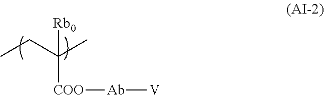

In the formula (AI-2), Rb₀ represents a hydrogen atom, a halogen atom, or an alkyl group having 1 to 4 carbon atoms.

The alkyl group of Rb₀ may have a substituent. The substituent that the alkyl group of Rb₀ may have may be a hydroxyl group or a halogen atom.

The halogen atom of Rb₀ may be a fluorine atom, a chlorine atom, a bromine atom, or an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, or a divalent linking group that is a combination of the foregoing. In particular, Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by removing one hydrogen atom from a ring-member atom of a lactone structure represented by any one of the formulas (LC1-1) to (LC1-22), a group formed by removing one hydrogen atom from a ring-member atom of a sultone structure represented by any one of the formulas (SL1-1) to (SL1-3), or a group formed by removing one hydrogen atom from a ring-member atom of a cyclic carbonic acid ester structure represented by any one of the formulas (CC1-1) to (CC1-2).

When the resin (P) includes the unit Y, the content of the unit Y is, relative to all the repeating units in the resin (P), preferably 1 mol % or more, and more preferably 10 mol % or more. The content of the unit Y is, relative to all the repeating units in the resin (P), preferably 85 mol % or less, more preferably 80 mol % or less, still more preferably 70 mol % or less, and particularly preferably 60 mol % or less.

### Repeating Unit Having Photoacid Generation Group

The resin (P) may have a repeating unit having a group that generates an acid upon irradiation with an actinic ray or a radiation (also referred to as “photoacid generation group”).

The repeating unit having a photoacid generation group may be a repeating unit represented by a formula (4).

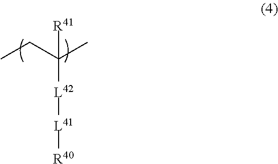

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

L⁴¹ represents a single bond or a divalent linking group, and preferably represents a single bond or an ester bond (—COO—).

L⁴² is preferably a linking group formed of at least one selected from the group consisting of an alkylene group, a cycloalkylene group, an arylene group, —O—, —CO—, —S—, —SO—, —SO₂—, and —NR—. R represents a hydrogen atom or an organic group (preferably an organic group having 1 to 10 carbon atoms such as an alkyl group, a cycloalkyl group, or an aryl group).

The alkylene group may be either linear or branched. The number of carbon atoms of the alkylene group is not particularly limited, but is preferably 1 to 10.

The cycloalkylene group may be a monocyclic cycloalkylene group or a polycyclic cycloalkylene group. The number of carbon atoms of the cycloalkylene group is not particularly limited, but is preferably 3 to 20, and more preferably 5 to 15.

The number of carbon atoms of the arylene group is not particularly limited, but is preferably 6 to 20, and more preferably 6 to 10.

The alkylene group, the cycloalkylene group, and the arylene group may have a substituent, and such substituents may be the above-described substituents T.

R⁴⁰ is preferably a group represented by the following formula (S4-1).

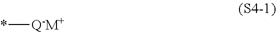

In the formula (S4-1), Q⁻ represents an acid residue, and M⁺ represents a cation. * represents a bonding site to L⁴¹.

The acid residue is a group formed by dissociation of a proton from an acid.

Q⁻ is preferably a carboxylate anion group (COO⁻), a sulfonate anion group (SO₃⁻), or a sulfonamide group (represented by N⁻—SO₂R^{N1}; R^{N1} represents an organic group, may be an organic group having 1 to 10 carbon atoms, and is preferably an alkyl group, a fluoroalkyl group, or an aryl group), and more preferably a sulfonate anion group.

The description, specific examples, and preferred ranges of M⁺ are the same as those described above for M⁺ in the salt compound.

Specific examples of the repeating unit having a photoacid generation group include the repeating units described in [0094] to [0105] of JP2014-041327A, the repeating units described in [0094] of WO2018/193954A, and the repeating units described in [0138] of WO2022/024928A. The above descriptions are incorporated herein.

Examples of the repeating unit represented by the formula (4) include the repeating units described in Paragraphs [0094] to [0105] of JP2014-041327A, and the repeating units described in Paragraph [0094] of WO2018/193954A.

When the resin (P) includes a repeating unit having a photoacid generation group, the content of the repeating unit having a photoacid generation group relative to all the repeating units in the resin (P) is preferably 1 mol % or more, and more preferably 5 mol % or more. The content of the repeating unit having a photoacid generation group relative to all the repeating units in the resin (P) is preferably 40 mol % or less, more preferably 35 mol % or less, and still more preferably 30 mol % or less.

### Repeating Unit Represented by Formula (V-1) or Formula (V-2)

The resin (P) may have a repeating unit represented by the following formula (V-1) or the following formula (V-2).

The repeating unit represented by the following formula (V-1) and the repeating unit represented by the following formula (V-2) are preferably repeating units different from the above-described repeating units.

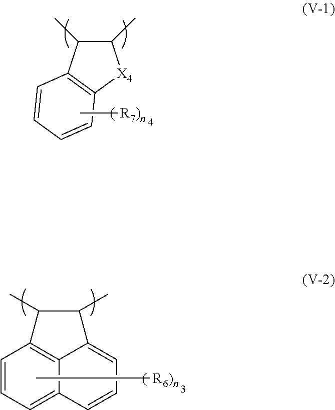

In the formulas (V-1) and (V-2), R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R is an alkyl group or a fluorinated alkyl group having 1 to 6 carbon atoms), or a carboxyl group. The alkyl group is preferably a linear, branched, or cyclic alkyl group having 1 to 10 carbon atoms. n3 represents an integer of 0 to 6. n4 represents an integer of 0 to 4. X₄ is a methylene group, an oxygen atom, or a sulfur atom.

Examples of the repeating unit represented by the formula (V-1) or the formula (V-2) include the repeating units described in Paragraph [0100] of WO2018/193954A.

### Repeating Unit for Lowering Mobility of Main Chain

The resin (P) may have a high glass transition temperature (Tg) from the viewpoint of suppressing excessive diffusion of the generated acid or pattern collapse during development. Tg may be more than 90° C., may be more than 100° C., may be more than 110° C., or may be more than 125° C. From the viewpoint of providing a high dissolution rate in the developer, Tg may be 400° C. or less, or may be 350° C. or less.

In this Specification, the glass transition temperature (Tg) of a polymer such as the resin (P) (hereinafter, “Tg's of the repeating units”) is calculated by the following method. First, for the repeating units included in the polymer, the Tg's of homopolymers composed only of the repeating units are individually calculated by the Bicerano method. Subsequently, the mass ratios (%) of the repeating units relative to all the repeating units in the polymer are calculated. Subsequently, the Fox equation (described in Materials Letters 62 (2008) 3152, for example) is used to calculate Tg's for the mass ratios and the Tg's are summed up to determine the Tg (° C.) of the polymer.

The Bicerano method is described in Prediction of polymer properties, Marcel Dekker Inc, New York (1993). The calculation of Tg by the Bicerano method can be performed using polymer physical property estimation software, MDL Polymer (MDL Information Systems, Inc.).

For the repeating unit for lowering the mobility of the main chain, the contents of [0144] to [0160] of WO2022/024928A are referred to.

Repeating Unit Having at Least One Type of Group Selected from the Group Consisting of Lactone Group, Sultone Group, Carbonate Group, Hydroxy Group, Cyano Group, and Alkali-Soluble Group

The resin (P) may have a repeating unit having at least one type of a group selected from the group consisting of a lactone group, a sultone group, a carbonate group, a hydroxy group, a cyano group, and an alkali-soluble group.

The repeating unit having a lactone group, a sultone group, or a carbonate group in the resin (P) may be the above-described repeating unit in <Repeating unit having lactone group, sultone group, or carbonate group>. The preferred content is also as described above in <Repeating unit having lactone group, sultone group, or carbonate group>.

The resin (P) may have a repeating unit having a hydroxy group or a cyano group. This improves the adhesiveness to the substrate and the affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano group include those described in Paragraphs [0081] to [0084] of JP2014-098921A.

The resin (P) may have a repeating unit having an alkali-soluble group.

Examples of the alkali-soluble group include a carboxyl group, a sulfonamide group, a sulfonylimide group, a bissulfonylimide group, and an aliphatic alcohol group substituted at the α-position with an electron-withdrawing group (for example, a hexafluoroisopropanol group), and is preferably a carboxyl group. When the resin (P) includes a repeating unit having an alkali-soluble group, it provides improved resolution particularly in the contact hole applications. Examples of the repeating unit having an alkali-soluble group include those described in Paragraphs and of JP2014-098921A.

### Repeating Unit Having Alicyclic Hydrocarbon Structure and not Exhibiting Acid-Decomposability

The resin (P) may have a repeating unit having an alicyclic hydrocarbon structure and not exhibiting acid-decomposability. This can result in, during liquid immersion exposure, a reduction in leaching of, from the resist film to the immersion liquid, low-molecular-weight components. Examples of the repeating unit having an alicyclic hydrocarbon structure and not exhibiting acid-decomposability include repeating units derived from 1-adamantyl (meth)acrylate, diamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (P) may have a repeating unit not having a hydroxy group or a cyano group and represented by a formula (III).

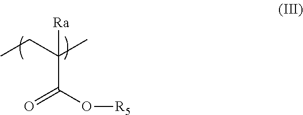

In the formula (III), R₅ represents a hydrocarbon group having at least one ring structure and not having a hydroxy group or a cyano group. Ra represents a hydrogen atom, an alkyl group, or a —CH₂—O—Ra₂ group. In the formula, Raz represents a hydrogen atom, an alkyl group, or an acyl group.

Examples of the repeating unit not having a hydroxy group or a cyano group and represented by the formula (III) include those described in Paragraphs [0087] to [0094] of JP2014-098921A.

### Other Repeating Unit

Furthermore, the resin (P) may have another repeating unit other than the above-described repeating units.

The resin (P) may have, for example, a repeating unit selected from the group consisting of a repeating unit having an oxathiane ring group, a repeating unit having an oxazolone ring group, a repeating unit having a dioxane ring group, and a repeating unit having a hydantoin ring group. Examples of the repeating unit include those described in [0170] of WO2022/024928A.

For the resin (P), the contents of [0171] to [0172] of WO2022/024928A can be further referred to.

The resin (P) can be synthesized by standard procedures (for example, radical polymerization).

The resin (P) has a weight-average molecular weight (Mw) of, a polystyrene-equivalent value determined by the GPC method, preferably 30,000 or less, more preferably 1,000 to 30,000, still more preferably 3,000 to 30,000, and particularly preferably 5,000 to 15,000.

The resin (P) has a dispersity (molecular weight distribution, Pd, Mw/Mn) of preferably 1 to 5, more preferably 1 to 3, still more preferably 1.0 to 3.0, and particularly preferably 1.1 to 2.0. As the dispersity lowers, the resolution becomes higher, the resist profile becomes better, the sidewalls of the resist pattern become smoother, and the roughness performance becomes higher.

When the solid substance (U) includes the resin (P), the content of the resin (P) is not particularly limited, but is, relative to the total solid content in the solution (Z), preferably 40 to 100 mass %, and more preferably 60 to 100 mass %.

Such resins (P) may be used alone or may be used in combination of two or more thereof. When two or more resins (P) are used, the total content thereof is preferably within such a preferred content range.

### Resin Having Phenolic Hydroxyl Group

The solid substance (U) may include a resin (also referred to as “resin (N)”) that has a phenolic hydroxyl group and is different from the above-described resin (P).

The resin (N) preferably includes a repeating unit having a phenolic hydroxyl group. The repeating unit having a phenolic hydroxyl group may be the above-described repeating unit represented by the formula (Pa2).

The content of the repeating unit having a phenolic hydroxyl group in the resin (N) is not particularly limited, but is, relative to all the repeating units in the resin (N), preferably 10 mol % or more, more preferably 20 mol % or more, and still more preferably 30 mol % or more. The content of the repeating unit having a phenolic hydroxyl group relative to all the repeating units in the resin (N) may be 100 mol % or less, may be 90 mol % or less, or may be 80 mol % or less.

The repeating unit having a phenolic hydroxyl group included in the resin (N) may be of one type, or may be of two or more types. When the resin (N) includes two or more types of repeating units having a phenolic hydroxyl group, the total content thereof is preferably within such a preferred content range.

The resin (N) may include another repeating unit other than those described above.

For specific examples of the repeating unit having a phenolic hydroxyl group, a group that the resin (N) preferably has, and the other repeating unit, the contents of [0238] to [0307] of WO2016/136563A are referred to.

When the solid substance (U) includes the resin (N), the content of the resin (N) is not particularly limited, but may be, relative to the total solid content in the solution (Z), 40 to 100 mass %, may be 50 to 100 mass %, or may be 60 to 100 mass %.

Such resins (N) may be used alone or may be used in combination of two or more thereof. When two or more resins (N) are used, the total content thereof is preferably within such a preferred content range.

### Crosslinking Agent

The solid substance (U) may include a crosslinking agent.

The crosslinking agent is preferably a compound that can form a bond with a compound having a phenolic hydroxyl group.

The crosslinking agent is preferably a compound having, as a cross-linking group, two or more hydroxymethyl groups, alkoxymethyl groups, acyloxymethyl groups, or alkoxy methyl ether groups, or an epoxy compound.

The crosslinking agent is more preferably an alkoxymethylated or acyloxymethylated melamine compound, an alkoxymethylated or acyloxymethylated urea compound, a hydroxymethylated or alkoxymethylated phenol compound, or an alkoxymethyl etherified phenol compound.

For the crosslinking agent, the epoxy compounds in [0196] to [0200] of JP2013-64998A ([0271] to [0277] of corresponding US2014/0178634A) and the oxetane compounds described in [0065] of JP2013-258332A can be referred to, and the contents thereof are incorporated herein.

The crosslinking agent preferably has a structure represented by the following formula (CL-1).

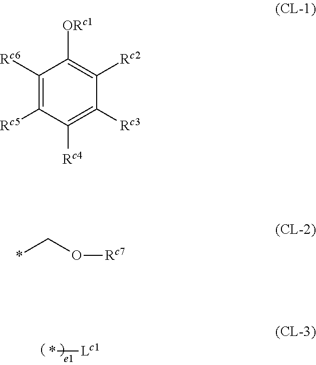

In the formula (CL-1), R^{c1} to R^{c6} each independently represent a hydrogen atom, an organic group, or a bonding site to a linking group or single bond represented by L^{c1} in the formula (CL-3), provided that at least one of R^{c2} to R^{c6} is a structure represented by the formula (CL-2).

In the formula (CL-2), R^{c7} represents a hydrogen atom or an organic group (preferably an organic group having 1 to 30 carbon atoms), and * represents a bonding site in any of R^{c2} to R^{c6}.

In the formula (CL-3), L^{c1} represents a linking group or a single bond, * represents a bonding site in any of R^{c1} to R^{c6}, and e1 represents an integer of 2 to 5.

When the crosslinking agent is a compound represented by the formula (CL-1), R^{c1} to R^{c6} each independently represent a hydrogen atom or an organic group (preferably an organic group having 1 to 50 carbon atoms). The organic group is, for example, an alkyl group, a cycloalkyl group, or an aryl group, or a group in which such groups are linked together via an alkylene group, an arylene group, a carboxylic acid ester bond, a carbonic acid ester bond, an ether bond, a thioether bond, a sulfo group, a sulfone group, a urethane bond, a urea bond, or a group that is a combination of the foregoing.

At least one of R^{c2} to R^{c6} is a structure represented by the formula (CL-2). Specific examples of the organic group represented by R^{c7} in the formula (CL-2) are the same as those described above for the organic groups represented by R^{c1} to R^{c6}. A single molecule preferably has two or more structures represented by the formula (CL-2).

The crosslinking agent may be a compound in which 1 to 5 structures represented by the formula (CL-1) are linked together via a linking group or single bond represented by L^{c1} in the formula (CL-3). In this case, at least one of R^{c1} to R^{c6} in the formula (CL-1) represents a bonding site to a linking group or single bond represented by the formula (CL-3).

The linking group represented by L^{c1} in the formula (CL-3) may be, for example, an alkylene group, an arylene group, a carboxylic acid ester bond, a carbonic acid ester bond, an ether bond, a thioether bond, a sulfo group, a sulfone group, a urethane bond, a urea bond, or a group that is a combination of two or more of the foregoing, and is preferably an alkylene group, an arylene group, or a carboxylic acid ester bond.

e1 preferably represents 2 or 3.

For specific examples of L^{c1}, the descriptions in [0059] to [0062] of WO2016/136563A can be referred to, and these contents are incorporated herein.

For specific examples of the crosslinking agent, the descriptions in [0064] to [0066] of WO2016/136563A can be referred to, and these contents are incorporated herein.

Other examples of the crosslinking agent include the following (i) compounds having an N-hydroxymethyl group, an N-alkoxymethyl group, or an N-acyloxymethyl group, and (ii) epoxy compounds. Specifically, the compounds represented by the general formulas described in [0294] to [0315] of JP2012-242556A can be suitably used. In particular, the (i) compounds having an N-hydroxymethyl group, an N-alkoxymethyl group, or an N-acyloxymethyl group are preferably compounds having 2 or more (more preferably 2 to 8) partial structures represented by the following formula (CLNM-1).

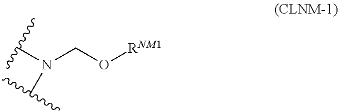

In the formula (CLNM-1), R^{NM1} represents a hydrogen atom, an alkyl group, a cycloalkyl group, or an oxoalkyl group.

More preferred embodiments of the compound having two or more partial structures represented by the formula (CLNM-1) include a urea-based crosslinking agent represented by the following formula (CLNM-2), an alkylene urea-based crosslinking agent represented by the following formula (CLNM-3), a glycoluril-based crosslinking agent represented by the following formula (CLNM-4), and a melamine-based crosslinking agent represented by the following formula (CLNM-5).

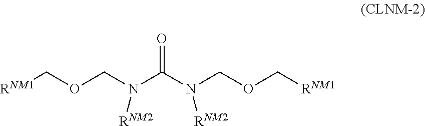

In the formula (CLNM-2), R^{NM1} have the same meaning as R^{NM1} in the formula (CLNM-1). The plurality of R^{NM1} may be the same or may be different.

R^{NM2} represent a hydrogen atom, an alkyl group (preferably having 1 to 6 carbon atoms), or a cycloalkyl group (preferably having 5 to 6 carbon atoms). The plurality of R^{NM2} may be the same or may be different.

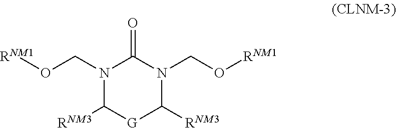

In the formula (CLNM-3), R^{NM1} have the same meaning as R^{NM1} in the formula (CLNM-1). The plurality of R^{NM1} may be the same or may be different.

R^{NM3} represent a hydrogen atom, a hydroxy group, a linear or branched alkyl group (preferably having 1 to 6 carbon atoms), a cycloalkyl group (preferably having 5 to 6 carbon atoms), an oxoalkyl group (preferably having 1 to 6 carbon atoms), an alkoxy group (preferably having 1 to 6 carbon atoms), or an oxoalkoxy group (preferably having 1 to 6 carbon atoms). The plurality of R^{NM3} may be the same or may be different.

G represents a single bond, an oxygen atom, a sulfur atom, an alkylene group (preferably having 1 to 3 carbon atoms), or a carbonyl group.

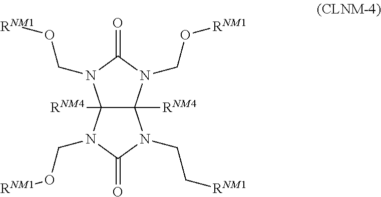

In the formula (CLNM-4), R^{NM1} have the same meaning as R^{NM1} in the formula (CLNM-1). The plurality of R^{NM1} may be the same or may be different.

R^{NM4} represent a hydrogen atom, a hydroxy group, an alkyl group, a cycloalkyl group, or an alkoxy group. The plurality of R^{NM4} may be the same or may be different.

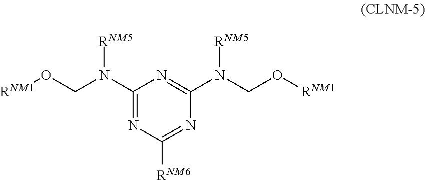

In the formula (CLNM-5), R^{NM1} have the same meaning as R^{NM1} in the formula (CLNM-1). The plurality of R^{NM1} may be the same or may be different.

R^{NM5} represent a hydrogen atom, an alkyl group, a cycloalkyl group, an aryl group, or an atomic group represented by the following formula (CLNM-5′). The plurality of R^{NM5} may be the same or may be different.

R^{NM6} represents a hydrogen atom, an alkyl group, a cycloalkyl group, an aryl group, or an atomic group represented by the following formula (CLNM-5″).

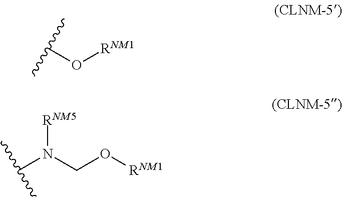

In the formula (CLNM-5′), R^{NM1} has the same meaning as R^{NM1} in the formula (CLNM-1).

In the formula (CLNM-5″), R^{NM1} has the same meaning as R^{NM1} in the formula (CLNM-1). R^{NM5} has the same meaning as R^{NM5} in the formula (CLNM-5).

For R^{NM5} and R^{NM6}, the alkyl group is preferably an alkyl group having 1 to 6 carbon atoms, the cycloalkyl group is preferably a cycloalkyl group having 5 to 6 carbon atoms, and the aryl group is preferably an aryl group having 6 to 10 carbon atoms.

The groups represented by R^{NM1} to R^{NM6} in the formulas (CLNM-1) to (CLNM-5) may further have a substituent.

For specific examples of the crosslinking agent, the descriptions in [0087] to [0089] of WO2016/136563A can also be referred to, and these contents are incorporated herein.

When the solid substance (U) includes a crosslinking agent, the content of the crosslinking agent is not particularly limited, but may be, relative to the total solid content in the solution (Z), 3 to 100 mass % or may be 5 to 100 mass %.

Such crosslinking agents may be used alone or may be used in combination of two or more thereof. When two or more thereof are used, the total content thereof is preferably within such a preferred content range.

### Acid Diffusion Control Agent

The solid substance (U) may include an acid diffusion control agent.

The acid diffusion control agent serves as a quencher that traps the acid generated from the photoacid generator or the like upon exposure and that suppresses the reaction of the acid-decomposable resin, in the unexposed regions, caused by the excess of the generated acid.

The type of the acid diffusion control agent is not particularly limited, and examples thereof include a basic compound (DA), a low-molecular-weight compound (DB) having a nitrogen atom and having a group that leaves by the action of an acid, and a compound (DC) whose acid diffusion control ability is reduced or lost upon irradiation with an actinic ray or a radiation.

The compound (DC) may be an onium salt compound (DD) that generates an acid that is a weak acid relative to the acid generated from the photoacid generator upon irradiation with an actinic ray or a radiation (also referred to as “onium salt compound that becomes a weak acid relative to the photoacid generator”), and a basic compound (DE) whose basicity is reduced or lost upon irradiation with an actinic ray or a radiation.

Specific examples of the basic compound (DA) include, for example, those described in Paragraphs [0132] to [0136] of WO2020/066824A; specific examples of the basic compound (DE) whose basicity is reduced or lost upon irradiation with an actinic ray or a radiation include those described in Paragraphs [0137] to [0155] of WO2020/066824A, and those described in Paragraph [0164] of WO2020/066824A; and, specific examples of the low-molecular-weight compound (DB) having a nitrogen atom and having a group that leaves by the action of an acid include those described in Paragraphs [0156] to [0163] of WO2020/066824A.

The onium salt compound (DD) that becomes a weak acid relative to the photoacid generator can be the above-described salt compound.

Specific examples of the onium salt compound (DD) that becomes a weak acid relative to the photoacid generator include, for example, those described in Paragraphs [0305] to [314] of WO2020/158337A.

In addition to those described above, for example, the publicly known compounds disclosed in Paragraphs [0627] to [0664] in US2016/0070167A, Paragraphs [0095] to [0187] in US2015/0004544A, Paragraphs [0403] to [0423] in US2016/0237190A, and Paragraphs [0259] to [0328] in US2016/0274458A can be suitably used as acid diffusion control agents.

When the solid substance (U) includes an acid diffusion control agent, the content of the acid diffusion control agent is not particularly limited, but is, relative to the total solid content in the solution (Z), preferably 0.1 to 100 mass %, more preferably 0.1 to 100 mass %, and still more preferably 1.0 to 100 mass %.

Such acid diffusion control agents may be used alone or may be used in combination of two or more thereof. When two or more thereof are used, the total content thereof is preferably within such a preferred content range.

### Hydrophobic Resin

The solid substance (U) may include a hydrophobic resin. The hydrophobic resin is a resin (also referred to as “hydrophobic resin (E)”) different from the above-described resin (P) and resin (N).

The hydrophobic resin (E) is preferably designed so as to be localized in the surface of a resist film; however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin (E) may be control of static and dynamic contact angles (for water) at the surface of the resist film, and suppression of outgassing.

From the viewpoint of localization to the film surface layer, the hydrophobic resin (E) preferably has any one or more, more preferably two or more, of a fluorine atom, a silicon atom, and a CH₃ partial structure included in a side chain portion of the resin. The hydrophobic resin preferably has a hydrocarbon group having 5 or more carbon atoms. The resin may have such a group in the main chain or, as a substituent, in a side chain.

Examples of the hydrophobic resin (E) include the compounds described in Paragraphs [0275] to [0279] in WO2020/004306A.

When the solid substance (U) includes the hydrophobic resin (E), the content of the hydrophobic resin (E) is not particularly limited, but is, relative to the total solid content in the solution (Z), preferably 0.01 to 100 mass %, and more preferably 0.1 to 100 mass %.

Such hydrophobic resins (E) may be used alone or may be used in combination of two or more thereof. When two or more thereof are used, the total content thereof is preferably within such a preferred content range.

### Compound Having Phenolic Hydroxyl Group

The solid substance (U) may include a compound having a phenolic hydroxyl group (also referred to as “compound (F)”) and being different from the above-described components. The compound (F) is a compound intramolecularly including one or more phenolic hydroxyl groups.

The compound (F) preferably has a molecular weight of 100 or more and 2000 or less, and more preferably 400 or more and 1200 or less.

Examples of the compound (F) include the compounds described in to of JP2021-92779A, and the compounds described in to of WO2021/215163A.

The compound (F) employed may be a phenol compound represented by any one of the formulas (FL-1) to (FL-12) below. In the formulas below, L^{f1} to L^{f8} each independently represent a hydrogen atom or a substituent, and at least one of them in one molecule is a hydrogen atom. When L^{f1} to L^{f8} are a substituent, it is preferably an alkyl group, an aryl group, or an aralkyl group.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. The alkyl group moiety in the aralkyl group is also the same as described above.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthranyl group, and more preferably a phenyl group. The aryl group moiety in the aralkyl group is also the same as described above.

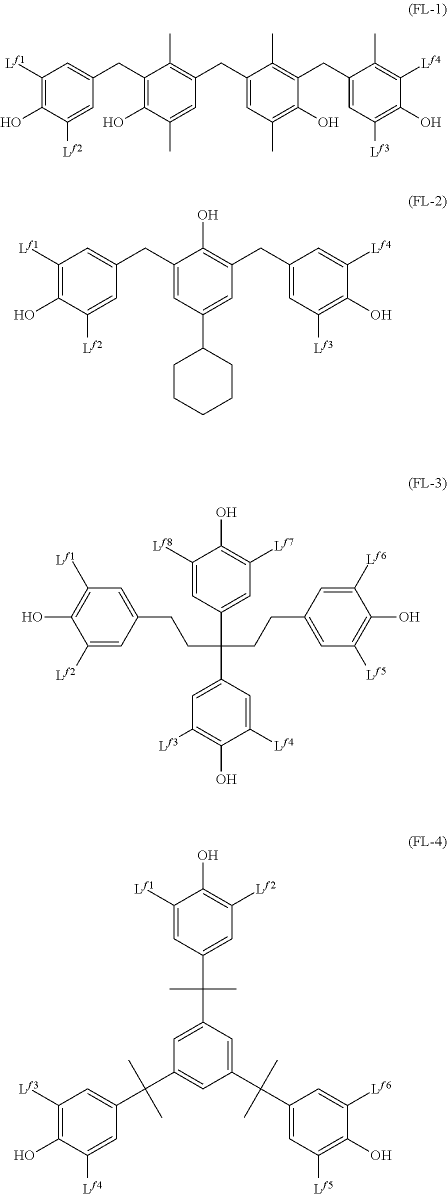

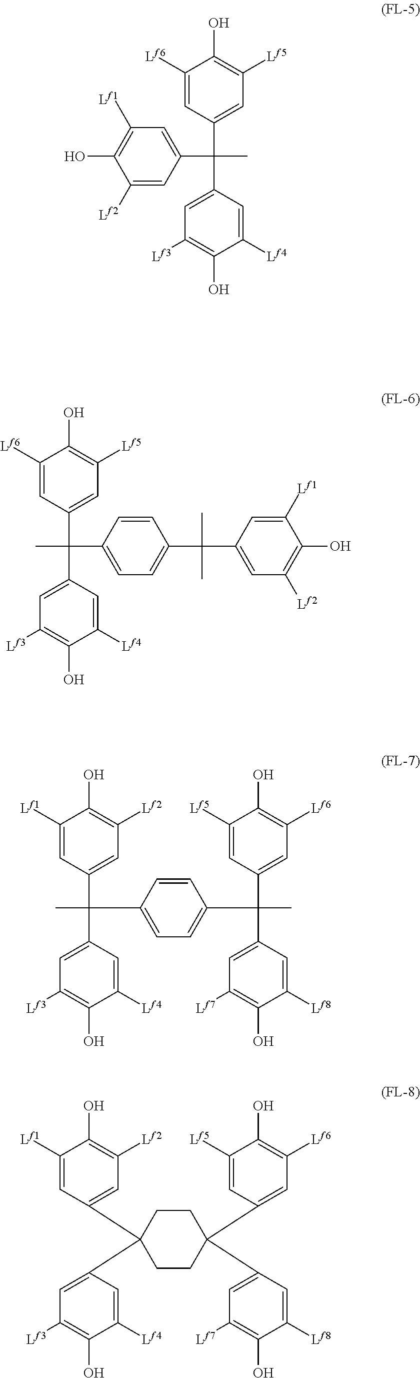

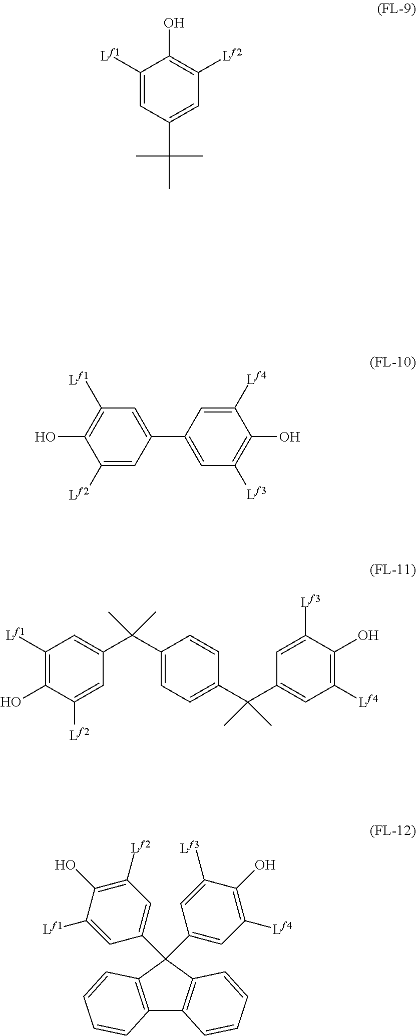

When the solid substance (U) includes the compound (F), the content of the compound (F) is not particularly limited, but is, relative to the total solid content in the solution (Z), preferably 0.01 to 100 mass %, and more preferably 0.1 to 100 mass %.

Such compounds (F) may be used alone or may be used in combination of two or more thereof. When two or more thereof are used, the total content thereof is preferably within such a preferred content range.

### Surfactant

The solid substance (U) may include a surfactant.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

Such surfactants may be used alone or may be used in combination of two or more thereof.

When the solid substance (U) includes a surfactant, the content of the surfactant is not particularly limited, but is, relative to the total solid content in solution (Z), preferably 0.0001 to 100 mass %, more preferably 0.0005 to 100 mass %, and still more preferably 0.1 to 100 mass %.

Such surfactants may be used alone or may be used in combination of two or more thereof. When two or more thereof are used, the total content thereof is preferably within such a preferred content range.

### Other Additives

The solid substance (U) may include other additives other than those described above. Examples of other additives include a crosslinking agent, a dissolution-inhibiting compound, a dye, a plasticizer, a photosensitizer, a light absorbent, and/or a compound that promotes solubility in the developer (for example, a phenol compound having a molecular weight of 1000 or less, or an alicyclic or aliphatic compound including a carboxyl group).

The “dissolution-inhibiting compound” is a compound that is decomposed by the action of an acid to cause a decrease in the degree of solubility in organic-based developers, and has a molecular weight of 3000 or less.

When the solid substance (U) includes other additives, the content of the other additives is not particularly limited, but may be, relative to the total solid content of the solution (Z), 0.0001 to 100 mass %, may be 20 mass % or less, may be 10 mass % or less, or may be 5 mass % or less.

Other additives may be used alone or may be used in combination of two or more thereof. When two or more thereof are used, the total content thereof is preferably within such a preferred content range.

### Concentration Step

The method for producing a solution of the present invention may further have a concentration step. That is, in the method for producing a solution of the present invention, the solution obtained in the solution-forming step may be concentrated. As a result of the concentration, the remaining low-boiling-point compounds can be removed. During the concentration, as in the solution-forming step, a container including a resin in at least a portion of the inner wall surface is preferably used.

The concentration can be performed by a publicly known concentration method. The concentration can be performed at atmospheric pressure or under a reduced pressure, but is preferably performed under a reduced pressure.

In the case of performing the concentration under a reduced pressure, the degree of the reduced pressure is preferably 50 kPa or less, more preferably 40 kPa or less, and still more preferably 30 kPa or less. The lower limit value of the degree of the reduced pressure is not particularly limited, but may be, for example, 0.05 kPa or more.

The temperature during the concentration is not particularly limited, but is preferably 20° C. or more, more preferably 30° C. or more, and still more preferably 40° C. or more. The temperature during the concentration is preferably 90° C. or less, more preferably 70° C. or less, and still more preferably 50° C. or less.

The concentration is preferably performed under stirring. The stirring can be performed using a stirring impeller, a magnetic stirrer, a rotary evaporator, or the like. In the case of using a stirring impeller and a magnetic stirrer, the surfaces of the stirring impeller and the stirrer tip that contact the solution are preferably covered with a resin.

### First Embodiment of Method for Producing Resist Composition

The method for producing a resist composition of the present invention may be a method for producing a resist composition (also referred to as “first embodiment of the method for producing a resist composition”) in which the solution (solution (Z)) produced by the above-described method for producing a solution is used to prepare a resist composition.

In the first embodiment of the method for producing a resist composition, the solution (Z) alone may be used to produce the resist composition, or the solution (Z) and another component may be used. Examples of the other component include a solid substance (also referred to as “solid substance (V)”) and a solvent (also referred to as “solvent (T)”).

The solid substance (V) may be the same solid substance as the solid substance included in the solution (Z) (the solid substance (U)), may be a solid substance different from the solid substance (U), or may be a mixture of the same solid substance as the solid substance (U) and a solid substance different from the solid substance (U).

The solvent (T) may be the same solvent as the solvent(S) included in the solution (Z), may be a solvent different from the solvent(S), or may be a mixed solvent of the same solvent as the solvent(S) and a solvent different from the solvent(S).

In the first embodiment of the method for producing a resist composition, the solution (Z) and at least one selected from the group consisting of the solid substance (V) and the solvent (T) are preferably placed into a container and mixed together. The container employed is preferably a container including a resin in at least a portion of the inner wall surface. The container including a resin in at least a portion of the inner wall surface is the same as that described above in the method for producing the solution (Z).

### Solvent (T)

The description, specific examples, and preferred ranges of the solvent (T) are the same as those described above for the solvent(S).

The solvent (T) is preferably an organic solvent.

The solvent (T) may be formed of a single solvent or a mixed solvent including two or more solvents.

The organic solvent preferably includes at least one of (M1) a propylene glycol monoalkyl ether carboxylate or (M₂) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M₁) and (M₂).

Details of the component (M₁) and the component (M₂) are described in Paragraphs to in WO2020/004306A, and these contents are incorporated herein.

When the solvent (T) further includes a component other than the components (M₁) and (M₂), the content of the component other than the components (M₁) and (M₂) relative to the total amount of the solvent (T) is preferably 5 to 30 mass %.

The amount of the solvent (T) used is not particularly limited, but is preferably set such that the solid-content concentration of the resist composition produced by the first embodiment of the method for producing a resist composition is 0.5 to 30 mass %, and more preferably 1 to 20 mass %.

### Solid Substance (V)

The description, specific examples, and preferred ranges of the solid substance (V) are the same as those described above for the solid substance (U).

When the solid substance (V) includes a salt compound, the content of the salt compound is not particularly limited, but is, relative to the total solid content in the resist composition produced by the first embodiment of the method for producing a resist composition, preferably 0.1 mass % or more and 60.0 mass % or less, more preferably 0.5 mass % or more and 50.0 mass % or less, and still more preferably 1.0 mass % or more and 40.0 mass % or less.

Such salt compounds may be used alone or may be used in combination of two or more thereof. When two or more thereof are used, the total content thereof is preferably within such a preferred content range.

When the solid substance (V) includes the resin (P), the content of the resin (P) is not particularly limited, but is, relative to the total solid content in the resist composition produced by the first embodiment of the method for producing a resist composition, preferably 40.0 to 99.9 mass % and more preferably 60.0 to 90.0 mass %.

Such resins (P) may be used alone or may be used in combination of two or more thereof. When two or more resins (P) are used, the total content thereof is preferably within such a preferred content range.

When the solid substance (V) includes the resin (N), the content of the resin (N) is not particularly limited, but is, relative to the total solid content in the resist composition produced by the first embodiment of the method for producing a resist composition, preferably 40.0 to 99.9 mass %, and more preferably 60.0 to 90.0 mass %.

Such resins (N) may be used alone or may be used in combination of two or more thereof. When two or more resins (N) are used, the total content thereof is preferably within such a preferred content range.

When the solid substance (V) includes a crosslinking agent, the content of the crosslinking agent is not particularly limited, but, relative to the total solid content in the resist composition produced by the first embodiment of the method for producing a resist composition, may be 3 to 65 mass %, or may be 5 to 50 mass %.

Such crosslinking agents may be used alone or may be used in combination of two or more thereof. When two or more thereof are used, the total content thereof is preferably within such a preferred content range.

When the solid substance (V) includes an acid diffusion control agent, the content of the acid diffusion control agent is not particularly limited, but is, relative to the total solid content in the resist composition produced by the first embodiment of the method for producing a resist composition, preferably 0.1 to 30.0 mass %, more preferably 0.1 to 15.0 mass %, and still more preferably 1.0 to 15.0 mass %.

Such acid diffusion control agents may be used alone or may be used in combination of two or more thereof. When two or more thereof are used, the total content thereof is preferably within such a preferred content range.

When the solid substance (V) includes the hydrophobic resin (E), the content of the hydrophobic resin (E) is not particularly limited, but is, relative to the total solid content in the resist composition produced by the first embodiment of the method for producing a resist composition, preferably 0.01 to 20.0 mass %, and more preferably 0.1 to 15.0 mass %.

Such hydrophobic resins (E) may be used alone or may be used in combination of two or more thereof. When two or more thereof are used, the total content thereof is preferably within such a preferred content range.

When the solid substance (V) includes the compound (F), the content of the compound (F) is not particularly limited, but is, relative to the total solid content in the resist composition produced by the first embodiment of the method for producing a resist composition, preferably 0.01 to 40.0 mass %, and more preferably 0.1 to 30.0 mass %.

Such compounds (F) may be used alone or may be used in combination of two or more thereof. When two or more thereof are used, the total content thereof is preferably within such a preferred content range.

When the solid substance (V) includes a surfactant, the content of the surfactant is not particularly limited, but is, relative to the total solid content in the resist composition produced by the first embodiment of the method for producing a resist composition, preferably 0.0001 to 2.0 mass %, more preferably 0.0005 to 1.0 mass %, and still more preferably 0.1 to 1.0 mass %.

Such surfactants may be used alone or may be used in combination of two or more thereof. When two or more thereof are used, the total content thereof is preferably within such a preferred content range.

In the first embodiment of the method for producing a resist composition, in the case of using the solid substance (V), a portion of or the entirety of the solid substance (V) is preferably dissolved in the solution (Z) or the solvent (T). At this time, when the solid substance (V) is formed of a single solid substance alone, a portion of or the entirety of the single solid substance may be dissolved. Alternatively, when the solid substance (V) includes two or more solid substances, a portion of or the entirety of at least one solid substance thereof may be dissolved.

The temperature at which the solid substance (V) is dissolved in the solution (Z) or the solvent (T) is not particularly limited, but is preferably 0 to 90° C., more preferably 10 to 70° C., and particularly preferably 15 to 50° C.

At the time of dissolution of the solid substance (V) in the solution (Z) or the solvent (T), the solution (Z) or the solvent (T) may be stirred. The stirring can be performed using a stirring impeller (stirring blade), a magnetic stirrer, a rotary mixer, or the like. In the case of using a stirring impeller and a magnetic stirrer, the surfaces of the stirring impeller and the stirrer tip that contact the solution (Z) or the solvent (T) are preferably covered with a resin. The resin may be the same as the above-described resin used for the container.

Note that the completion of dissolution of the solid substance (V) in the solution (Z) or the solvent (T) can be confirmed by, for example, the same method as described above in the method for producing the solution (Z).

### Second Embodiment of Method for Producing Resist Composition

The method for producing a resist composition of the present invention may be a method for producing a resist composition (also referred to as “second embodiment of the method for producing a resist composition”) including a step of placing, into a container including a resin in at least a portion of the inner wall surface, one or more solid substances used as components of a resist composition and a solvent, and dissolving a portion of or the entirety of a solid content formed of the one or more solid substances.

In the first embodiment of the method for producing a resist composition, the solution (Z) is used to prepare the resist composition, whereas, in the second embodiment of the method for producing a resist composition, the solution (Z) is not necessarily used. In the second embodiment of the method for producing a resist composition, for example, the solution (Z) is not used and a solid substance that is a dry powder or a wet powder may be used. However, in the second embodiment of the method for producing a resist composition, the solution (Z) may also be used.

The container including a resin in at least a portion of the inner wall surface and used in the second embodiment of the method for producing a resist composition is the same as that described above in the method for producing the solution (Z).

The solid substance used in the second embodiment of the method for producing a resist composition is the same as the above-described solid substance (U). The content of a salt compound in a case where the solid substance used in the second embodiment of the method for producing a resist composition includes the salt compound, the content of the resin (P) in a case where the solid substance includes the resin (P), the content of an acid diffusion control agent in a case where the solid substance includes the acid diffusion control agent, the content of the hydrophobic resin (E) in a case where the solid substance includes the hydrophobic resin (E), and the content of a surfactant in a case where the solid substance includes the surfactant are respectively the same as those described above in the first embodiment of the method for producing a resist composition.

The solvent used in the second embodiment of the method for producing a resist composition is the same as the above-described solvent (S).

The amount of solvent used is preferably set such that the solid-content concentration of the resist composition produced by the second embodiment of the method for producing a resist composition is 0.5 to 30 mass %, and more preferably 1 to 20 mass %.

The temperature at which the solid substance is dissolved in the solvent is not particularly limited, but is preferably 0 to 90° C., more preferably 10 to 70° C., and particularly preferably 15 to 50° C.

At the time of dissolution of the solid substance in the solvent, the solution may be stirred. For the stirring, a stirring impeller (stirring blade), a magnetic stirrer, a rotary mixer, or the like can be used. In the case of using a stirring impeller and a magnetic stirrer, the surfaces of the stirring impeller and the stirrer tip that contact the solution are preferably covered with a resin. The resin may be the same as the above-described resin used for the container.

Note that the completion of dissolution of the solid substance in the solvent can be confirmed by the same method as the above-described method in the method for producing the solution (Z).

### Resist Composition

The resist compositions produced by the first embodiment of the method for producing a resist composition and the second embodiment of the method for producing a resist composition may be a positive resist composition or a negative resist composition. Such a resist composition may be a resist composition for alkali development or a resist composition for organic-solvent development. The resist composition may be a chemical amplification resist composition or a non-chemical amplification resist composition.

The resist composition can be used to form a resist film.

### Pattern Forming Method

The present invention also relates to a pattern forming method including: a resist film formation step of forming a resist film using the resist composition produced by the above-described first embodiment of the method for producing a resist composition or the above-described second embodiment of the method for producing a resist composition; an exposure step of exposing the resist film; and a development step of developing the exposed resist film using a developer.

The procedure of the pattern forming method of the present invention preferably includes the following steps.

Step 1: a step of using the resist composition produced by the first embodiment of the method for producing a resist composition or the second embodiment of the method for producing a resist composition to form a resist film on a substrate;

Step 2: a step of exposing the resist film; and Step 3: a step of developing the exposed resist film using a developer.

Hereinafter, procedures of the steps will be individually described in detail.

### Step 1: Resist Film Formation Step

The step 1 is a step of using the resist composition produced by the first embodiment of the method for producing a resist composition or the second embodiment of the method for producing a resist composition to form a resist film on a substrate.

The process of using the resist composition to form a resist film on a substrate may be, for example, a process of applying the resist composition onto the substrate.

Note that the resist composition is preferably filtered through a filter before the application as needed. The filter preferably has a pore size of 0.1 μm or less, more preferably 0.05 μm or less, and still more preferably 0.03 μm or less. The filter is preferably formed of polytetrafluoroethylene, polyethylene, or nylon.

The resist composition can be applied onto a substrate used in the production of integrated circuit elements (for example, formed of silicon or silicon dioxide-covered silicon) by an appropriate application process using a spinner, a coater, or the like. The application process is preferably spin-coating using a spinner. The spin-coating using a spinner is preferably performed at a rotation rate of 1000 to 3000 rpm (rotations per minute).

After application of the resist composition, the substrate may be dried to form a resist film. Note that, as needed, as underlayers of the resist film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the resist film is not particularly limited, but is, from the viewpoint of enabling formation of more precise fine patterns, preferably 10 to 120 nm. In particular, in the case of employing EUV exposure, the film thickness of the resist film is more preferably 10 to 65 nm, and still more preferably 15 to 50 nm. In the case of employing ArF liquid immersion exposure, the film thickness of the resist film is more preferably 10 to 120 nm, and still more preferably 15 to 90 nm.

Note that, for an overlying layer of the resist film, a topcoat composition may be used to form a topcoat.

The topcoat composition preferably does not mix with the resist film, and can be uniformly applied for an overlying layer of the resist film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the resist film. Specific examples of the basic compound that can be included in the topcoat include basic compounds that may be included in the composition of the present invention.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the resist film.

The exposure process may be a process of irradiating the formed resist film, through a predetermined mask, with an actinic ray or a radiation.

Examples of the actinic ray or the radiation include infrared light, visible light, ultraviolet light, far-ultraviolet light, extreme ultraviolet light, X-rays, and an electron beam; preferred is 250 nm or less; more preferred is 220 nm or less; particularly preferred is far-ultraviolet light having wavelengths of 1 to 200 nm; and specific examples thereof include the KrF excimer laser (248 nm), the ArF excimer laser (193 nm), the F₂ excimer laser (157 nm), EUV (13.5 nm), X-rays, and an electron beam.

In particular, in the case of forming a large-area pattern on a wafer using an electron beam, electron beam proximity effect correction software may be used. The use of this software can correct irradiation energy for each patterning position and can improve the pattern profile uniformity between the central and peripheral portions of the pattern.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed resist film to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less. Other step

The pattern forming method preferably includes a step of using a rinse liquid to perform rinsing after the step 3.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and can be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the resist composition and the pattern forming method (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph [0321] in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter and the adsorption material may be used in combination. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

The present invention also relates to a method for producing an electronic device, the method including the above-described pattern forming method, and an electronic device produced by the production method.

Preferred embodiments of the electronic device of the present invention include embodiments of being mounted on electric and electronic apparatuses (home appliances, OA (Office Automation), media-related devices, optical devices, communication devices, and the like).

### EXAMPLES

Hereinafter, the present invention will be described further in detail with reference to Examples. In the following Examples, materials, usage amounts, ratios, details of treatments, and orders of treatments can be appropriately changed without departing from the spirit and scope of the present invention. Thus, the scope of the present invention should not be construed as being limited to the following Examples.

Solid substances and solvents used in Examples and Comparative Examples will be described below.

### Solid Substances

The following solid substances were used.

A-1 to A-5 are resins (A-1 to A-3 are the resin (P), and A-4 and A-5 are the resin (N)). The subscripts attached to the parentheses of the repeating units of A-1 to A-5 represent the contents of the repeating units. The content of such a repeating unit is a molar ratio relative to all the repeating units in the resin. The contents of the repeating units were measured by ¹³C-NMR (nuclear magnetic resonance).

For A-1 to A-5, weight-average molecular weight (Mw) and dispersity (Pd) will also be described. Mw and Pd were measured by GPC (carrier: tetrahydrofuran (THF)) (polystyrene-equivalent amounts).

B-1 to B-8, C-1, C-2, and D-2 are salt compounds.

B-6 to B-8, C-1, and C-2 were used as photoacid generators.

B-1 to B-5, D-1, and D-2 were used as acid diffusion control agents.

E-1 and E-2 are crosslinking agents.

W-1 to W-6 are surfactants.

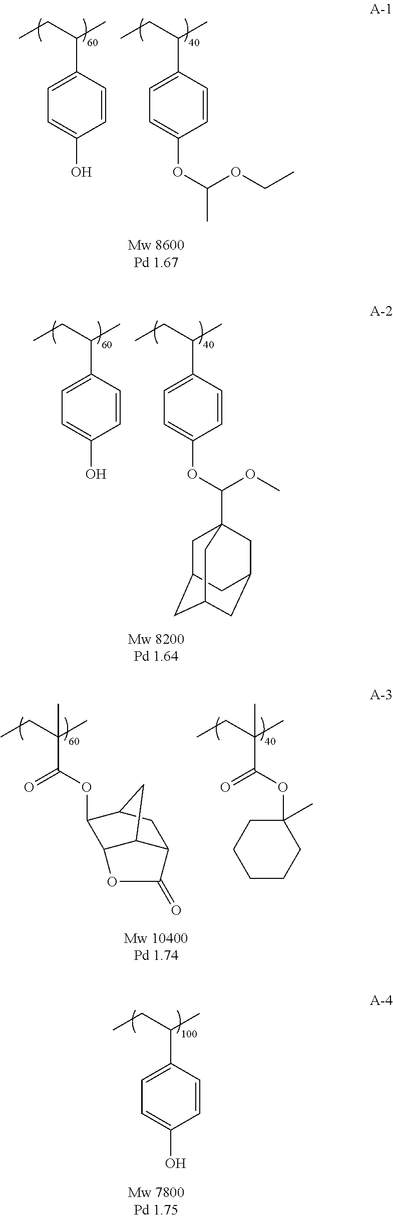

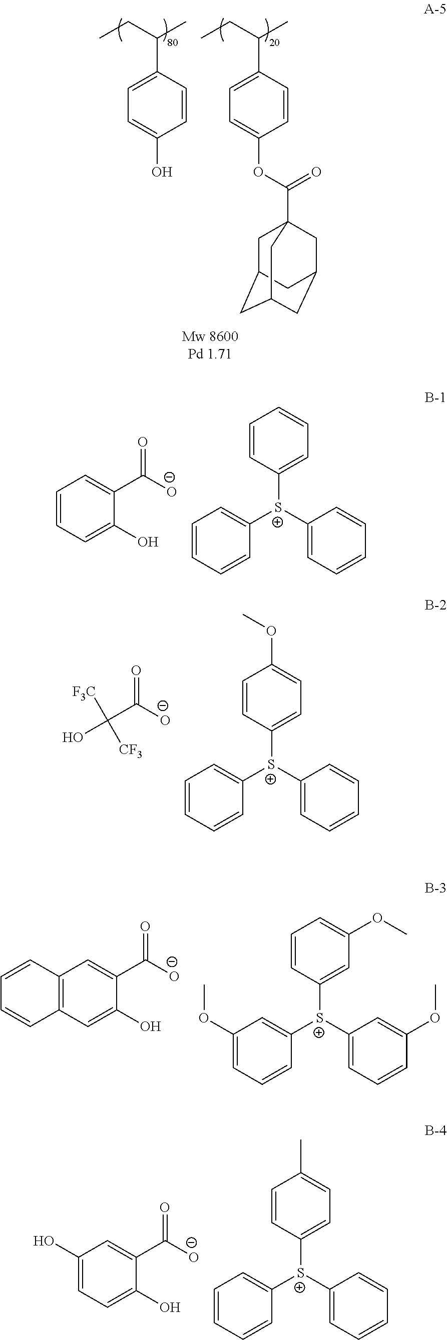

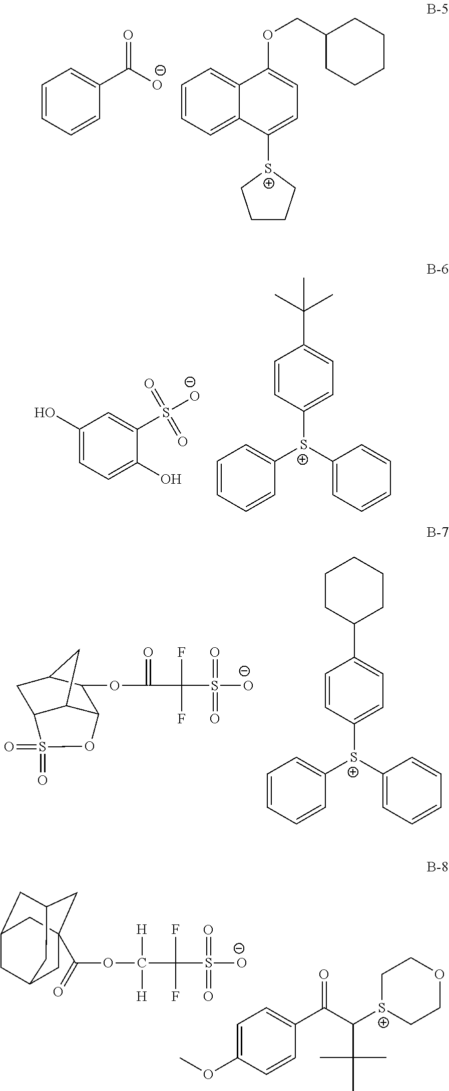

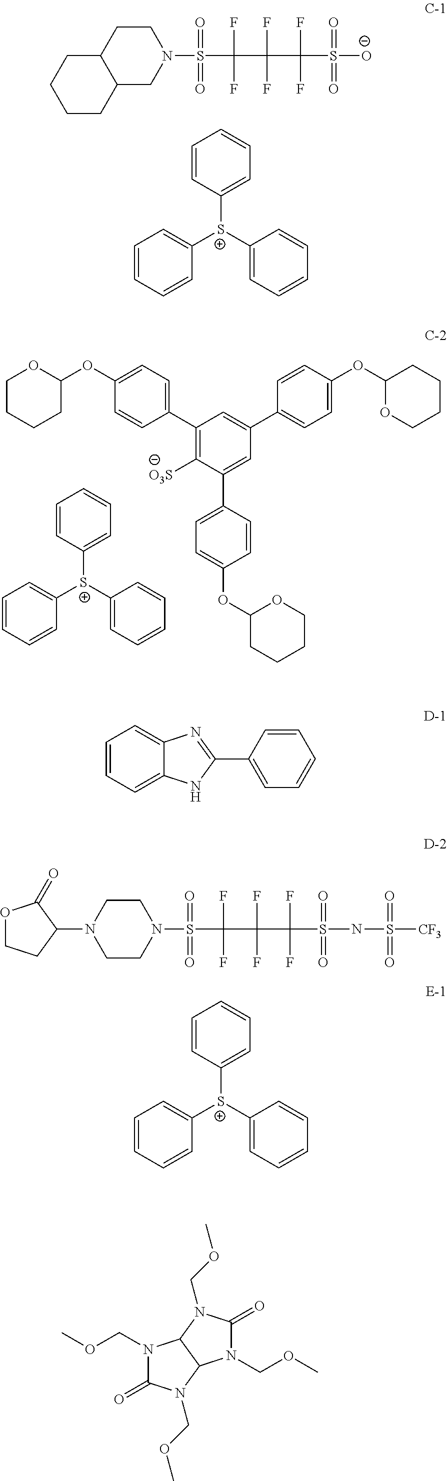

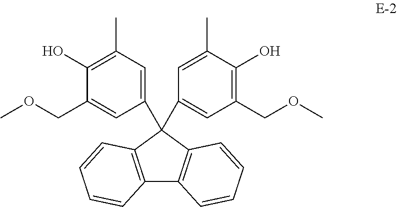

W-1: MEGAFAC F176 (manufactured by DIC Corporation; fluorine-based)

W-2: MEGAFAC R08 (manufactured by DIC Corporation; fluorine and silicone-based)

W-3: Polysiloxane polymer KP-341 (manufactured by Shin-Etsu Chemical Co., Ltd.; silicone-based) W-4: Troysol S-366 (manufactured by Troy Chemical Corporation)

W-5: KH-20 (manufactured by Asahi Glass Co., Ltd.)

W-6: PolyFox PF-6320 (manufactured by OMNOVA solutions Inc.; fluorine-based)

### Solvents

The solvents used are as follows.

SL-1: Propylene glycol monomethyl ether acetate (PGMEA)

SL-2: Propylene glycol monomethyl ether propionate

SL-3: 2-Heptanone

SL-4: Ethyl lactate

SL-5: Propylene glycol monomethyl ether (PGME)

SL-6: Cyclohexanone

SL-7: γ-Butyrolactone

SL-8: Propylene carbonate

SL-9: Diacetone alcohol

### Synthesis Example of A-1

Hereinafter, the synthesis example of A-1 will be described. The other resins were synthesized by similar methods or other publicly known methods.

Cyclohexanone (31.3 g) was heated to 85° C. under a nitrogen stream. While this liquid was stirred, a mixed solution of 4-vinylphenol (14.4 g), AS-1 (15.4 g), cyclohexanone (58.0 g), and dimethyl 2,2′-azobisisobutyrate [V-601, manufactured by FUJIFILM Wako Pure Chemical Corporation] (3.4 g) was added dropwise to the liquid over 3 hours to obtain a reaction solution. After completion of the dropwise addition, the reaction solution was further stirred at 85° C. for 3 hours. The obtained reaction solution was left to cool, then subjected to reprecipitation with 1400 g of ethyl acetate/heptane (in a mass ratio of 1:9), and then filtered; and the obtained solid was vacuum-dried to thereby obtain A-1 (24.1 g).

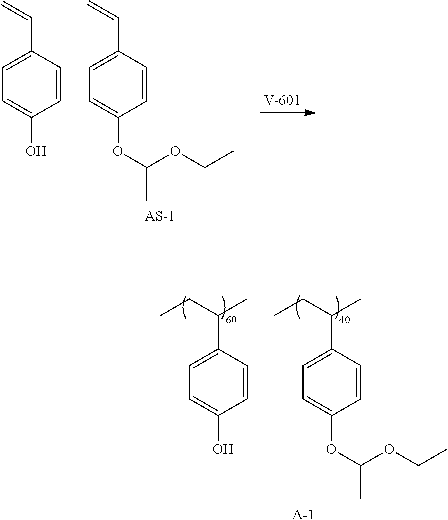

### Synthesis Example of B-1

B-1 was synthesized by the method described in WO2015/019983A. The other salt compounds were synthesized by similar methods or other publicly known methods.

### Production of Solutions

### Example 1: Production of Solution B-1-1

B-1 (15 g) was placed into a clean bottle having a volume of 250 mL and manufactured by AICELLO CORPORATION (trade name: AC-250); subsequently SL-5 (135 g) was added; and stirring was performed at 25° C. for 1 hour using a roller mixer to thereby obtain a 10 mass % solution of B-1 (solution B-1-1).

### Example 2: Production of Solution B-1-2

B-1 (15 g) was placed into a PTFE separable flask having a volume of 500 mL and manufactured by FLON CHEMICAL INC.; subsequently SL-5 (135 g) was added; and stirring was performed at 25° C. for 1 hour using a PTFE stirring blade (shape: half-moon, size: 4 cm) to thereby obtain a 10 mass % solution of B-1 (solution B-1-2).

### Example 3: Production of Solution B-1-3

B-1 (15 g) was placed into a recovery flask having an inner surface coated with PFA, having a volume of 300 mL, and manufactured by SANSYO Co., LTD.; subsequently SL-5 (150 g) was added and dissolved by stirring, using a PTFE stirring blade (shape: half-moon, size: 4 cm), at 25° C. for 1 hour. Subsequently, this solution was concentrated at 45° C. using a rotary evaporator to obtain a 10 mass % solution of B-1 (solution B-1-3).

### Example 4: Production of Solution B-2-1

The same procedures as in Example 2 were performed except that B-1 was replaced by B-2 and SL-5 was replaced by SL-2 to obtain a 10 mass % solution of B-2 (solution B-2-1).

### Example 5: Production of Solution B-3-1

The same procedures as in Example 2 were performed except that B-1 was replaced by B-3 and SL-5 was replaced by SL-9 to obtain a 10 mass % solution of B-3 (solution B-3-1).

### Example 6: Production of Solution B-4-1

The same procedures as in Example 3 were performed except that B-1 was replaced by B-4 and SL-5 was replaced by SL-1/SL-5 (in a mass ratio of 7/3) to obtain a 10 mass % solution of B-4 (solution B-4-1).

### Example 7: Production of Solution B-5-1

The same procedures as in Example 3 were performed except that B-1 was replaced by B-5 and SL-5 was replaced by SL-4 to obtain a 10 mass % solution of B-5 (solution B-5-1).

### Example 8: Production of Solution B-6-1

The same procedures as in Example 1 were performed except that B-1 was replaced by B-6 and SL-5 was replaced by SL-6 to obtain a 10 mass % solution of B-6 (solution B-6-1).

### Example 9: Production of Solution B-7-1

The same procedures as in Example 2 were performed except that B-1 was replaced by B-7 and SL-5 was replaced by SL-7 to obtain a 10 mass % solution of B-7 (solution B-7-1).

### Example 10: Production of Solution B-8-1

The same procedures as in Example 3 were performed except that B-1 was replaced by B-8 and SL-5 was replaced by SL-8 to obtain a 10 mass % solution of B-8 (solution B-8-1).

### Example 11: Production of Solution A-1-1

The same procedures as in Example 2 were performed except that B-1 was replaced by A-1 and SL-5 was replaced by SL-1 to obtain a 10 mass % solution of A-1 (solution A-1-1).

### Example 12

B-1 (60 g) was placed into a clean bottle having a volume of 1 L (trade name: AC-1L) manufactured by AICELLO CORPORATION; subsequently SL-5 (540 g) was added; stirring was performed using a roller mixer at 25° C. for 1 hour to thereby obtain a 10 mass % solution of B-1 (solution B-1-1-2).

### Example 13

B-1 (1500 g) was placed into a clean bottle having a volume of 20 L (trade name: AS050C) manufactured by AICELLO CORPORATION; subsequently SL-5 (13500 g) was added; and stirring was performed using a roller mixer at 25° C. for 1 hour to thereby obtain a 10 mass % solution of B-1 (solution B-1-1-3).

### Comparative Example 1: Production of Solution B-1-4

B-1 (15 g) was placed into a glass separable flask having a volume of 500 mL; subsequently SL-5 (135 g) was added; and stirring was performed using a PTFE stirring blade (shape: half-moon, size: 4 cm) at 25° C. for 1 hour to thereby obtain a 10 mass % solution of B-1 (solution B-1-4).

### Comparative Example 2: Production of Solution B-1-5

B-1 (15 g) was placed into a stainless steel separable flask having a volume of 500 mL; subsequently SL-5 (135 g) was added; stirring was performed using a PTFE stirring blade (shape: half-moon, size: 4 cm) at 25° C. for 1 hour to thereby obtain a 10 mass % solution of B-1 (solution B-1-5).

### Comparative Example 3: Production of Solution B-1-6

B-1 (15 g) was placed into a glass recovery flask having a volume of 300 ml; subsequently SL-5 (150 g) was added and dissolved by stirring at 25° C. for 1 hour using a PTFE stirring blade (shape: half-moon, size: 4 cm). Subsequently, this solution was concentrated at 45° C. using a rotary evaporator to obtain a 10 mass % solution of B-1 (solution B-1-6).

For the solutions produced in Examples 1 to 13 and Comparative Examples 1 to 3, the solid substances and solvents(S) used are summarized in Table 1 below. Note that the solutions produced in Examples 1 to 13 and Comparative Examples 1 to 3 were visually observed to find that the solid substances were completely dissolved in the solvents (the solid contents formed of the solid substances were entirety dissolved in the solvents).

TABLE 1

| | Produced | Solid | |
|---|---|---|---|
| | solution | substance | Solvent (S) |
| Example 1 | B-1-1 | B-1 | SL-5 |
| Example 2 | B-1-2 | B-1 | SL-5 |
| Example 3 | B-1-3 | B-1 | SL-5 |
| Example 4 | B-2-1 | B-2 | SL-2 |
| Example 5 | B-3-1 | B-3 | SL-9 |
| Example 6 | B-4-1 | B-4 | SL-1/SL-5 |
| | | | (mass ratio 70/30) |
| Example 7 | B-5-1 | B-5 | SL-4 |
| Example 8 | B-6-1 | B-6 | SL-6 |
| Example 9 | B-7-1 | B-7 | SL-7 |
| Example 10 | B-8-1 | B-8 | SL-8 |
| Example 11 | A-1-1 | A-1 | SL-1 |
| Example 12 | B-1-1-2 | B-1 | SL-5 |
| Example 13 | B-1-1-3 | B-1 | SL-5 |
| Comparative Example 1 | B-1-4 | B-1 | SL-5 |
| Comparative Example 2 | B-1-5 | B-1 | SL-5 |
| Comparative Example 3 | B-1-6 | B-1 | SL-5 |

### Examples 1-1 to 1-15 and Comparative Examples 1-1 to 1-3 Production of Resist Compositions

The following solution preparation method 1 or 2 was performed to produce resist compositions (R-1 to R-15 and RX-1 to RX-3).

### Solution Preparation Method 1

In Table 2 below, a solution described in the “Solution employed” column, solid substances described in the “Solid substance added” column, and a solvent described in the “Solvent added” column (mixed solvent including the solvents at the mass ratio in Table 2 below) were placed into a clean bottle having a volume of 1 L (trade name: AC-1L) manufactured by AICELLO CORPORATION; and a football-shaped stirring bar (material: PTFE) having a size of 2.5 cm and a magnetic stirrer were used to dissolve the solid substances in the solvent, to prepare a solution having a solid-content concentration of 2.7 mass %. This solution was filtered through a polyethylene filter having a pore size of 0.02 μm to obtain a resist composition.

### Solution Preparation Method 2

In Table 2 below, a solution described in the “Solution employed” column, solid substances described in the “Solid substance added” column, and a solvent described in the “Solvent added” column (mixed solvent including the solvents at the mass ratio described in Table 2 below) were placed into a PTFE separable flask having a volume of 500 mL and manufactured by FLON CHEMICAL INC.; stirring was performed using a PTFE stirring blade (shape: half-moon, size: 4 cm) to thereby dissolve the solid substances in the solvent to prepare a solution having a solid-content concentration of 2.7 mass %. This solution was filtered through a polyethylene filter having a pore size of 0.02 μm to obtain a resist composition.

Note that, for the solutions described in the “Solution employed” column and the solid substances described in the “Solid substance added” column in Table 2 below, the amounts of addition were adjusted such that the mass of each component included in the resist compositions matched the value in the “Amount (g)” column in Table 3 below. For the solvents described in the “Solvent added” column in Table 2 below, the amounts of addition were adjusted such that the resist compositions have a solid-content concentration of 2.7 mass %.

In Table 3 below, when two or more types of such a component were used, their types and amounts were individually described so as to be separated by “/”. For example, in the resist composition R-7, “A-1/A-2” indicates that two resins A-1 and A-2 were used, and “5/5” indicates that A-1 is used in an amount of 5 g and A-2 is used in an amount of 5 g. The same applies to Table 5 and Table 7 below.

TABLE 2

| | | Solution | | | | | Solvent added | |
|---|---|---|---|---|---|---|---|---|
| | Resist | preparation | Solution | | | | | Mass |
| | composition | method | employed | Solid substance added | | | Type | ratio |
| Example 1-1 | R-1 | 1 | B-1-1 | A-1 | C-2 | W-1 | SL-1/ | 60/40 |
| | | | | | | | SL-5 | |
| Example 1-2 | R-2 | 1 | B-1-2 | A-1 | C-2 | W-1 | SL-1/ | 60/40 |
| | | | | | | | SL-5 | |
| Example 1-3 | R-3 | 1 | B-1-3 | A-1 | C-2 | W-1 | SL-1/ | 60/40 |
| | | | | | | | SL-5 | |
| Example 1-4 | R-4 | 1 | B-2-1 | A-2 | C-2 | W-5 | SL-1/ | 60/40 |
| | | | | | | | SL-5 | |
| Example 1-5 | R-5 | 1 | B-3-1 | A-2 | C-2 | W-3 | SL-1/ | 60/40 |
| | | | | | | | SL-3 | |
| Example 1-6 | R-6 | 2 | B-4-1 | A-2 | C-2 | W-6 | SL-1/ | 70/30 |
| | | | | | | | SL-7 | |
| Example 1-7 | R-7 | 2 | B-5-1 | A-1/ | C-2 | W-2 | SL-1/ | 70/30 |
| | | | | A-2 | | | SL-5 | |
| Example 1-8 | R-8 | 1 | B-6-1 | A-2 | D-1 | W-4 | SL-1/ | 60/40 |
| | | | | | | | SL-9 | |
| Example 1-9 | R-9 | 1 | B-7-1 | A-3 | D-1 | W-2 | SL-2/ | 70/30 |
| | | | | | | | SL-6 | |
| Example 1-10 | R-10 | 2 | B-8-1 | A-3 | D-2 | W-1 | SL-1/ | 60/40 |
| | | | | | | | SL-4 | |
| Example 1-11 | R-11 | 1 | A-1-1/ | C-2 | W-1 | — | SL-1/ | 60/40 |
| | | | B-1-1 | | | | SL-5 | |
| Example 1-12 | R-12 | 1 | B-6-1/ | A-3 | D-2 | W-1 | SL-1/ | 60/40 |
| | | | B-7-1 | | | | SL-9 | |
| Example 1-13 | R-13 | 1 | B-1-1/ | A-2 | C-2 | W-4 | SL-1/ | 60/40 |
| | | | B-2-1 | | | | SL-5 | |
| Example 1-14 | R-14 | 1 | B-1-1-2 | A-1 | C-2 | W-1 | SL-1/ | 60/40 |
| | | | | | | | SL-5 | |
| Example 1-15 | R-15 | 1 | B-1-1-3 | A-1 | C-2 | W-1 | SL-1/ | 60/40 |
| | | | | | | | SL-5 | |
| Comparative | RX-1 | 1 | B-1-4 | A-1 | C-2 | W-1 | SL-1/ | 60/40 |
| Example 1-1 | | | | | | | SL-5 | |
| Comparative | RX-2 | 1 | B-1-5 | A-1 | C-2 | W-1 | SL-1/ | 60/40 |
| Example 1-2 | | | | | | | SL-5 | |
| Comparative | RX-3 | 1 | B-1-6 | A-1 | C-2 | W-1 | SL-1/ | 60/40 |
| Example 1-3 | | | | | | | SL-5 | |

### Application of Resist Composition and Formation of Resist Film

Such a resist composition produced was applied onto a 6-inch Si (silicon) wafer having been treated with hexamethyldisilazane (HMDS) in advance, using a spin coater Mark8 manufactured by Tokyo Electron Ltd., and dried on a hot plate at 130° C. for 300 seconds to obtain a resist film having a film thickness of 100 nm.

Note that, even when the Si wafer is changed to a chromium substrate, similar results are obtained.

### Pattern Forming Method (1): EB Exposure, Alkali Development (Positive)

The wafer obtained above and having the resist film formed was subjected to pattern irradiation using an electron beam lithography apparatus (manufactured by ADVANTEST CORPORATION; F7000S, accelerating voltage: 50 keV). During this process, patterning was performed so as to form a 1:1 line-and-space. After the electron beam patterning, heating was performed on a hot plate at 100° C. for 60 seconds; subsequently immersion in a developer of a 2.38 mass % aqueous tetramethylammonium hydroxide (TMAH) solution was performed for 60 seconds; subsequently rising with water was performed for 30 seconds and drying was performed. Subsequently, the wafer was rotated at a rotation rate of 4000 rpm for 30 seconds, and subsequently baked at 95° C. for 60 seconds for drying.

### Evaluation of Development Defects

The profile of the obtained pattern was observed using a scanning electron microscope (manufactured by Hitachi, Ltd. S-9380II). The exposure dose at which a 1:1 line-and-space resist pattern having a line width of 50 nm is resolved was defined as sensitivity (Eop).

A defect inspection apparatus KLA2360 manufactured by KLA-Tencor Corporation was used to perform measurement in the random mode such that the pixel size of the defect inspection apparatus was set to 0.16 μm and the threshold value was set to 20; development defects extracted on the basis of differences provided by performing pixel-by-pixel overlay with a comparison image were detected, and the number of development defects per unit area (1 cm²) was calculated. A case in which the value was less than 0.5 was evaluated as A; a case in which the value was 0.5 or more and less than 0.7 was evaluated as B; a case in which the value was 0.7 or more and less than 1.0 was evaluated as C; and a case in which the value was 1.0 or more was evaluated as D. The smaller the value, the higher the performance. The results are described in Table 3 below.

TABLE 3

| | | | Photoacid | | Acid diffusion | | | | |
|---|---|---|---|---|---|---|---|---|---|
| | Resin | | generator | | control agent | | Surfactant | | |
| Resist | | Amount | | Amount | | Amount | | Amount | Development |
| composition | Type | (g) | Type | (g) | Type | (g) | Type | (g) | defects |
| R-1 | A-1 | 10 | C-2 | 1.0 | B-1 | 0.20 | W-1 | 0.003 | A |
| R-2 | A-1 | 10 | C-2 | 1.0 | B-1 | 0.20 | W-1 | 0.003 | A |
| R-3 | A-1 | 10 | C-2 | 1.0 | B-1 | 0.20 | W-1 | 0.003 | A |
| R-4 | A-2 | 10 | C-2 | 1.0 | B-2 | 0.20 | W-5 | 0.003 | A |
| R-5 | A-2 | 10 | C-2 | 1.0 | B-3 | 0.20 | W-3 | 0.003 | A |
| R-6 | A-2 | 10 | C-2 | 1.0 | B-4 | 0.20 | W-6 | 0.003 | A |
| R-7 | A-1/ | 5/5 | C-2 | 1.0 | B-5 | 0.20 | W-2 | 0.003 | A |
| | A-2 | | | | | | | | |
| R-8 | A-2 | 10 | B-6 | 1.0 | D-1 | 0.20 | W-4 | 0.003 | A |
| R-9 | A-3 | 10 | B-7 | 1.0 | D-1 | 0.20 | W-2 | 0.003 | A |
| R-10 | A-3 | 10 | B-8 | 1.0 | D-2 | 0.20 | W-1 | 0.003 | A |
| R-11 | A-1 | 10 | C-2 | 1.0 | B-1 | 0.20 | W-1 | 0.003 | A |
| R-12 | A-3 | 10 | B-6/ | 0.5/ | D-2 | 0.20 | W-1 | 0.003 | A |
| | | | B-7 | 0.5 | | | | | |
| R-13 | A-2 | 10 | C-2 | 1.0 | B-1/ | 0.10/ | W-4 | 0.003 | A |
| | | | | | B-2 | 0.10 | | | |
| R-14 | A-1 | 10 | C-2 | 1.0 | B-1 | 0.20 | W-1 | 0.003 | A |
| R-15 | A-1 | 10 | C-2 | 1.0 | B-1 | 0.20 | W-1 | 0.003 | A |
| RX-1 | A-1 | 10 | C-2 | 1.0 | B-1 | 0.20 | W-1 | 0.003 | C |
| RX-2 | A-1 | 10 | C-2 | 1.0 | B-1 | 0.20 | W-1 | 0.003 | C |
| RX-3 | A-1 | 10 | C-2 | 1.0 | B-1 | 0.20 | W-1 | 0.003 | C |

### Examples 2-1 to 2-6 and Comparative Example 2-1

### Production of Resist Compositions

The following solution preparation method 3 or 4 was performed to produce resist compositions (Q-1 to Q-6 and QX-1).

### Solution Preparation Method 3

In Table 4 below, a solution described in the “Solution employed” column, solid substances described in the “Solid substance added” column, and a solvent described in the “Solvent added” column (mixed solvent including the solvents at the mass ratio in Table 4 below) were placed into a clean bottle having a volume of 1 L (trade name: AC-1L) manufactured by AICELLO CORPORATION; and a football-shaped stirring bar (material: PTFE) having a size of 2.5 cm and a magnetic stirrer were used to dissolve the solid substances in the solvent, to prepare a solution having a solid-content concentration of 2.7 mass %. This solution was filtered through a polyethylene filter having a pore size of 0.02 μm to obtain a resist composition.

### Solution Preparation Method 4

In Table 4 below, a solution described in the “Solution employed” column, solid substances described in the “Solid substance added” column, and a solvent described in the “Solvent added” column (mixed solvent including the solvents at the mass ratio described in Table 4 below) were placed into a PTFE separable flask having a volume of 500 mL and manufactured by FLON CHEMICAL INC.; stirring was performed using a PTFE stirring blade (shape: half-moon, size: 4 cm) to thereby dissolve the solid substances in the solvent to prepare a solution having a solid-content concentration of 2.7 mass %. This solution was filtered through a polyethylene filter having a pore size of 0.02 μm to obtain a resist composition.

Note that, for the solutions described in the “Solution employed” column and the solid substances described in the “Solid substance added” column in Table 4 below, the amounts of addition were adjusted such that the mass of each component included in the resist compositions matched the value in the “Amount (g)” column in Table 5 below. For the solvents described in the “Solvent added” column in Table 4 below, the amounts of addition were adjusted such that the resist compositions have a solid-content concentration of 2.7 mass %.

TABLE 4

| | | Solution | | | | | | Solvent added | |
|---|---|---|---|---|---|---|---|---|---|
| | Resist | preparation | Solution | | | | | | Mass |
| | composition | method | employed | Solid substance added | | | | Type | ratio |
| Example 2-1 | Q-1 | 3 | B-1-2 | A-4 | C-1 | E-1 | W-1 | SL-1/ | 60/40 |
| | | | | | | | | SL-5 | |
| Example 2-2 | Q-2 | 3 | B-6-1 | A-5 | D-1 | E-2 | W-1 | SL-1/ | 60/40 |
| | | | | | | | | SL-7 | |
| Example 2-3 | Q-3 | 4 | B-7-1 | A-5 | D-1 | E-2 | W-1 | SL-1/ | 70/30 |
| | | | | | | | | SL-3 | |
| Example 2-4 | Q-4 | 4 | B-8-1 | A-4/ | D-1 | E-2 | W-5 | SL-1/ | 70/30 |
| | | | | A-5 | | | | SL-5 | |
| Example 2-5 | Q-5 | 4 | B-7-1/ | A-5 | D-1 | E-2 | W-1 | SL-1/ | 70/30 |
| | | | B-8-1 | | | | | SL-3 | |
| Example 2-6 | Q-6 | 4 | B-2-1 | A-5 | C-1 | E-1/ | W-1 | SL-1/ | 60/40 |
| | | | | | | E-2 | | SL-9 | |
| Comparative | QX-1 | 3 | B-1-4 | A-4 | C-1 | E-1 | W-1 | SL-1/ | 60/40 |
| Example 2-1 | | | | | | | | SL-5 | |

### Application of Resist Composition and Formation of Resist Film

Such a resist composition produced was applied onto a 6-inch Si (silicon) wafer having been treated with hexamethyldisilazane (HMDS) in advance, using a spin coater Mark8 manufactured by Tokyo Electron Ltd., and dried on a hot plate at 130° C. for 300 seconds to obtain a resist film having a film thickness of 100 nm.

Note that, even when the Si wafer is changed to a chromium substrate, similar results are obtained.

### Pattern Forming Method (2): EB Exposure, Alkali Development (Negative)

The wafer obtained above and having the resist film formed was subjected to pattern irradiation using an electron beam lithography apparatus (manufactured by ADVANTEST CORPORATION, F7000S, accelerating voltage: 50 keV). During this process, patterning was performed so as to form a 1:1 line-and-space. After the electron beam patterning, heating was performed on a hot plate at 100° C. for 60 seconds; immersion in a developer of a 2.38 mass % aqueous tetramethylammonium hydroxide (TMAH) solution was performed for 60 seconds; subsequently, rinsing with water was performed for 30 seconds, and drying was performed. Subsequently, the wafer was rotated at a rotation rate of 4000 rpm for 30 seconds, and subsequently baked at 95° C. for 60 seconds for drying.

### Evaluation of Development Defects

The same method as in Examples 1-1 to 1-15 and Comparative Examples 1-1 to 1-3 was performed to evaluate development defects. The results are described in Table 5 below.

TABLE 5

| | | | Photoacid | | Acid diffusion | | Crosslinking | | | | |
|---|---|---|---|---|---|---|---|---|---|---|---|
| | Resin | | generator | | control agent | | agent | | Surfactant | | |
| Resist | | Amount | | Amount | | Amount | | Amount | | Amount | Development |
| composition | Type | (g) | Type | (g) | Type | (g) | Type | (g) | Type | (g) | defects |
| Q-1 | A-4 | 10 | C-1 | 1.0 | B-1 | 0.20 | E-1 | 3.0 | W-1 | 0.003 | A |
| Q-2 | A-5 | 10 | B-6 | 1.0 | D-1 | 0.20 | E-2 | 3.0 | W-1 | 0.003 | A |
| Q-3 | A-5 | 10 | B-7 | 1.0 | D-1 | 0.20 | E-2 | 3.0 | W-1 | 0.003 | A |
| Q-4 | A-4/ | 4/6 | B-8 | 1.0 | D-1 | 0.20 | E-2 | 3.0 | W-5 | 0.003 | A |
| | A-5 | | | | | | | | | | |
| Q-5 | A-5 | 10 | B-7/ | 0.5/ | D-1 | 0.20 | E-2 | 3.0 | W-1 | 0.003 | A |
| | | | B-8 | 0.5 | | | | | | | |
| Q-6 | A-5 | 10 | C-1 | 1.0 | B-2 | 0.20 | E-1/ | 1.0/ | W-1 | 0.003 | A |
| | | | | | | | E-2 | 2.0 | | | |
| QX-1 | A-4 | 10 | C-1 | 1.0 | B-1 | 0.20 | E-1 | 3.0 | W-1 | 0.003 | C |

### Examples 3-1 to 3-7 and Comparative Example 3-1

### Production of Resist Compositions

The following solution preparation method 5 or 6 was performed to produce resist compositions (T-1 to T-7 and TX-1).

### Solution Preparation Method 5

In Table 6 below, a solution described in the “Solution employed” column, solid substances described in the “Solid substance added” column, and a solvent described in the “Solvent added” column (mixed solvent including the solvents at the mass ratio in Table 6 below) were placed into a clean bottle having a volume of 1 L (trade name: AC-1L) manufactured by AICELLO CORPORATION; and a football-shaped stirring bar (material: PTFE) having a size of 2.5 cm and a magnetic stirrer were used to dissolve the solid substances in the solvent, to prepare a solution having a solid-content concentration of 2.7 mass %. This solution was filtered through a polyethylene filter having a pore size of 0.02 μm to obtain a resist composition.

### Solution Preparation Method 6

In Table 6 below, a solution described in the “Solution employed” column, solid substances described in the “Solid substance added” column, and a solvent described in the “Solvent added” column (mixed solvent including the solvents at the mass ratio described in Table 6 below) were placed into a PTFE separable flask having a volume of 500 mL and manufactured by FLON CHEMICAL INC.; stirring was performed using a PTFE stirring blade (shape: half-moon, size: 4 cm) to thereby dissolve the solid substances in the solvent to prepare a solution having a solid-content concentration of 2.7 mass %. This solution was filtered through a polyethylene filter having a pore size of 0.02 μm to obtain a resist composition.

Note that, for the solutions described in the “Solution employed” column and the solid substances described in the “Solid substance added” column in Table 6 below, the amounts of addition were adjusted such that the mass of each component included in the resist compositions matched the value in the “Amount (g)” column in Table 7 below. For the solvents described in the “Solvent added” column in Table 6 below, the amounts of addition were adjusted such that the resist compositions have a solid-content concentration of 2.7 mass %.

TABLE 6

| | | Solution | | | | | Solvent added | |
|---|---|---|---|---|---|---|---|---|
| | Resist | preparation | Solution | | | | | Mass |
| | composition | method | employed | Solid substance added | | | Type | ratio |
| Example 3-1 | T-1 | 5 | B-1-3 | A-3 | C-1 | W-1 | SL-1/ | 60/40 |
| | | | | | | | SL-5 | |
| Example 3-2 | T-2 | 5 | B-7-1 | A-3 | D-1 | W-1 | SL-1/ | 60/40 |
| | | | | | | | SL-5 | |
| Example 3-3 | T-3 | 5 | B-8-1 | A-3 | D-2 | W-1 | SL-1/ | 60/40 |
| | | | | | | | SL-9 | |
| Example 3-4 | T-4 | 6 | B-1-2 | A-2/ | C-1 | W-1 | SL-2/ | 70/30 |
| | | | | A-3 | | | SL-6 | |
| Example 3-5 | T-5 | 6 | B-6-1 | A-3 | D-2 | W-5 | SL-1/ | 60/40 |
| | | | | | | | SL-4 | |
| Example 3-6 | T-6 | 5 | B-7-1/ | A-3 | W-1 | — | SL-2/ | 70/30 |
| | | | B-8-1/ | | | | SL-6 | |
| | | | B-1-2 | | | | | |
| Example 3-7 | T-7 | 5 | B-1-2/ | A-3 | C-1 | W-4 | SL-1/ | 60/40 |
| | | | B-2-1 | | | | SL-4 | |
| Comparative | TX-1 | 5 | B-1-5 | A-3 | C-1 | W-1 | SL-1/ | 60/40 |
| Example 3-1 | | | | | | | SL-5 | |

### Application of Resist Composition and Formation of Resist Film

Such a resist composition produced was applied onto a 6-inch Si (silicon) wafer having been treated with hexamethyldisilazane (HMDS) in advance, using a spin coater Mark8 manufactured by Tokyo Electron Ltd., and dried on a hot plate at 130° C. for 300 seconds to obtain a resist film having a film thickness of 100 nm.

Note that, even when the Si wafer is changed to a chromium substrate, similar results are obtained.

### Pattern Forming Method (3): EUV Exposure, Organic-Solvent Development (Negative)

The wafer obtained above and having the resist film formed was subjected to pattern exposure using an EUV exposure apparatus (manufactured by Exitech Ltd., Micro Exposure Tool, NA (numerical aperture): 0.3, Quadrupole, outer sigma: 0.68, inner sigma: 0.36) and using an exposure mask (line:space=1:1). After the exposure, heating was performed on a hot plate at 100° C. for 90 seconds; subsequently, development was performed with n-butyl acetate for 30 seconds; this was spin-dried to obtain a negative pattern.

### Evaluation of Development Defects

The same method as in Examples 1-1 to 1-15 and Comparative Examples 1-1 to 1-3 was performed to evaluate development defects. The results are described in Table 7 below.

TABLE 7

| | | | Photoacid | | Acid diffusion | | | | |
|---|---|---|---|---|---|---|---|---|---|
| | Resin | | generator | | control agent | | Surfactant | | |
| Resist | | Amount | | Amount | | Amount | | Amount | Development |
| composition | Type | (g) | Type | (g) | Type | (g) | Type | (g) | defects |
| T-1 | A-3 | 10 | C-1 | 1.0 | B-1 | 0.20 | W-1 | 0.003 | A |
| T-2 | A-3 | 10 | B-7 | 1.0 | D-1 | 0.20 | W-1 | 0.003 | A |
| T-3 | A-3 | 10 | B-8 | 1.0 | D-2 | 0.20 | W-1 | 0.003 | A |
| T-4 | A-2/ | 2/8 | C-1 | 1.0 | B-1 | 0.20 | W-1 | 0.003 | A |
| | A-3 | | | | | | | | |
| T-5 | A-3 | 10 | B-6 | 1.0 | D-2 | 0.20 | W-5 | 0.003 | A |
| T-6 | A-3 | 10 | B-7/ | 0.5/ | B-1 | 0.20 | W-1 | 0.003 | A |
| | | | B-8 | 0.5 | | | | | |
| T-7 | A-3 | 10 | C-1 | 1.0 | B-1/ | 0.10/ | W-4 | 0.003 | A |
| | | | | | B-2 | 0.10 | | | |
| TX-1 | A-3 | 10 | C-1 | 1.0 | B-1 | 0.20 | W-1 | 0.003 | C |

The above-described results have demonstrated that the resist compositions produced using the solutions produced by the methods for producing a solution in the Examples can suppress generation of development defects when used for pattern formation.

The present invention can provide a method for producing a solution that can be used for preparing a resist composition that can suppress generation of development defects when used for pattern formation, a method for producing the resist composition, a pattern forming method using the resist composition produced by the method for producing the resist composition, and a method for producing an electronic device.

The present invention has been described in detail and with reference to specific embodiments thereof; however, it would be apparent to those skilled in the art that various changes and modifications can be made therein without departing from the spirit and scope of the present invention.

What is claimed is:

1. A method for producing a solution wherein one or more solid substances are dissolved in a solvent,
the one or more solid substances are used as components of a resist composition, and
the method comprises placing, into a container including a resin in at least a portion of an inner wall surface, the one or more solid substances and the solvent and dissolving a portion of or an entirety of a solid content contained in the one or more solid substances.

2. The method for producing a solution according to claim 1, wherein the solvent includes at least one selected from the group consisting of a compound represented by a formula (1-1) below and a compound represented by a formula (1-2) below: 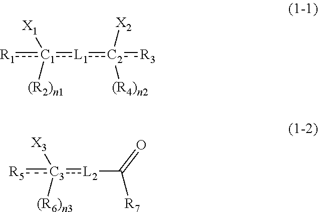
in the formula (1-1), X₁ and X₂ each independently represent a hydroxy group, an alkoxy group, an acyloxy group, —N(Rx)₂, —NRaCORb, a thiol group, or a thioalkoxy group;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
C₁ and C₂ each independently represent an sp³ carbon or an sp² carbon;
L₁ represents a single bond, a double bond, an aromatic carbon-carbon bond, or a linking group having 2 or less carbon atoms;
R₁ to R₄ each independently represent a hydrogen atom or an organic group;
at least two of X₁, X₂, R₁ to R₄, and L₁ may be bonded together to form a ring;
n1 represents 0 or 1, provided that, when C₁ is an sp² carbon, n1 is 0, and when C₁ is an sp³ carbon, n1 is 1; and
n2 represents 0 or 1, provided that, when C₂ is an sp² carbon, n2 is 0, and when C₂ is an sp³ carbon, n2 is 1,
in the formula (1-2), X₃ represents a hydroxy group, an alkoxy group, an acyloxy group, —N(Rx)₂, —NRaCORb, a thiol group, or a thioalkoxy group;
C₃ represents an sp³ carbon or an sp² carbon;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
L₂ represents a single bond, a double bond, an aromatic carbon-carbon bond, or a linking group having 2 or less carbon atoms;
R₅ and R₆ each independently represent a hydrogen atom or an organic group;
R₇ represents a hydrogen atom, an alkyl group, an aryl group, —OH, or —OR₈;
R₈ represents an organic group;
at least two of X₃, R₅ to R₈, and L₂ may be bonded together to form a ring; and
n3 represents 0 or 1, provided that, when C₃ is an sp² carbon, n3 is 0, and when C₃ is an sp³ carbon, n3 is 1.

3. The method for producing a solution according to claim 1, wherein the solid substances include a compound having a salt structure.

4. The method for producing a solution according to claim 3, wherein the compound having a salt structure includes at least one selected from the group consisting of a compound represented by a formula (2-1) below, a compound represented by a formula (2-2) below, and a compound represented by a formula (2-3) below: 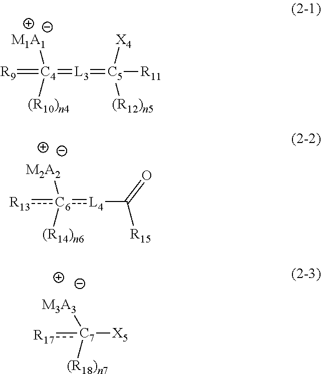
in the formula (2-1), M₁⁺ represents an organic cation;
A₁⁻ represents an acid residue;
X₄ represents a hydroxy group, an alkoxy group, an acyloxy group, —N(Rx)₂, —NRaCORb, a thiol group, or a thioalkoxy group;
C₄ and C₅ each independently represent an sp³ carbon or an sp² carbon;
Rx represents a hydrogen atom or an organic group, and two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different;
L₃ represents a single bond, a double bond, an aromatic carbon-carbon bond, or a linking group having 2 or less carbon atoms;
R₉ to R₁₂ each independently represent a hydrogen atom or an organic group;
at least two of X₄, R₉ to R₁₂, and L₃ may be bonded together to form a ring;
n4 represents 0 or 1, provided that, when C₄ is an sp² carbon, n4 is 0, and when C₄ is an sp³ carbon, n4 is 1; and
n5 represents 0 or 1, provided that, when C₅ is an sp² carbon, n5 is 0, and when C₅ is an sp³ carbon, n5 is 1,
in the formula (2-2), M₂⁺ represents an organic cation;
A₂⁻ represents an acid residue;
L₄ represents a single bond, a double bond, an aromatic carbon-carbon bond, or a linking group having 2 or less carbon atoms;
C₆ represents an sp³ carbon or an sp² carbon;
R₁₃ and R₁₄ each independently represent a hydrogen atom or an organic group;
R₁₅ represents a hydrogen atom, an alkyl group, an aryl group, —OH, or —OR₁₆;
R₁₆ represents an organic group;
at least two of R₁₃ to R₁₆ and L₄ may be bonded together to form a ring; and
n6 represents 0 or 1, provided that, when C₆ is an sp² carbon, n6 is 0, and when C₆ is an sp³ carbon, n6 is 1,
in the formula (2-3), M₃⁺ represents an organic cation;
A₃⁻ represents an acid residue;
X₅ represents a hydroxy group, an alkoxy group, an acyloxy group, —N(Rx)₂, —NRaCORb, a thiol group, or a thioalkoxy group;
Rx represents a hydrogen atom or an organic group;
two Rx may be the same or different;
Ra represents a hydrogen atom or an organic group;
Rb represents a hydrogen atom, an alkyl group, a cycloalkyl group, an aryl group, an aralkyl group, an alkoxy group, —N(Rc)₂, or a thioalkoxy group;
Rc represents a hydrogen atom or an organic group, and two Rc may be the same or different,
C₇ represents an sp³ carbon or an sp² carbon;
R₁₇ and R₁₈ each independently represent a hydrogen atom or an organic group;
at least two of X₅, R₁₇, and R₁₈ may be bonded together to form a ring; and
n7 represents 0 or 1, provided that, when C₇ is an sp² carbon, n7 is 0 or, when C₇ is an sp³ carbon, n7 is 1.

5. The method for producing a solution according to claim 1, wherein the container is a portable container.

6. The method for producing a solution according to claim 5, wherein the container has a volume of 1 L or more.

7. A method for producing a resist composition, the method comprising:
placing, into a container including a resin in at least a portion of an inner wall surface, one or more solid substances used as components of a resist composition and a solvent; and
dissolving a portion of or an entirety of a solid content contained in the one or more solid substances.

8. A method for producing a resist composition, the method comprising using a solution produced by the method for producing a solution according to claim 1, to prepare a resist composition.

9. A pattern forming method comprising:
forming a resist film using a resist composition produced by the method for producing a resist composition according to claim 7;
exposing the resist film; and
developing the exposed resist film using a developer.

10. A method for producing an electronic device, the method comprising the pattern forming method according to claim 9.
